(19) United States
(12) Patent Application Publication
(10) Pub. No.: US 2015/0093691 A1
(43) Pub. Date: Apr. 2, 2015

(54) ACTINIC-RAY- OR RADIATION-SENSITIVE RESIN COMPOSITION AND METHOD OF FORMING PATTERN USING THE COMPOSITION

(71) Applicant: FUJIFILM CORPORATION, Tokyo (JP)

(72) Inventor: Akinori SHIBUYA, Haibara-gun (JP)

(73) Assignee: FUJIFILM CORPORATION, Tokyo (JP)

(21) Appl. No.: 14/559,595

(22) Filed: Dec. 3, 2014

Related U.S. Application Data
(63) Continuation of application No. PCT/JP2013/065633, filed on Jun. 5, 2013.

(30) Foreign Application Priority Data
Jun. 5, 2012 (JP) 2012-128252

(51) Int. Cl. G03F 7/027; G03F 7/20; G03F 7/038; G03F 7/30

(52) U.S. Cl. CPC G03F 7/027; G03F 7/30; G03F 7/2041; G03F 7/038
USPC 430/18; 430/281.1; 430/325; 430/311

(57) ABSTRACT

According to one embodiment, an actinic-ray- or radiation-sensitive resin composition includes compound (A) that when exposed to actinic rays or radiation, generates acids and resin (B) that when acted on by an acid, is decomposed to thereby increase its solubility in an alkali developer. Compound (A) is expressed by general formula (I) below. Resin (B) contains at least one of repeating units of general formula (1) below.

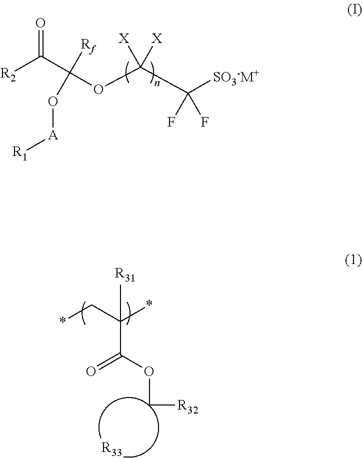

### CROSS-REFERENCE TO RELATED APPLICATIONS

This application is a Continuation Application of PCT Application No. PCT/JP2013/065633, filed Jun. 5, 2013 and based upon and claiming the benefit of priority from Japanese Patent Application No. 2012-128252, filed Jun. 5, 2012, the entire contents of all of which are incorporated herein by reference.

### FIELD

The present invention relates to an actinic-ray- or radiation-sensitive resin composition, and relates to an actinic-ray- or radiation-sensitive film therefrom and a method of forming a pattern using the composition. More particularly, the present invention relates to an actinic-ray- or radiation-sensitive resin composition for use in not only a semiconductor production process for an IC or the like, a circuit board production for a liquid crystal, a thermal head or the like and other photofabrication processes but also a lithographic printing plate and an acid-hardenable composition, and further relates to an actinic-ray- or radiation-sensitive film therefrom and a method of forming a pattern using the composition. Still further, the present invention relates to a process for manufacturing an electronic device, in which the above pattern forming method is utilized, and an electronic device manufactured by the process.

### BACKGROUND

A chemically amplified resist composition is a pattern forming material that is capable of, upon exposure to far ultraviolet or other radiation, generating an acid in exposed areas and, by a reaction catalyzed by the acid, changing the solubility in a developer between the areas having been exposed to actinic radiation and the nonexposed areas to thereby attain pattern formation on a substrate.

When a KrF excimer laser is used as an exposure light source, a resin whose fundamental skeleton is formed of a poly(hydroxystyrene) exhibiting a low absorption mainly in the region of 248 nm is employed as a major component of the resist composition. Accordingly, there can be attained a high sensitivity, high resolution and favorable pattern formation. Thus, a system superior to the conventional naphthoquinone diazide/novolak resin system is realized.

In contrast, when use is made of a light source of a further shorter wavelength, for example, an exposure light source of an ArF excimer laser (193 nm), as the compounds containing aromatic groups inherently exhibit a sharp absorption in the region of 193 nm, the above-mentioned chemical amplification system has not been satisfactory. Consequently, resists for ArF excimer laser containing a resin with an alicyclic hydrocarbon structure have been developed.

Moreover, various compounds have been developed as a photoacid generator being a main constituent of the chemically amplified resist composition (see, for example, patent reference 1). Patent reference 1 describes photoacid generators comprised of fluorinated sulfonic acid salts.

However, with respect to these resist compositions, further improvement is required in the temporal stability thereof in the form of a liquid.

Patent reference 1: PCT International Publication No. 2012/056901 (pamphlet).

### DETAILED DESCRIPTION

It is an object of the present invention to provide an actinic-ray- or radiation-sensitive resin composition excelling in not only exposure latitude (hereinafter also referred to as DOF) and pattern roughness, such as line width roughness (hereinafter also referred to as LWR), but also temporal stability. It is another object of the present invention to provide a method of forming a pattern through the use of the composition.

The inventors have conducted extensive and intensive studies with a view toward solving the above problem. As a result, the following embodiments of inventions have been completed.

[1] An actinic-ray- or radiation-sensitive resin composition comprising:

(A) at least one of compounds of general formula (I) below that when exposed to actinic rays or radiation, generates acids, and

(B) a resin containing at least one of repeating units of general formula (1) below, which resin when acted on by an acid, is decomposed to thereby increase its solubility in an alkali developer,

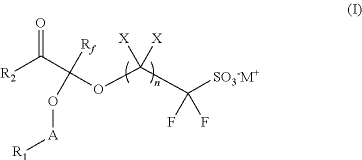

in which

each of X's independently represents a hydrogen atom, a fluorine atom or a fluorinated alkyl group;

R₁ represents a hydrogen atom, a halogen atom, an alkyl group, a mono- or polycycloalkyl group, an alkenyl group, an oxoalkyl group, an aryl group or an aralkyl group;

R₂ is either R₃O or R₄R₅N, in which each of R₃, R₄ and R₅ independently represents a hydrogen atom, an alkyl group, a mono- or polycycloalkyl group, an alkenyl group, an oxoalkyl group, an aryl group, an aralkyl group or a lactone group, provided that when R₂ is R₄R₅N, R₄ and R₅ may be bonded to each other to thereby form a ring structure in cooperation with the nitrogen atom to which R₄ and R₅ are bonded;

R_{f} represents a hydrogen atom, a fluorine atom or a fluorinated alkyl group;

A is any of groups of formulae below;

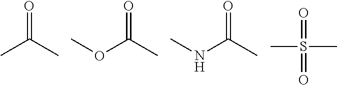

M⁺ represents a monovalent cation; and

n is an integer of 1 to 10,

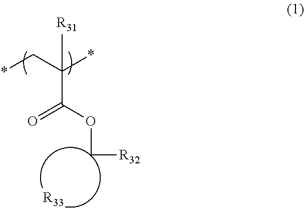

in which

R₃₁ represents a hydrogen atom, a fluorine atom, an alkyl group or a fluorinated alkyl group;

R₃₂ represents a methyl group, an ethyl group, an n-propyl group, an isopropyl group, an n-butyl group, an isobutyl group or a sec-butyl group; and

R₃₃ represents an atomic group required to form a monoalicyclic hydrocarbon structure in cooperation with the carbon atom to which R₃₂ is bonded, provided that in the alicyclic hydrocarbon structure, ring-constituting carbon atoms may be partially replaced by a heteroatom or a heteroatom-containing group.

[2] The actinic-ray- or radiation-sensitive resin composition according to item [1], wherein in general formula (I), M⁺ is any of sulfonium cations of general formulae (II) and (III) below,

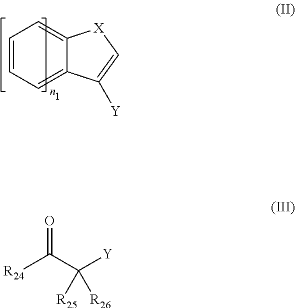

in which

Y represents any of structures of general formulae (V-1) to (V-3) below,

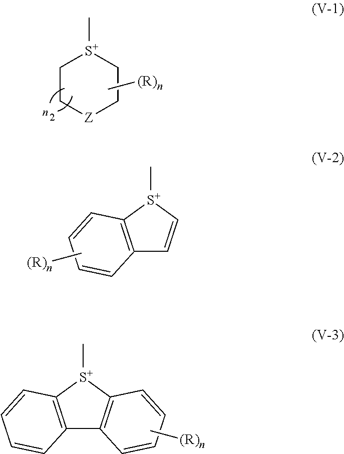

each of n₁ and n₂ independently is 0 or 1;

each of X and Z is any of —CH₂—, —CR₂₁═CR₂₂—, —NR₂₃—, —S— and —O—, in which each of R₂₁, R₂₂ and R₂₃ independently represents a hydrogen atom, a substituted or unsubstituted alkyl group, a cycloalkyl group or an alkoxy group;

R₂₄ represents a substituted or unsubstituted aryl group;

each of R₂₅ and R₂₆ independently represents a hydrogen atom, a substituted or unsubstituted alkyl group or a cycloalkyl group, provided that R₂₅ and R₂₆ may be connected to each other to thereby form a ring; and

(R)ₙ represents a substituent.

[3] The actinic-ray- or radiation-sensitive resin composition according to item [1] or [2], further comprising (C) any of compounds of general formula (2) below,

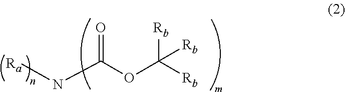

in which

Ra, or each of Ra's independently, represents a hydrogen atom, an alkyl group, a cycloalkyl group, an aryl group or an aralkyl group, provided that when n is 2, two Ra's may be identical to or different from each other, and two Ra's may be bonded to each other to thereby form a heterocyclic hydrocarbon group or a derivative thereof in cooperation with the nitrogen atom to which Ra is bonded;

each of Rb's independently represents a hydrogen atom, an alkyl group, a cycloalkyl group, an aryl group or an aralkyl group, provided that a plurality of Rb's may be bonded to each other to thereby form an alicyclic hydrocarbon group, an aromatic hydrocarbon group, a heterocyclic hydrocarbon group or a derivative of any of these; and

n is an integer of 0 to 2, and m is an integer of 1 to 3, provided that n+m=3.

[4] The actinic-ray- or radiation-sensitive resin composition according to any of items [1] to [3], further comprising at least one photoacid generator other than the compounds (A).

[5] The actinic-ray- or radiation-sensitive resin composition according to any of items [1] to [4], wherein the resin (B) further contains at least one repeating unit that when acted on by an acid, is decomposed to thereby realize an increased solubility in an alkali developer, other than the repeating units of general formula (1).

[6] The actinic-ray- or radiation-sensitive resin composition according to any of items [1] to [5], further comprising a hydrophobic resin.

[7] An actinic-ray- or radiation-sensitive film comprising the composition according to any of items [1] to [6].

[8]A method of forming a pattern, comprising forming a film comprising the composition according to any of items [1] to [6], exposing the film to actinic rays or radiation, and developing the film having been exposed to actinic rays or radiation.

[9] The pattern forming method according to item [8], wherein the exposure to actinic rays or radiation is performed by ArF liquid-immersion exposure.

[10]A process for manufacturing an electronic device, comprising the pattern forming method according to item [8] ir [9].

[11] An electronic r device manufactured by the electronic device manufacturing process according to item [10].

The present invention makes it feasible to provide an actinic-ray- or radiation-sensitive resin composition excelling in not only exposure latitude and pattern roughness, such as line width roughness, but also temporal stability. Further, the present invention makes it feasible to provide an actinic-ray- or radiation-sensitive film therefrom and a method of forming a pattern through the use of the composition.

### DESCRIPTION OF EMBODIMENTS

Embodiments of the present invention will be described in detail below.

Herein, the term “group (atomic group)” for which no statement is made as to substitution or nonsubstitution is to be interpreted as including not only one containing no substituent but also one containing a substituent. For example, the term “alkyl group” is to be interpreted as including not only an alkyl group containing no substituent (unsubstituted alkyl group) but also an alkyl group containing a substituent (substituted alkyl group).

Further, herein, the “alkyl group” and “substituted alkyl group” include linear and branched alkyl groups. Similarly, the alkyl group as a constituent of the “alkoxy group” may be linear or branched, and may be a cycloalkyl group.

Still further, in the present invention, the term “actinic rays” or “radiation” means, for example, brightline spectra from a mercury lamp, far ultraviolet represented by an excimer laser, extreme ultraviolet (EUV light), X-rays, particle beams such as electron beams and ion beams, or the like. In the present invention, the term “light” means actinic rays or radiation.

Moreover, herein, the term “exposure to light” unless otherwise specified means not only irradiation with light, such as brightline spectra from a mercury lamp, far ultraviolet represented by an excimer laser, X-rays or extreme ultraviolet (EUV light), but also lithography using particle beams, such as electron beams and ion beams.

The actinic-ray- or radiation-sensitive resin composition of the present invention comprises (A) at least one of compounds (hereinafter also referred to as “compounds (A)” or “photoacid generators (A)”) of general formula (I) below that when exposed to actinic rays or radiation, generate acids, and (B) a resin (hereinafter also referred to as “resin (B)”) containing at least one of repeating units of general formula (1) below, which resin when acted on by an acid, is decomposed to thereby increase its solubility in an alkali developer.

By virtue of the incorporation of compound (A) and resin (B) therein, the actinic-ray- or radiation-sensitive resin composition of the present invention is a composition exhibiting not only enhanced exposure latitude and line width roughness but also enhanced temporal stability.

The components of the composition of the present invention will be described below.

[1] Compound (A)

As mentioned above, the actinic-ray- or radiation-sensitive resin composition of the present invention comprises at least one of compounds (A) of general formula (I) below that when exposed to actinic rays or radiation, generate acids.

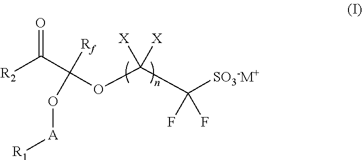

In general formula (I), each of X's independently represents a hydrogen atom, a fluorine atom or a fluorinated alkyl group. Preferably, X is a hydrogen atom, a fluorine atom or a trifluoromethyl group.

R₁ represents a hydrogen atom, a halogen atom, an alkyl group, a mono- or polycycloalkyl group, an alkenyl group, an oxoalkyl group, an aryl group or an aralkyl group. Preferably, the above alkyl group has 1 to 20 carbon atoms, the cycloalkyl group 3 to 20 carbon atoms, each of the alkenyl group and oxoalkyl group 2 to 20 carbon atoms, and each of the aryl group and aralkyl group 6 to 18 carbon atoms.

As a linear alkyl group having 1 to 20 carbon atoms, there can be mentioned, for example, a methyl group, an ethyl group, an n-propyl group, an n-butyl group, an n-pentyl group, an n-hexyl group, an n-heptyl group, an n-octyl group, an n-nonyl group, an n-decyl group or the like. As a substituted alkyl group, there can be mentioned, for example, a linear alkyl group containing a cycloalkyl group, such as a cyclopentylmethyl group, a cyclopentylethyl group, a cyclohexylmethyl group, a cyclohexylethyl group, an adamantylmethyl group, an adamantylethyl group, a norbornylmethyl group, a norbornylethyl group, a camphoroylmethyl group, a camphoroylethyl group or the like.

As a branched alkyl group having 3 to 20 carbon atoms, there can be mentioned, for example, an i-propyl group, a sec-butyl group, an i-butyl group, a t-butyl group or the like.

As a cycloalkyl group having 3 to 20 carbon atoms, there can be mentioned, for example, a cyclopentyl group, a cyclohexyl group, an adamantyl group, a methylcyclopentyl group, a methylcyclohexyl group, a methyladamantyl group, an ethylcyclopentyl group, an ethylcyclohexyl group, an ethyladamantyl group, a norbornyl group, a camphoroyl group or the like.

As an alkenyl group having 2 to 20 carbon atoms, there can be mentioned, for example, a vinyl group, a 1-methylethenyl group, an allyl group, a 3-butenyl group, a 1-methylallyl group, a 2-methylallyl group, a 4-pentenyl group, a 5-hexenyl group or the like.

As an oxoalkyl group having 2 to 20 carbon atoms, there can be mentioned, for example, a 2-oxo-propyl group, a 2-oxo-butyl group, a 2-oxo-3-methyl-butyl group, a 2-oxo-pentyl group, a 2-oxo-3-methyl-pentyl group, a 2-oxo-4-methyl-pentyl group, a 2-oxo-3-ethyl-pentyl group, a 2-oxo-hexyl group, a 2-oxo-3-methyl-hexyl group, a 2-oxo-4-methyl-hexyl group, a 2-oxo-5-methyl-hexyl group, a 2-oxo-3-ethyl-hexyl group, a 2-oxo-4-ethyl-hexyl group, a 2-oxo-heptyl group, a 2-oxo-3-methyl-heptyl group, a 2-oxo-4-methyl-heptyl group, a 2-oxo-5-methyl-heptyl group, a 2-oxo-6-methyl-heptyl group, a 2-oxo-3-ethyl-heptyl group, a 2-oxo-4-ethyl-heptyl group, a 2-oxo-5-ethyl-heptyl group, a 2-oxo-3-propyl-heptyl group, a 2-oxo-4-propyl-heptyl group, a 2-oxo-octyl group, a 2-oxo-3-methyl-octyl group, a 2-oxo-4-methyl-octyl group, a 2-oxo-5-methyl-octyl group, a 2-oxo-6-methyl-octyl group, a 2-oxo-7-methyl-octyl group, a 2-oxo-3-ethyl-octyl group, a 2-oxo-4-ethyl-octyl group, a 2-oxo-5-ethyl-octyl group, a 2-oxo-cyclopentyl group, a 2-oxo-cyclohexyl group, a 2-oxo-cycloheptyl group, a 2-oxo-cyclopropylmethyl group, a 2-oxo-methylcyclohexyl group, a 2-oxo-cyclohexylmethyl group, a 2-oxo-norbornyl group, a 2-oxo-tricyclo[5.2.1.0^{2,6}]decyl group, a 2-cyclo-oxotetracyclo[4.4.0.1^{2,5}1^{7,10}]dodecyl group, a 2-oxo-bornyl group or the like.

As an aryl group having 6 to 18 carbon atoms, there can be mentioned, for example, aphenyl group, an o-tolyl group, am-tolyl group, a p-tolyl group, a p-hydroxyphenyl group, a p-trifluoromethylphenyl group, a 1-naphthyl group, a 1-anthracenyl group or the like.

As an aralkyl group having 6 to 18 carbon atoms, there can be mentioned, for example, a benzyl group, a 1-phenylethyl group, a 2-phenylethyl group, a 1-phenylpropyl group, a 2-phenylpropyl group, a 3-phenylpropyl group, a 1-naphthylmethyl group, a 2-naphthylmethyl group or the like.

The hydrogen atom on each of the carbon atoms as constituents of this R₁ may be replaced by a substituent. As the substituent, there can be mentioned, for example, a halogen atom, such as a fluorine atom, a chlorine atom, a bromine atom or an iodine atom, a hydroxyl group, a thiol group, an aryl group, an organic group containing a heteroatom, such as a halogen atom, an oxygen atom, a nitrogen atom, a sulfur atom, a phosphorus atom or a silicon atom, or the like. Further, examples of the substituents include a ketone group resulting from replacement of two hydrogen atoms on any identical carbon of R₁ by one oxygen atom. The number of substituents introduced is not limited as long as structurally permitted.

It is preferred for R₁ to be a bulky functional group. For example, R₁ is a cyclopentyl group, a cyclohexyl group, an adamantyl group, a methylcyclopentyl group, a methylcyclohexyl group, a methyladamantyl group, an ethylcyclopentyl group, an ethylcyclohexyl group, an ethyladamantyl group, a norbornyl group, a camphoroyl group, a cyclopentylmethyl group, a cyclopentylethyl group, a cyclohexylmethyl group, a cyclohexylethyl group, an adamantylmethyl group, an adamantylethyl group, a norbornylmethyl group, a norbornylethyl group, a camphoroylmethyl group, a camphoroylethyl group or the like. Among these, a cyclohexyl group and an adamantyl group are preferred.

R₂ is either R₃O or R₄R₅N. Each of R₃, R₄ and R₅ independently represents a hydrogen atom, an alkyl group, a mono- or polycycloalkyl group, an alkenyl group, an oxoalkyl group, an aryl group, an aralkyl group or a lactone group. When R₂ is R₄R₅N, R₄ and R₅ may be bonded to each other to thereby form a ring structure in cooperation with the nitrogen atom to which R₄ and R₅ are bonded. It is preferred for the thus formed ring structure to be comprised of 3 to 18 members.

Preferably, the above alkyl group has 1 to 20 carbon atoms, the cycloalkyl group 3 to 20 carbon atoms, each of the alkenyl group and oxoalkyl group 2 to 20 carbon atoms, each of the aryl group and aralkyl group 6 to 18 carbon atoms, and the lactone group 3 to 30 carbon atoms. The lactone group may be monocyclic or polycyclic.

Particular examples of the alkyl groups each having 1 to 20 carbon atoms, cycloalkyl groups each having 3 to 20 carbon atoms, alkenyl and oxoalkyl groups each having 2 to 20 carbon atoms and aryl and aralkyl groups each having 6 to 18 carbon atoms represented by R₃, R₄ and R₅ are the same as set forth above in connection with R₁.

The lactone group having 3 to 30 carbon atoms is a monovalent group resulting from the removal of one hydrogen atom from the corresponding lactone. This lactone may be monocyclic or polycyclic. As such, there can be mentioned, for example, γ-butyrolactone, γ-valerolactone, angelica-lactone, γ-hexalactone, γ-heptalactone, γ-octalactone, γ-nonalactone, 3-methyl-4-octanolide (whisky lactone), γ-decalactone, γ-undecalactone, γ-dodecalactone, γ-jasmolactone (7-decenolactone), δ-hexalactone, 4,6,6(4,4,6)-trimethyltetrahydropyran-2-one, δ-octalactone, δ-nonalactone, δ-decalactone, δ-2-decenolactone, δ-undecalactone, δ-dodecalactone, δ-tridecalactone, δ-tetradecalactone, lactoscatone, ε-decalactone, ε-dodecalactone, cyclohexyllactone, jasmine lactone, cis-jasmone lactone or methyl-γ-decalactone. Further, as the lactone group, there can be mentioned the following. The dotted line shows a position of bonding.

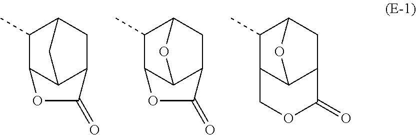

A 3 to 18-membered heterocycle formed by R₄ and R₅ is, for example, the following. The dotted line shows a position of bonding.

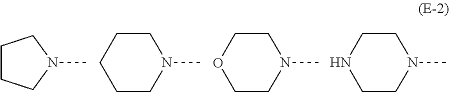

The hydrogen atom on each of the carbon atoms as constituents of R₃, R₄ and R₅ above may be replaced by a substituent. Examples of such substituents are the same as set forth above in connection with R₁.

Preferred groups represented by R₂ are as shown below. The dotted line shows a position of bonding.

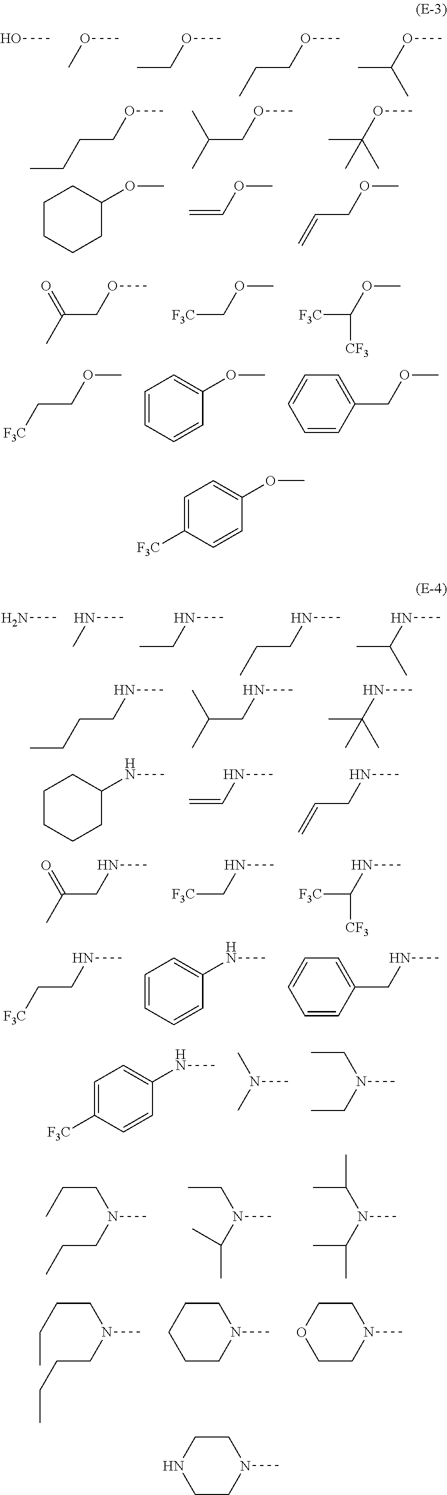

R_{f} represents a hydrogen atom, a fluorine atom or a fluorinated alkyl group. R_{f} is preferably a perfluoroalkyl group, more preferably a trifluoromethyl group.

A is any of groups of formulae below;

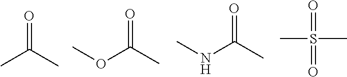

M⁺ represents a monovalent cation. The monovalent cation represented by M is preferably a proton (H⁺), a metal cation, such as a lithium ion, a sodium ion or a potassium ion, or any of onium ions, such as ammonium ions, sulfonium ions, iodonium ions or phosphonium ions.

It is more preferred for M⁺ to be any of sulfonium cations of general formulae (II) and (III) below.

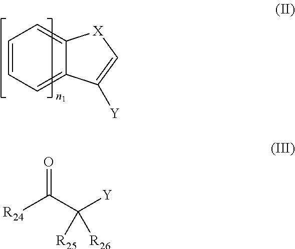

In general formulae (II) and (III),

Y represents any of structures of general formulae (V-1) to (V-3) below.

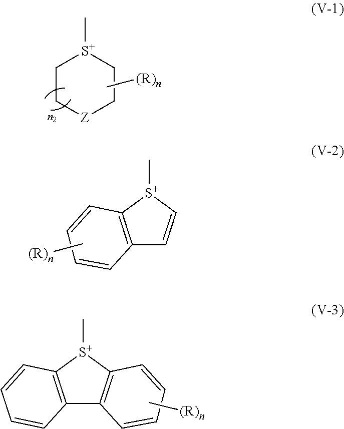

In the formulae, each of n₁ and n₂ independently is 0 or 1.

Each of X and Z represents —CH₂—, —CR₂₁═CR₂₂—, —NR₂₃—, —S— or —O—. Each of R₂₁, R₂₂ and R₂₃ independently represents a hydrogen atom, a substituted or unsubstituted alkyl group, a cycloalkyl group or an alkoxy group.

R₂₄ represents a substituted or unsubstituted aryl group.

Each of R₂₅ and R₂₆ independently represents a hydrogen atom, a substituted or unsubstituted alkyl group or a cycloalkyl group. R₂₅ and R₂₆ may be connected to each other to thereby form a ring.

(R)ₙ represents a substituent.

In general formula (I), n is an integer of 1 to 10, preferably 1 to 6.

In general formula (I), the structure of —(CX₂)ₙ— is a linear alkylene group having 1 to 10 carbon atoms, wherein any of hydrogen atoms thereof is replaced by a fluorine atom. The structure of —(CX₂)ₙ— is preferably —(CH₂)ₚ—(CF₂)_{q}—. In the formula, p is an integer of 0 to 10, and q is an integer of 0 to 8. Preferably, p is an integer of 0 to 6, and q an integer of 0 to 5. More preferably, p is an integer of 1 to 4, and q 0 or 1.

The compounds of general formula (I) are preferably those of general formula (I′) below.

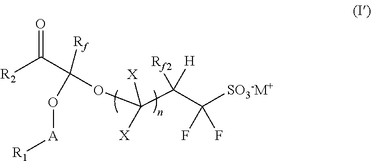

In general formula (I′), X, R₁, R₂, R_{f}, A, n and M⁺ are as defined above in connection with general formula (I).

R_{f2} represents a hydrogen atom, a fluorine atom or a trifluoromethyl group.

As the anion structures of the compounds of general formula (I), there can be mentioned not only the anion structures shown in [Chem 19] to [Chem 32] in PCT International Publication No. 2012/056901 (pamphlet) but also the following structures.

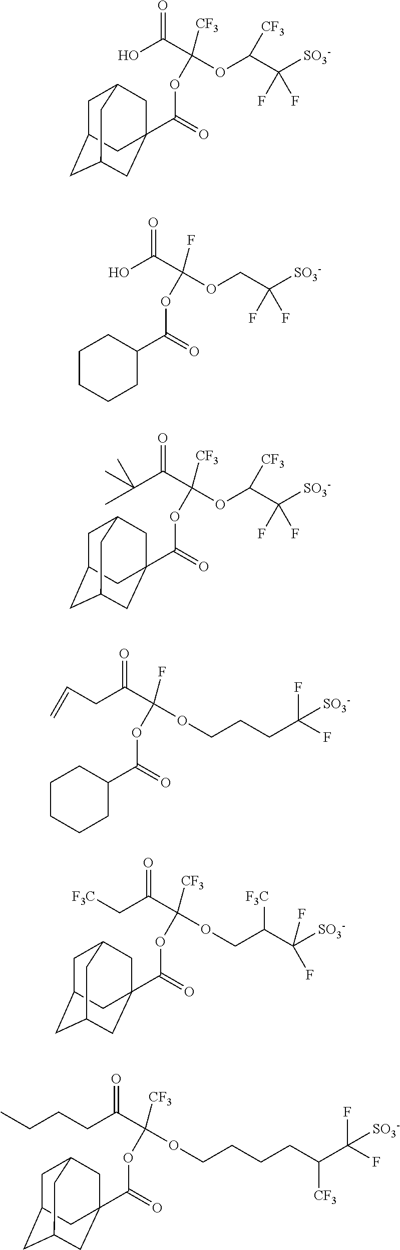

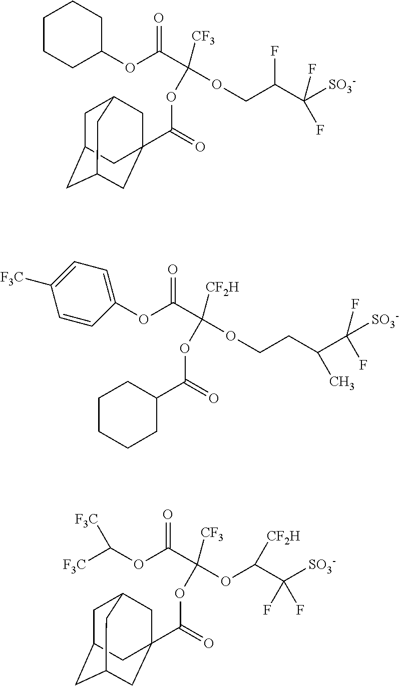

The content of compound (A) in the composition of the present invention, based on the total solids of the composition, is preferably in the range of 0.1 to 30 mass %, more preferably 3 to 25 mass % and further more preferably 7 to 20 mass %.

The composition of the present invention may contain two or more of compounds (A), and also may contain a compound (A) plus a photoacid generator (hereinafter also referred to as compound (A′)) other than the compounds (A). When the composition of the present invention contains two or more photoacid generators, it is preferred for the total content of photoacid generators to fall within the above range.

As the compound (A′), use can be made of a member appropriately selected from among a photoinitiator for photocationic polymerization, a photoinitiator for photoradical polymerization, a photo-achromatic agent and photo-discoloring agent for dyes, any of generally known compounds that when exposed to actinic rays or radiation, generate acids, employed in microresists, etc., and mixtures thereof.

For example, there can be mentioned a diazonium salt, a phosphonium salt, a sulfonium salt, an iodonium salt, an imide sulfonate, an oxime sulfonate, diazosulfone, disulfone or o-nitrobenzyl sulfonate.

Further, use can be made of a compound resulting from the introduction of such a group or compound capable of generating an acid when exposed to actinic rays or radiation in a principal chain or side chain of polymer, for example, any of compounds described in U.S. Pat. No. 3,849,137, German Patent 3914407, Jpn. Pat. Appln. KOKAI Publication No. (hereinafter referred to as JP-A-) S63-26653, JP-A's S55-164824, S62-69263, S63-146038, S63-163452, S62-153853 and S63-146029, etc.

Still further, use can be made of compounds capable of generating acids when exposed to light, described in U.S. Pat. No. 3,779,778, European Patent 126,712, etc.

As preferred compounds (A′), there can be mentioned compounds of general formulae (ZI), (ZII) and (ZIII) below.

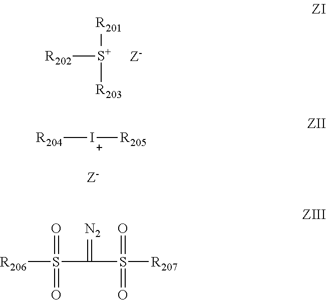

In general formula (ZI) above,

each of R₂₀₁, R₂₀₂ and R₂₀₃ independently represents an organic group.

The number of carbon atoms of each of the organic groups represented by R₂₀₁, R₂₀₂ and R₂₀₃ is generally in the range of 1 to 30, preferably 1 to 20.

Any two of R₂₀₁ to R₂₀₃ may be bonded to each other to thereby form a ring structure, and the ring within the same may contain an oxygen atom, a sulfur atom, an ester bond, an amide bond or a carbonyl group. As a group formed by the mutual bonding of two of R₂₀₁ to R₂₀₃, there can be mentioned an alkylene group (for example, a butylene group or a pentylene group).

Z⁻ represents a nonnucleophilic anion.

As the nonnucleophilic anion represented by Z⁻, there can be mentioned, for example, a sulfonate anion, a carboxylate anion, a sulfonylimide anion, a bis(alkylsulfonyl)imide anion, a tris(alkylsulfonyl)methyl anion or the like.

The nonnucleophilic anion is an anion whose capability of inducing a nucleophilic reaction is extremely low, and is an anion capable of inhibiting any temporal decomposition by intramolecular nucleophilic reaction. This anion enhances the temporal stability of the resist.

As the sulfonate anion, there can be mentioned, for example, an aliphatic sulfonate anion, an aromatic sulfonate anion, a camphor sulfonate anion or the like.

As the carboxylate anion, there can be mentioned, for example, an aliphatic carboxylate anion, an aromatic carboxylate anion, an aralkyl carboxylate anion or the like.

The aliphatic moiety in the aliphatic sulfonate anion may be an alkyl group or a cycloalkyl group, being preferably an alkyl group having 1 to 30 carbon atoms or a cycloalkyl group having 3 to 30 carbon atoms. As such, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group and the like.

As a preferred aromatic group in the aromatic sulfonate anion, there can be mentioned an aryl group having 6 to 14 carbon atoms, for example, a phenyl group, a tolyl group, a naphthyl group or the like.

Substituents may be introduced in the alkyl group, cycloalkyl group and aryl group in the aliphatic sulfonate anion and aromatic sulfonate anion. As the substituents introducible in the alkyl group, cycloalkyl group and aryl group in the aliphatic sulfonate anion and aromatic sulfonate anion, there can be mentioned, for example, a nitro group, a halogen atom (fluorine atom, chlorine atom, bromine atom or iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. With respect to the aryl group or ring structure in each of these groups, an alkyl group (preferably having 1 to 15 carbon atoms) can further be mentioned as a substituent.

As the aliphatic moiety in the aliphatic carboxylate anion, there can be mentioned the same alkyl group or cycloalkyl group as set forth above in connection with the aliphatic sulfonate anion.

As the aromatic group in the aromatic carboxylate anion, there can be mentioned the same aryl group as set forth above in connection with the aromatic sulfonate anion.

As a preferred aralkyl group in the aralkyl carboxylate anion, there can be mentioned an aralkyl group having 6 to 12 carbon atoms, for example, a benzyl group, a phenethyl group, a naphthylmethyl group, a naphthylethyl group, a naphthylbutyl group or the like.

Substituents may be introduced in the alkyl group, cycloalkyl group, aryl group and aralkyl group in the aliphatic carboxylate anion, aromatic carboxylate anion and aralkyl carboxylate anion. As the substituents introducible in the alkyl group, cycloalkyl group, aryl group and aralkyl group in the aliphatic carboxylate anion, aromatic carboxylate anion and aralkyl carboxylate anion, there can be mentioned, for example, the same halogen atom, alkyl group, cycloalkyl group, alkoxy group, alkylthio group, etc. as set forth above in connection with the aromatic sulfonate anion.

As the sulfonylimide anion, there can be mentioned, for example, a saccharin anion.

The alkyl group in the bis(alkylsulfonyl)imide anion and tris(alkylsulfonyl)methyl anion is preferably an alkyl group having 1 to 5 carbon atoms. As such, there can be mentioned, for example, a methyl group, an ethyl group, a propyl group, an isopropyl group, an n-butyl group, an isobutyl group, a sec-butyl group, a pentyl group, a neopentyl group or the like. As substituents introducible in these alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group and the like. Among these, an alkyl group substituted with a fluorine atom is preferred.

As other nonnucleophilic anions, there can be mentioned, for example, phosphorus fluoride, boron fluoride, antimony fluoride and the like.

The nonnucleophilic anion represented by Z is preferably an aliphatic sulfonate anion substituted, at its α-position of sulfonic acid, with a fluorine atom; an aromatic sulfonate anion substituted with a fluorine atom or a group containing a fluorine atom; a bis(alkylsulfonyl)imide anion whose alkyl group is substituted with a fluorine atom; or a tris(alkylsulfonyl)methide anion whose alkyl group is substituted with a fluorine atom. More preferably, the nonnucleophilic anion is a perfluorinated aliphatic sulfonate anion having 4 to 8 carbon atoms, or a benzene sulfonate anion containing a fluorine atom. Further more preferably, the nonnucleophilic anion is a nonafluorobutanesulfonate anion, a perfluorooctanesulfonate anion, a pentafluorobenzenesulfonate anion or a 3,5-bis(trifluoromethyl)benzenesulfonate anion.

Use can be made of a compound containing a plurality of structures of general formula (ZI). For example, use can be made of a compound with a structure in which at least one of R₂₀₁ to R₂₀₃ of a compound expressed by general formula (ZI) is bonded to at least one of R₂₀₁ to R₂₀₃ of another compound expressed by general formula (ZI).

Especially preferred examples of the acid generators usable in combination with the acid generator according to the present invention are as follows.

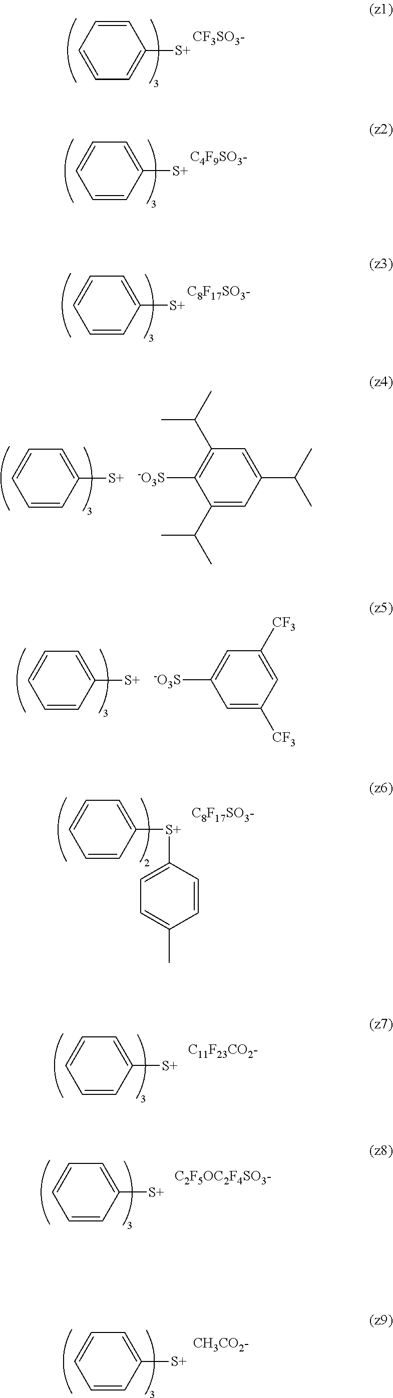

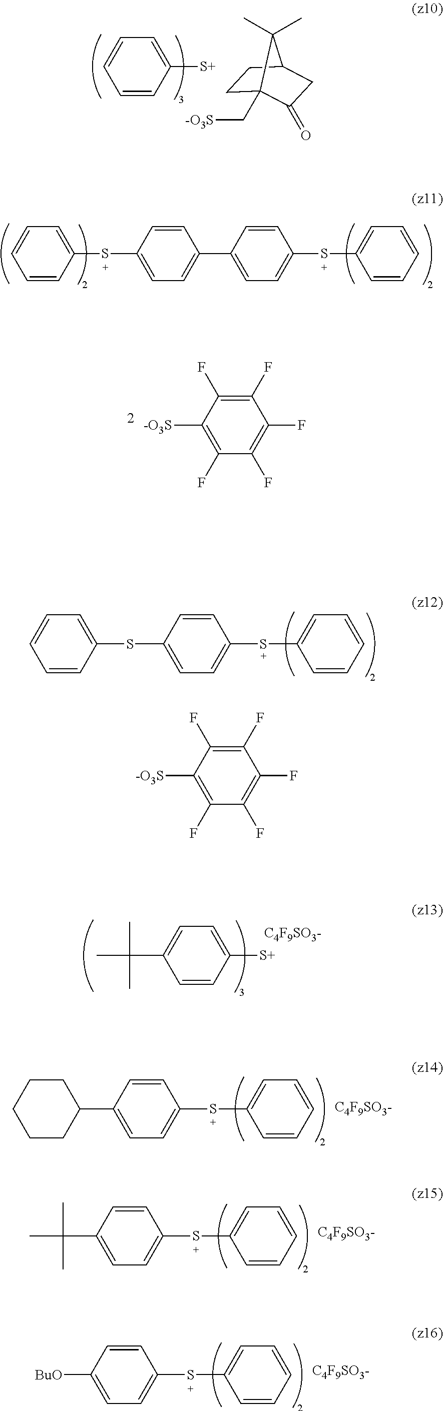

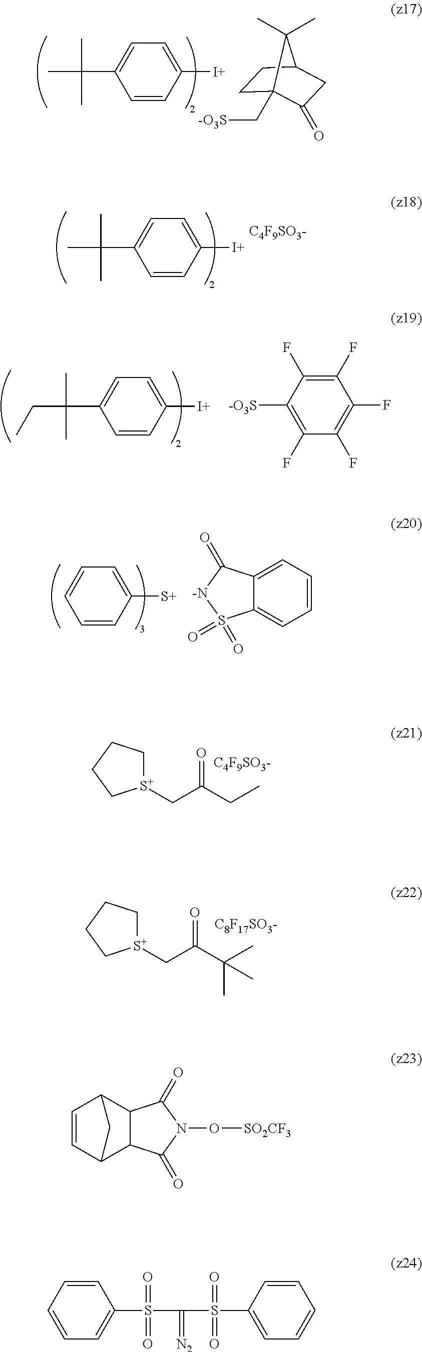

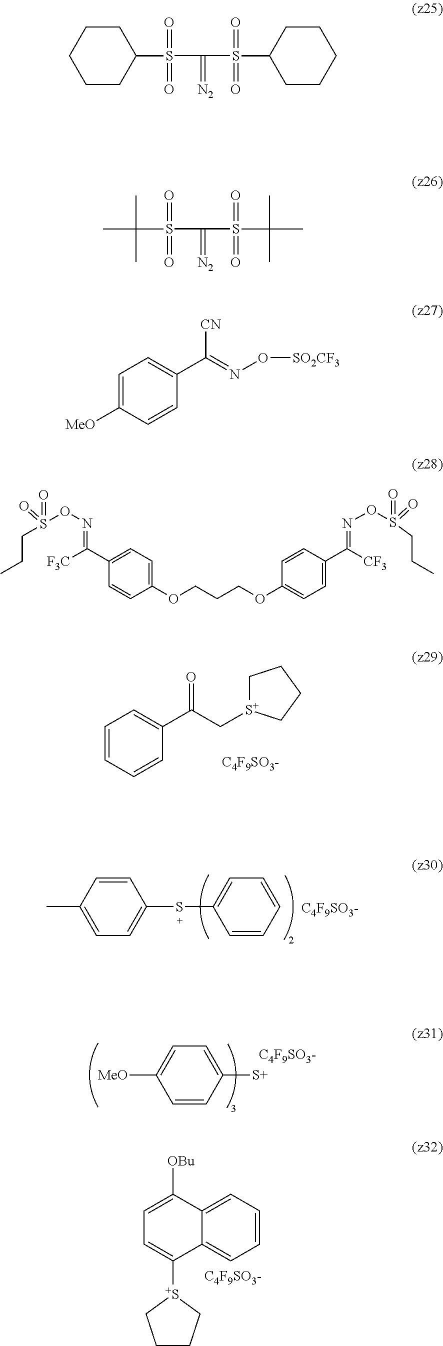

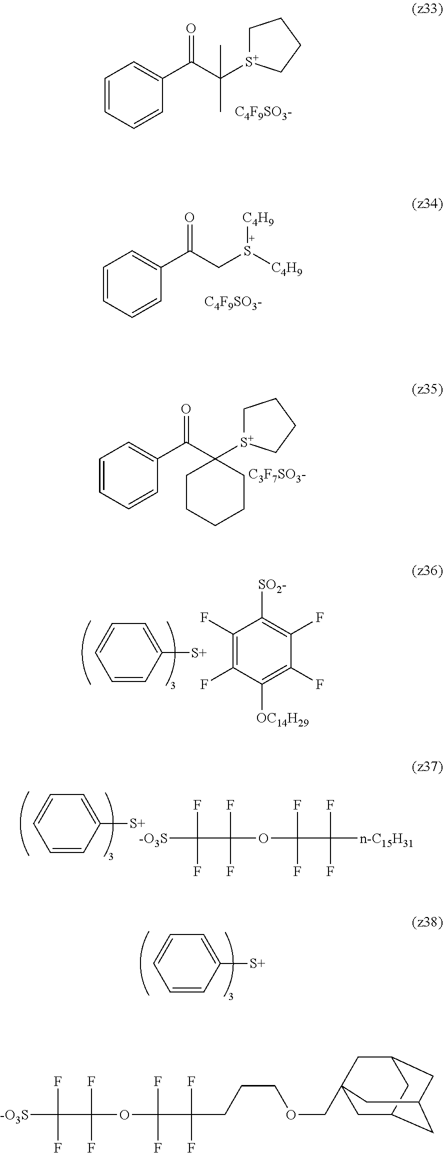

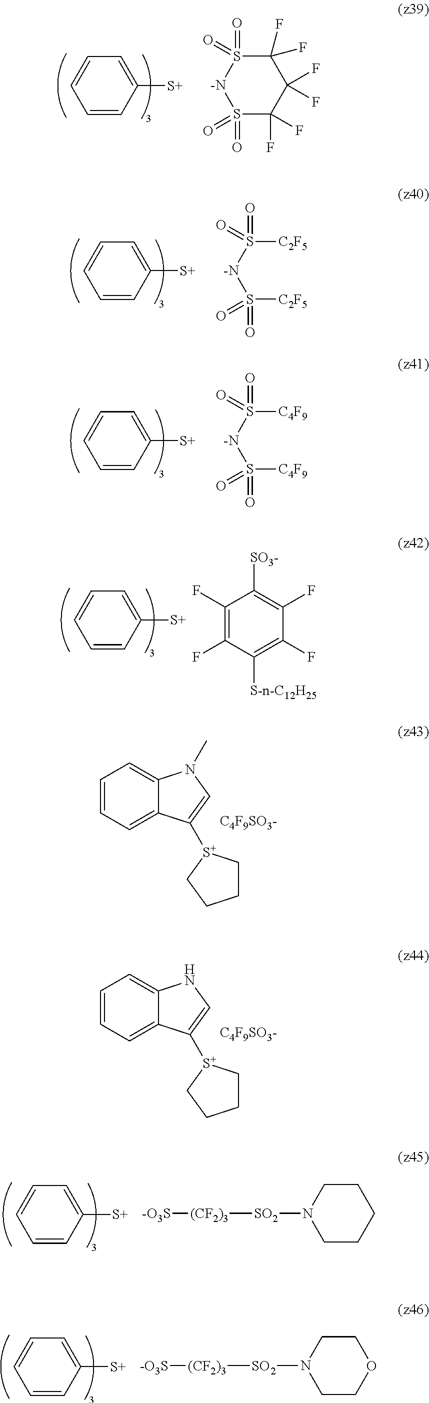

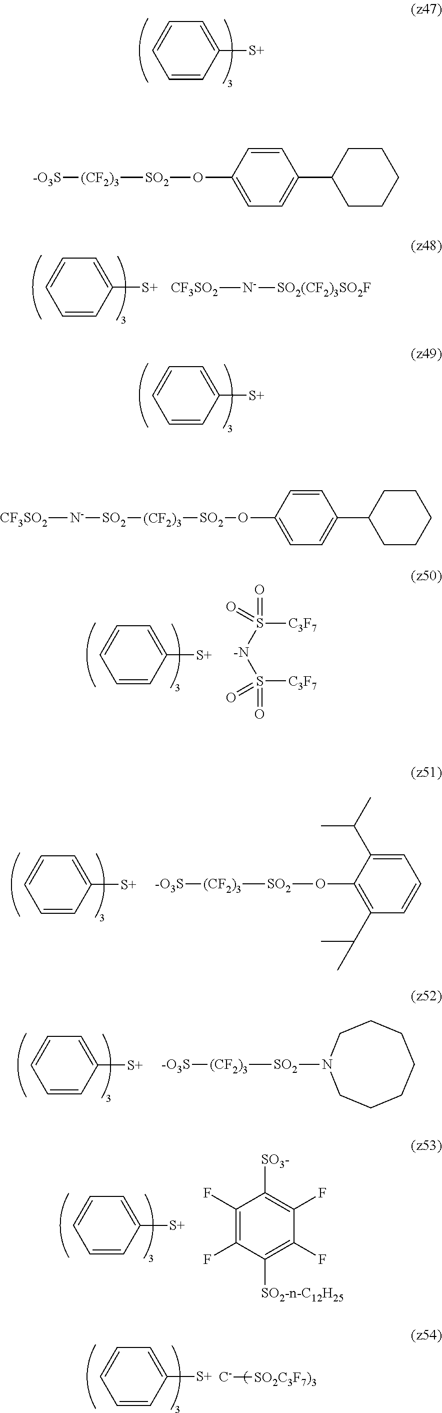

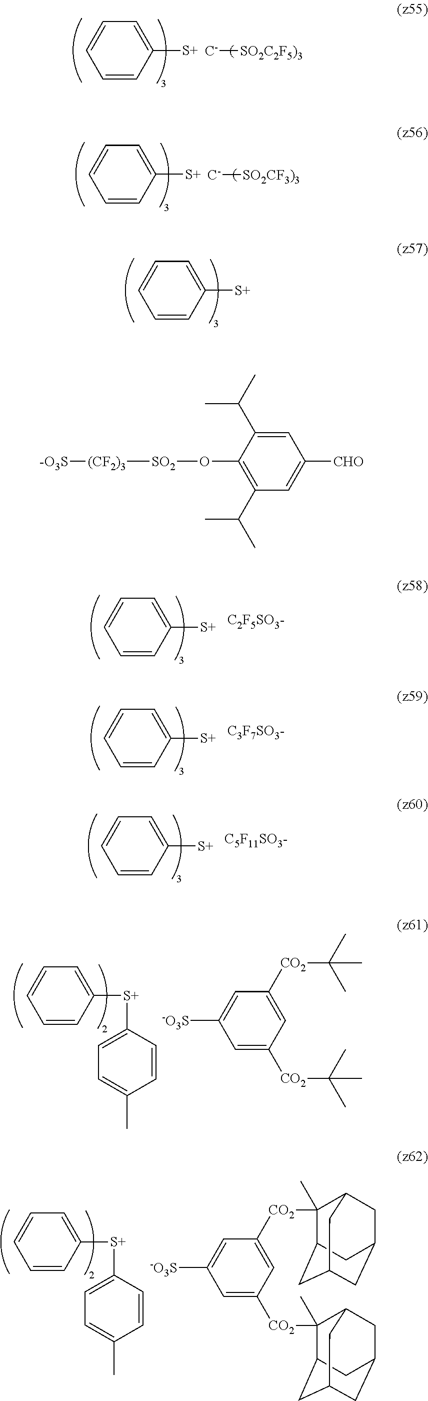

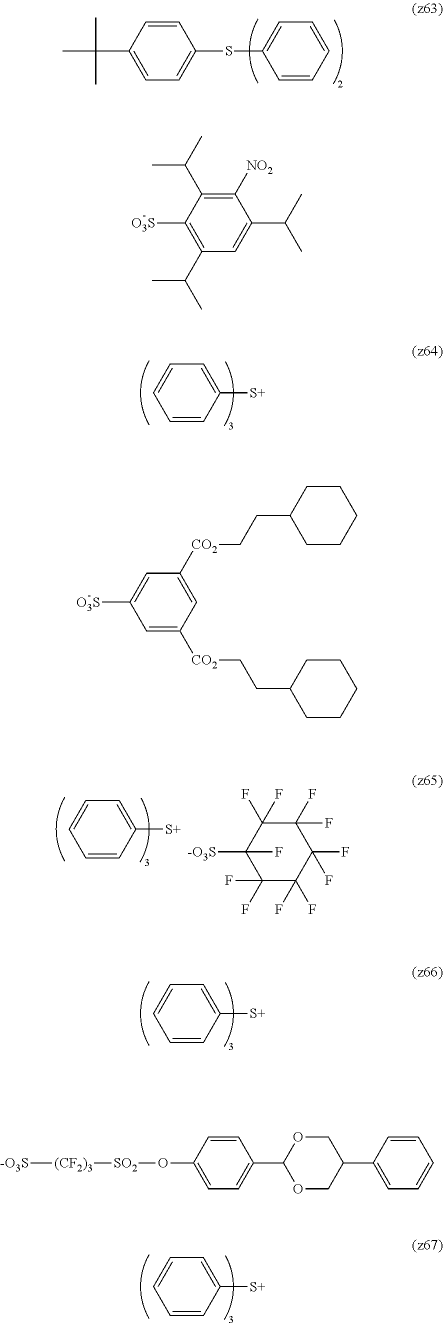

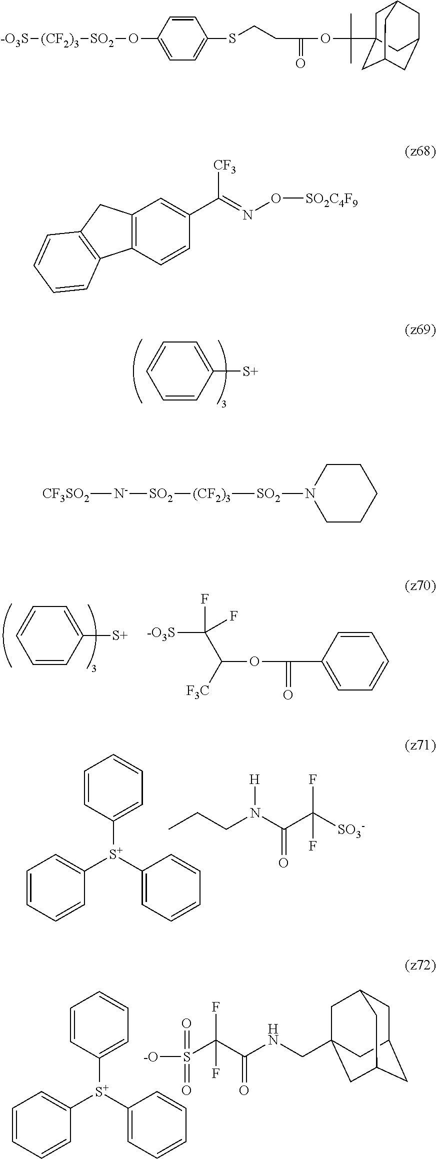

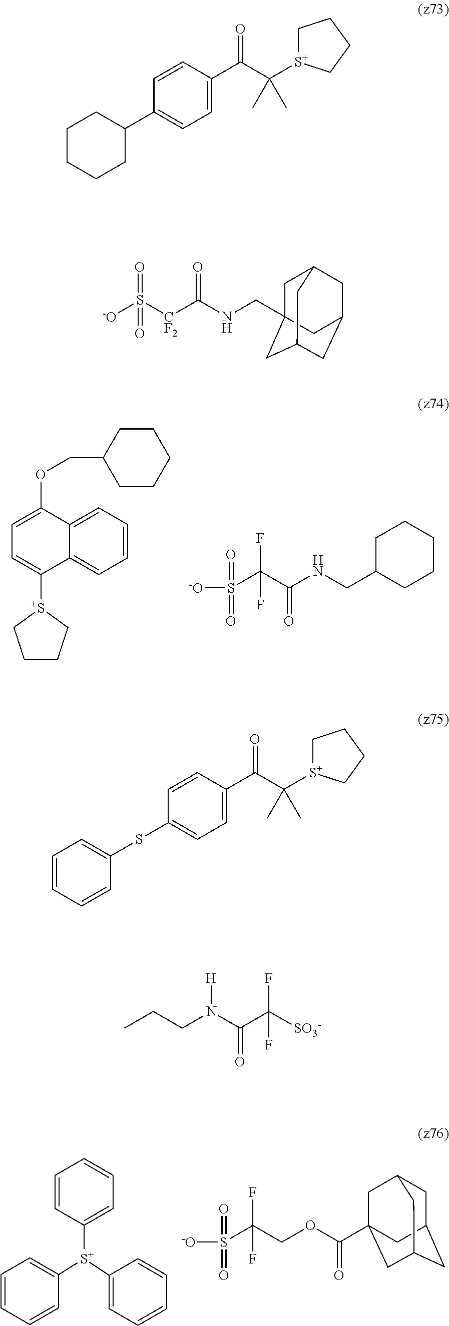

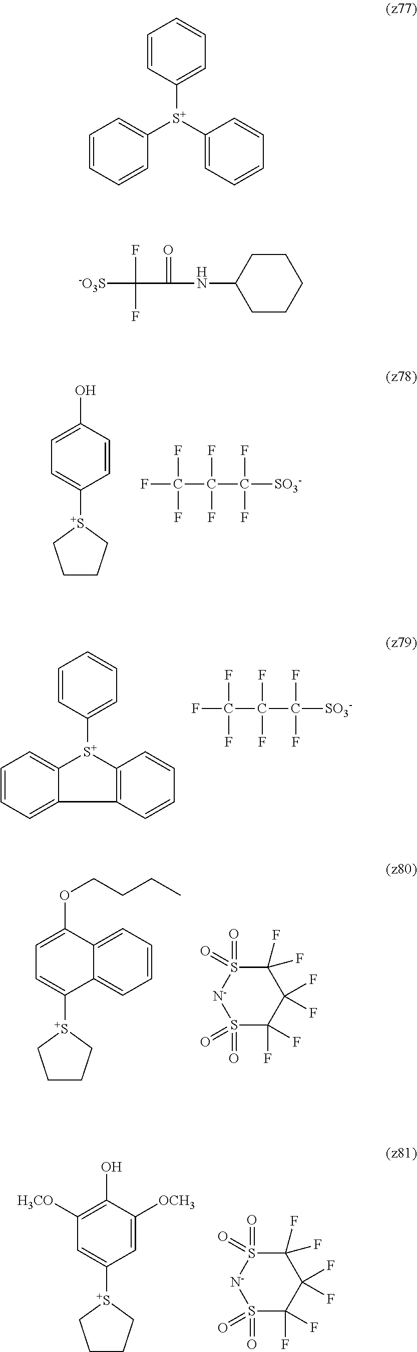

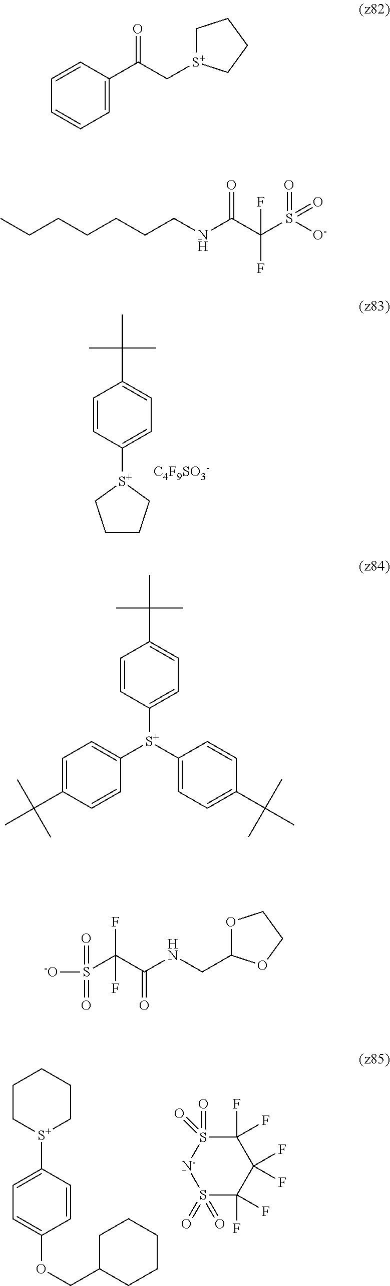

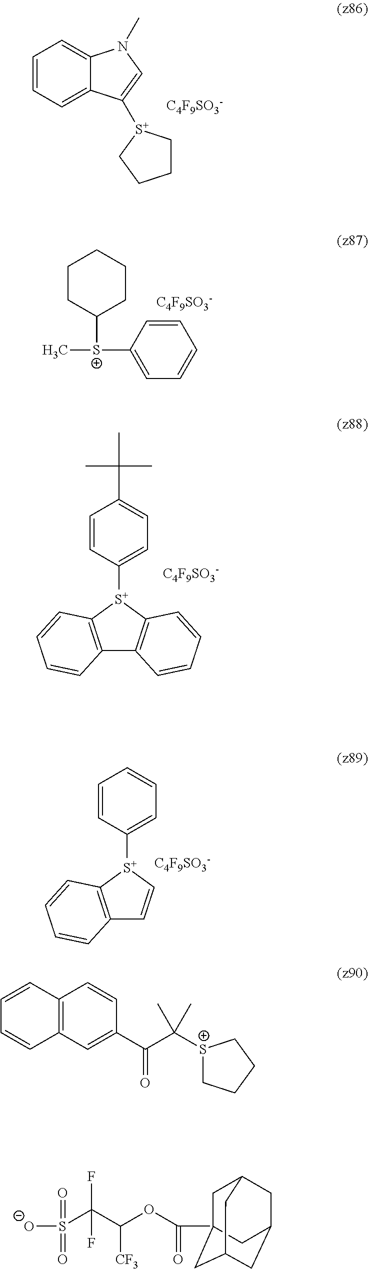

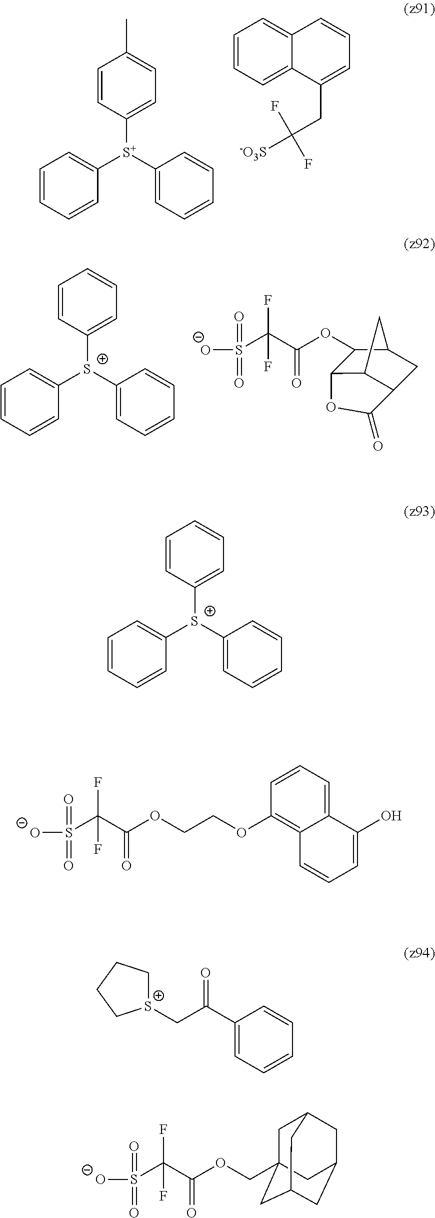

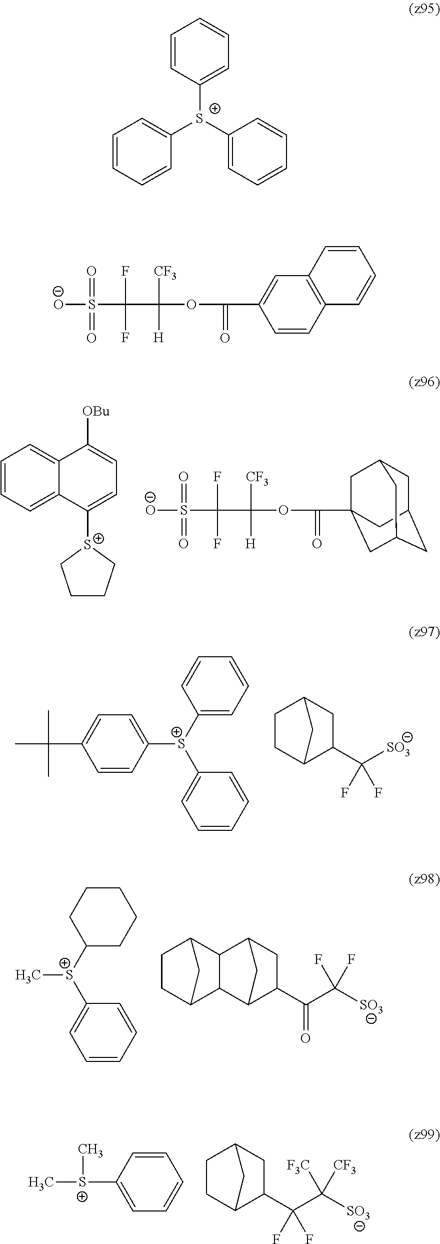

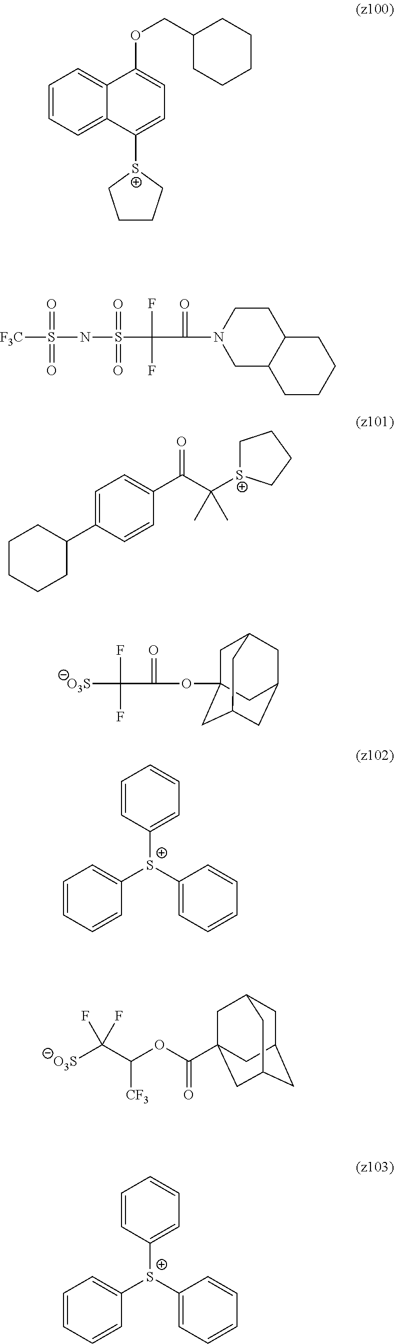

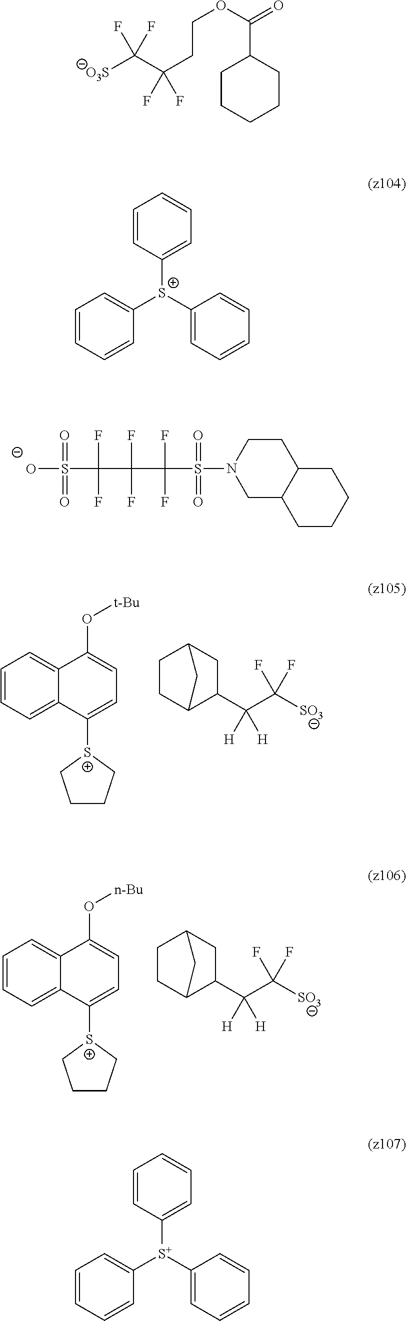

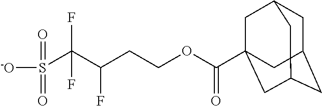

By virtue of the use of these compounds, the transmission of ArF light of 193 nm wavelength through the formed film can be held high. For example, when the film thickness is 100 nm, the transmission of ArF light of 193 nm wavelength through the film can be in the range of 60 to 85%. High transmission of ArF light is advantageous in realizing favorable performance in the patterning with ArF light.

The transmission of light of 193 nm wavelength can be calculated from the absorbance determined in, for example, the following manner. Namely, an actinic-ray- or radiation-sensitive resin composition is applied onto a quartz glass substrate by spin coating, and prebaked at 100° C. to thereby form a 100 nm thick film. The absorbance of light of 193 nm wavelength in the film is measured by means of, for example, an ellipsometer EPM-222 (manufactured by J.A. Woollam Co., Inc.), and the transmission is calculated from the absorbance.

Based on the total amount of compounds (A′), compounds of general formula (1-1) or (1-2) below are preferably contained in an amount of 50 to 100 mass %, more preferably 80 to 100 mass % and most preferably 90 to 100 mass %.

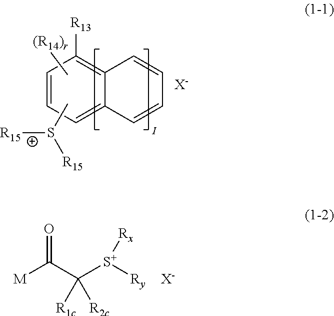

In general formula (1-1),

R₁₃ represents a hydrogen atom, a fluorine atom, a hydroxyl group, an alkyl group, a cycloalkyl group, an alkoxy group, an alkoxycarbonyl group, a group with a mono- or polycycloalkyl skeleton, or an alkylene oxide chain.

R₁₄, or each of a plurality of R₁₄s independently, represents an alkyl group, a cycloalkyl group, an alkoxy group, an alkoxycarbonyl group, an alkylcarbonyl group, an alkylsulfonyl group, a cycloalkylsulfonyl group, a group with a mono- or polycycloalkyl skeleton, or an alkylene oxide chain.

Each of R₁₅s independently represents an alkyl group, a cycloalkyl group or a naphthyl group, provided that two R₁₅s may be bonded to each other to thereby form a ring;

l is an integer of 0 to 2;

r is an integer of 0 to 8.

X⁻ represents a nonnucleophilic anion.

In general formula (1-2),

M represents an alkyl group, a cycloalkyl group, an aryl group or a benzyl group, provided that when a cyclic structure is contained, an oxygen atom, a sulfur atom, an ester bond, an amide bond or a carbon to carbon double bond may be introduced in the cyclic structure.

Each of R_{1c} and R_{2c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, an alkoxycarbonylalkyl group, an allyl group or a vinyl group.

Rₓ and R_{y} may be bonded to each other to thereby form a ring, and at least two of M, R_{1c} and R_{2c} may be bonded to each other to thereby form a ring, which ring in its structure may contain a carbon to carbon double bond. X⁻ represents a nonnucleophilic anion.

First, general formula (1-1) will be described in detail below.

Each of the alkyl groups represented by R₁₃, R₁₄ and R₁₅ in general formula (1-1) is linear or branched, preferably having 1 to 10 carbon atoms. As such, there can be mentioned a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group and the like. Of these alkyl groups, amethyl group, an ethyl group, an n-butyl group, a t-butyl group and the like are preferred.

As the cycloalkyl groups represented by R₁₃, R₁₄ and R₁₅, there can be mentioned cyclopropyl, cyclobutyl, cyclopentyl, cyclohexyl, cycloheptyl, cyclooctyl, cyclododecanyl, cyclopentenyl, cyclohexenyl, cyclooctadienyl, adamantyl groups and the like. Of these, cyclopropyl, cyclopentyl, cyclohexyl and cyclooctyl are especially preferred.

The alkoxy groups represented by R₁₃ and R₁₄ may be linear, branched or cyclic, and preferably each have 1 to 10 carbon atoms. As such, there can be mentioned, for example, a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, a cycloheptyloxy group, a cyclooctyloxy group and the like. Of these alkoxy groups, a methoxy group, an ethoxy group, an n-propoxy group, an n-butoxy group and the like are preferred. The alkoxycarbonyl groups represented by R₁₃ and R₁₄ may be linear or branched, and preferably each have 2 to 11 carbon atoms.

As such, there can be mentioned, for example, a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group and the like. Of these alkoxycarbonyl groups, a methoxycarbonyl group, an ethoxycarbonyl group, an n-butoxycarbonyl group and the like are preferred.

As the groups with a mono- or polycycloalkyl skeleton represented by R₁₃ and R₁₄, there can be mentioned, for example, a mono- and polycycloalkyloxy group and an alkoxy group containing a mono- and polycycloalkyl group. Substituents may further be introduced in these groups.

Each of the mono- and polycycloalkyloxy groups represented by R₁₃ and R₁₄ preferably has 7 or more carbon atoms in total, more preferably 7 to 15 carbon atoms in total. Preferably, a monocycloalkyl skeleton is contained therein. The monocycloalkyloxy group having 7 or more carbon atoms in total refers to a monocycloalkyloxy group comprised of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, arbitrarily substituted with an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group or the like, wherein the sum of carbon atoms thereof including those of any arbitrary substituents introduced in the cycloalkyl group is 7 or greater.

As the polycycloalkyloxy group having 7 or more carbon atoms in total, there can be mentioned a norbornyloxy group, a tricyclodecanyloxy group, a tetracyclodecanyloxy group, an adamantyloxy group or the like. The above-mentioned substituents may be introduced in these.

Each of the alkoxy groups with a mono- and polycycloalkyl skeleton represented by R₁₃ and R₁₄ preferably has 7 or more carbon atoms in total, more preferably 7 to 15 carbon atoms in total.

The alkoxy group with a monocycloalkyl skeleton is preferred. The alkoxy group with a monocycloalkyl skeleton, which has 7 or more carbon atoms in total, refers to an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with any of the above-mentioned optionally substituted monocycloalkyl groups, wherein the sum of carbon atoms thereof including those of substituents is 7 or greater. For example, there can be mentioned a cyclohexylmethoxy group, a cyclopentylethoxy group, a cyclohexylethoxy group or the like. A cyclohexylmethoxy group is preferred.

As the alkoxy group with a polycycloalkyl skeleton, which has 7 or more carbon atoms in total, there can be mentioned a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group or the like. Of these, a norbornylmethoxy group and a norbornylethoxy group are preferred. The above-mentioned substituents may be introduced in these.

With respect to the alkyl group in the alkylcarbonyl group represented by R₁₄, there can be mentioned the same particular examples as mentioned above with respect to the alkyl groups represented by R₁₃ to R₁₅.

Each of the alkylsulfonyl group and cycloalkylsulfonyl group represented by R₁₄ may be linear, branched or cyclic, and preferably has 1 to 10 carbon atoms. As particular examples thereof, there can be mentioned a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group and the like. Of these alkylsulfonyl and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group and the like are preferred.

As the alkylene oxide chains represented by R₁₃ and R₁₄, there can be mentioned, for example, an ethylene oxide chain, a propylene oxide chain and a butylene oxide chain. In the alkylene oxide chain, the number of repeating units is preferably in the range of 1 to 10, more preferably 1 to 5 and most preferably 2 to 4.

A substituent may be introduced in each of these groups. As such a substituent, there can be mentioned, for example, a halogen atom (e.g., a fluorine atom), a hydroxyl group, a carboxyl group, a cyano group, a nitro group, an alkoxy group, an alkoxyalkyl group, an alkoxycarbonyl group, an alkoxycarbonyloxy group or the like.

As the alkoxy group, there can be mentioned, for example, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

As the alkoxyalkyl group, there can be mentioned, for example, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

As the alkoxycarbonyl group, there can be mentioned, for example, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

As the alkoxycarbonyloxy group, there can be mentioned, for example, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

As the ring structure that may be formed by the mutual bonding of two R₁₅s, there can be mentioned a 5- or 6-membered ring, most preferably a 5-membered ring (namely, a tetrahydrothiophene ring), formed by two bivalent R₁₅s in cooperation with the sulfur atom in general formula (1-1). The ring structure may be condensed with an aryl group or a cycloalkyl group. Substituents may be introduced in the bivalent R₁₅s. As such substituents, there can be mentioned, for example, a hydroxyl group, a carboxyl group, a cyano group, a nitro group, an alkoxy group, an alkoxyalkyl group, an alkoxycarbonyl group, an alkoxycarbonyloxy group and the like.

R₁₅ is preferably a methyl group, an ethyl group, a naphthyl group, a bivalent group occurring at the formation of a tetrahydrothiophene ring structure upon the mutual bonding of two R₁₅s in cooperation with the sulfur atom, or the like.

Preferred substituents that can be introduced in R₁₃ and R₁₄ are a hydroxyl group, an alkoxy group, an alkoxycarbonyl group and a halogen atom (especially, a fluorine atom).

In the formula, 1 is preferably 0 or 1, more preferably 1; and

r is preferably from 0 to 2.

Particular examples of the salts of general formula (1-1) in the present invention are shown below.

In the following formulae, X⁻ represents a counter anion.

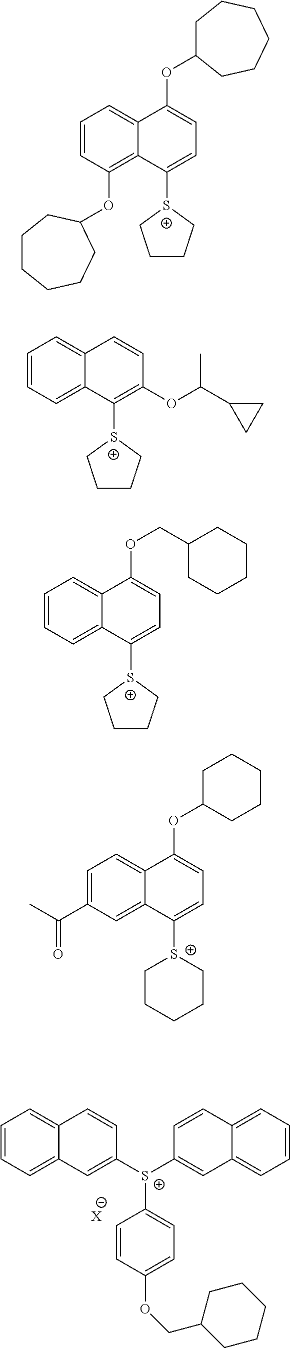

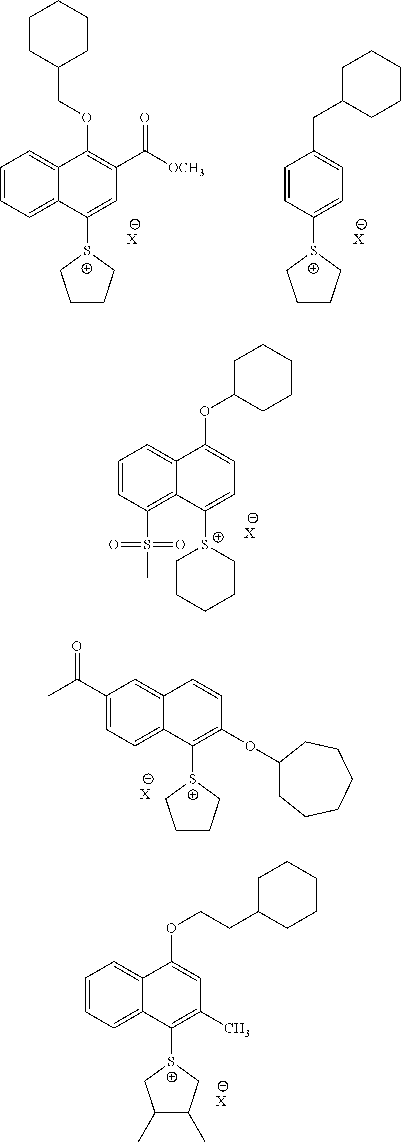

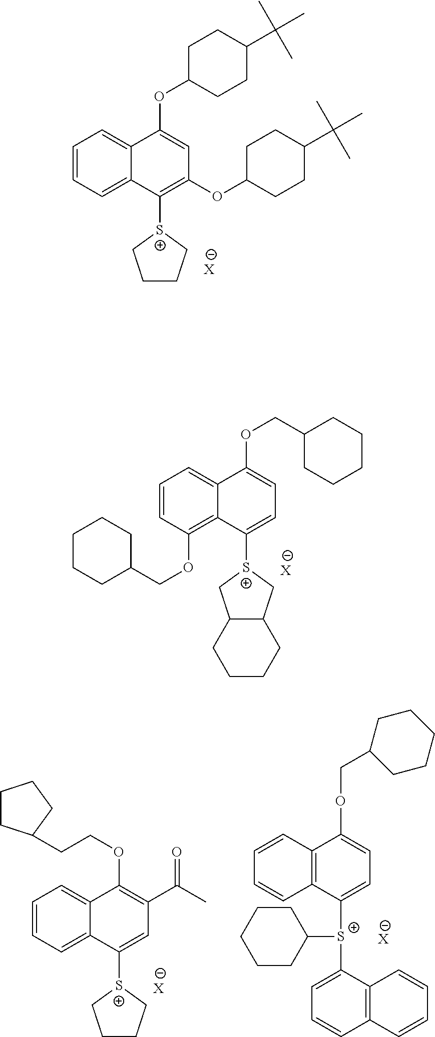

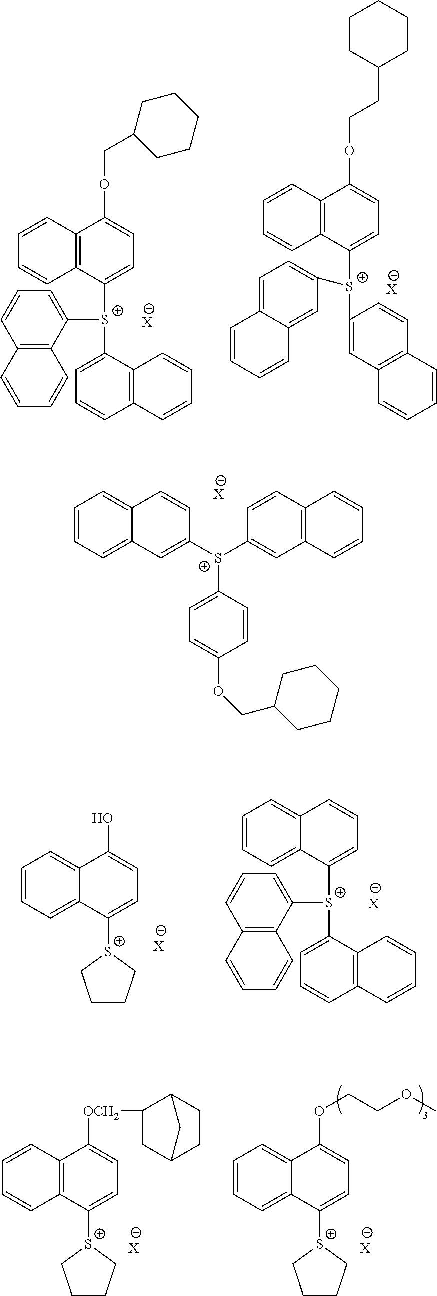

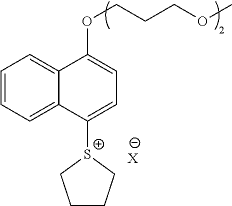

Now, general formula (1-2) will be described.

In the formula, each of R_{1c} and R_{2c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, an alkoxycarbonylalkyl group, an allyl group or a vinyl group.

M represents an alkyl group, a cycloalkyl group, an aryl group or a benzyl group, provided that when a cyclic structure is contained, an oxygen atom, a sulfur atom, an ester bond, an amide bond or a carbon to carbon double bond may be introduced in the cyclic structure.

Rₓ and R_{y} may be bonded to each other to thereby form a ring, and at least two of M, R_{1c} and R_{2c} may be bonded to each other to thereby form a ring, which ring in its structure may contain a carbon to carbon double bond.

The alkyl group represented by M may be linear or branched. For example, this alkyl group has 1 to 20 carbon atoms, and a linear or branched alkyl group having 1 to 12 carbon atoms is preferred. As such an alkyl group, there can be mentioned, for example, a methyl group, an ethyl group, an n-propyl group, an isopropyl group, an n-butyl group, a sec-butyl group, a tert-butyl group, a pentyl group, a hexyl group, an octyl group or a 2-ethylhexyl group.

The cycloalkyl group represented by M is a cyclic alkyl group having 3 to 12 carbon atoms. As such a cycloalkyl group, there can be mentioned, for example, a cyclopropyl group, a cyclobutyl group, a cyclopentyl group, a cyclohexyl group, a cycloheptyl group, a cyclodecyl group or the like.

The aryl group represented by M preferably has 5 to 15 carbon atoms. As such an aryl group, there can be mentioned, for example, a phenyl group or a naphthyl group.

A substituent, such as a cycloalkyl group, an alkoxy group, a halogen atom, a phenylthio group or the like, may be introduced in each of the groups represented by M. An alkyl group as a substituent may further be introduced in the cycloalkyl group and aryl group represented by M. The number of carbon atoms contained in each of these substituents is preferably 15 or less.

When M is a phenyl group, it is preferred for the same to contain at least one linear, branched or cyclic alkyl group, linear, branched or cyclic alkoxy group or phenylthio group as a substituent. More preferably, the sum of carbon atoms contained in each of these substituents is in the range of 2 to 15. If so, the solubility in solvents can be increased, and any particle generation during storage can be suppressed.

The alkyl group represented by R_{1c} or R_{2c} is, for example, one having 1 to 12 carbon atoms, preferably a linear or branched alkyl group having 1 to 5 carbon atoms (for example, a methyl group, an ethyl group or a linear or branched propyl group).

The cycloalkyl group represented by R_{1c} or R_{2c} is, for example, one having 3 to 12 carbon atoms. As preferred examples thereof, there can be mentioned a cyclopropyl group, a cyclobutyl group, a cyclopentyl group, a cyclohexyl group, a cycloheptyl group, a cyclodecyl group or the like.

As the halogen atom, there can be mentioned a fluorine atom, a chlorine atom, a bromine atom or an iodine atom.

The aryl group represented by each of R_{1c} and R_{2c} preferably has 5 to 15 carbon atoms. For example, there can be mentioned a phenyl group or a naphthyl group.

The ring structure formed by the mutual bonding of at least two of M, R_{1c} and R_{2c} is preferably a 3- to 12-membered ring, more preferably a 3- to 10-membered ring and further more preferably a 3- to 6-membered ring. The ring skeleton may contain a carbon to carbon double bond.

When R_{1c} and R_{2c} are bonded to each other to thereby form a ring, the group formed by the mutual bonding of R_{1c} and R_{2c} is preferably an alkylene group having 2 to 10 carbon atoms. For example, there can be mentioned an ethylene group, a propylene group, a butylene group, a pentylene group, a hexylene group or the like. The ring formed by the mutual bonding of R_{1c} and R_{2c} may contain a heteroatom, such as an oxygen atom, in the ring.

As the alkyl group represented by each of Rₓ and R_{y}, there can be mentioned any of those mentioned above as the alkyl groups represented by R_{1c} and R_{2c}.

The cycloalkyl group is preferably, for example, one having 3 to 8 carbon atoms. For example, there can be mentioned a cyclopentyl group, a cyclohexyl group or the like.

The 2-oxoalkyl group may be a group resulting from the introduction of >C═O in the 2-position of any of the alkyl groups represented by R_{1c} and R_{2c}.

The alkoxy group in the alkoxycarbonylalkyl group may be linear, branched or cyclic. As examples thereof, there can be mentioned an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 8 carbon atoms (for example, a cyclopentyloxy group or a cyclohexyloxy group). As the alkyl group in the alkoxycarbonylalkyl group, there can be mentioned, for example, an alkyl group having 1 to 12 carbon atoms, preferably a linear alkyl group having 1 to 5 carbon atoms (for example, a methyl group or an ethyl group).

The allyl group is not particularly limited. Preferably, it is an allyl group unsubstituted or substituted with a mono- or polycycloalkyl group.

The vinyl group is not particularly limited. Preferably, it is a vinyl group unsubstituted or substituted with a mono- or polycycloalkyl group.

As the ring structure that may be formed by the mutual bonding of Rₓ and R_{y}, there can be mentioned a 5-membered or 6-membered ring, most preferably a 5-membered ring (namely, a tetrahydrothiophene ring), formed by bivalent Rₓ and R_{y} (for example, a methylene group, an ethylene group, a propylene group or the like) in cooperation with the sulfur atom in general formula (1-2) above. An oxygen atom is preferably introduced in the ring formed by the mutual bonding of Rₓ and R_{y}.

Each of Rₓ and R_{y} is preferably an alkyl group having 4 or more carbon atoms, more preferably 6 or more carbon atoms and further more preferably 8 or more carbon atoms.

Particular examples of cations in the compounds of general formula (1-2) according to the present invention are shown below.

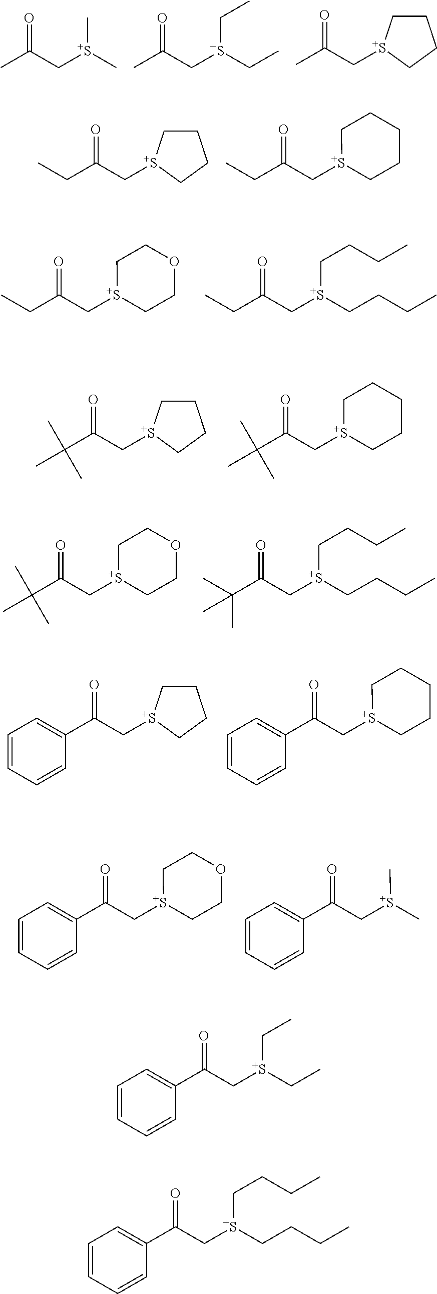

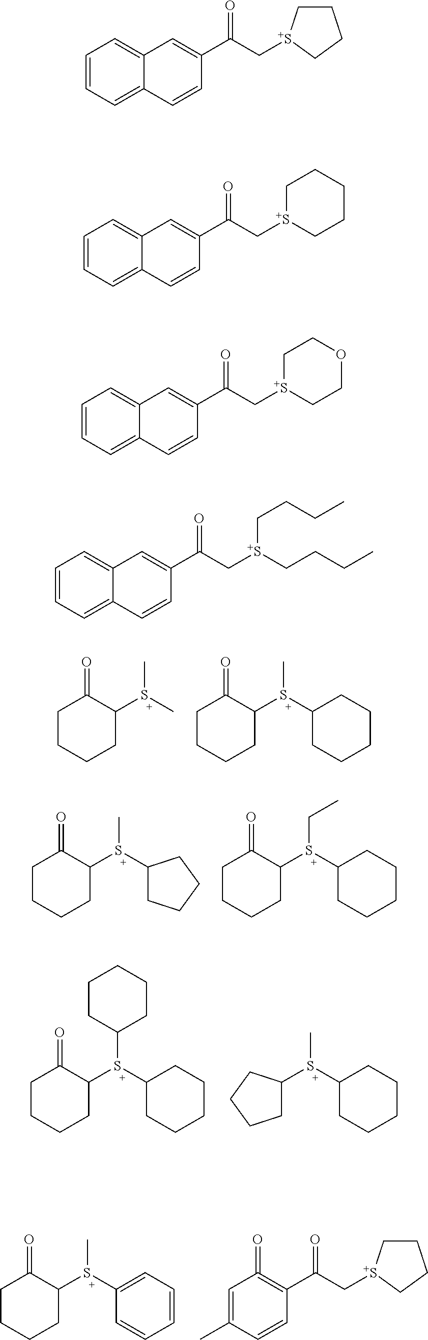

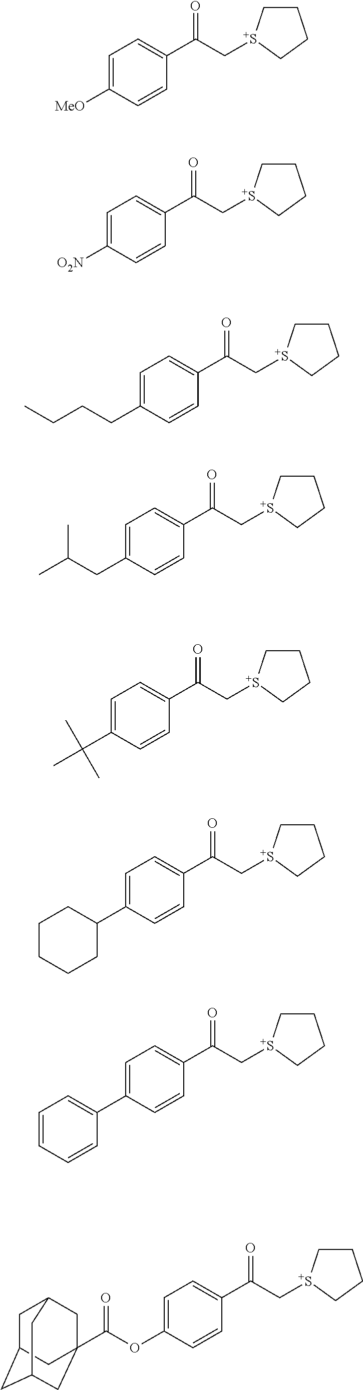

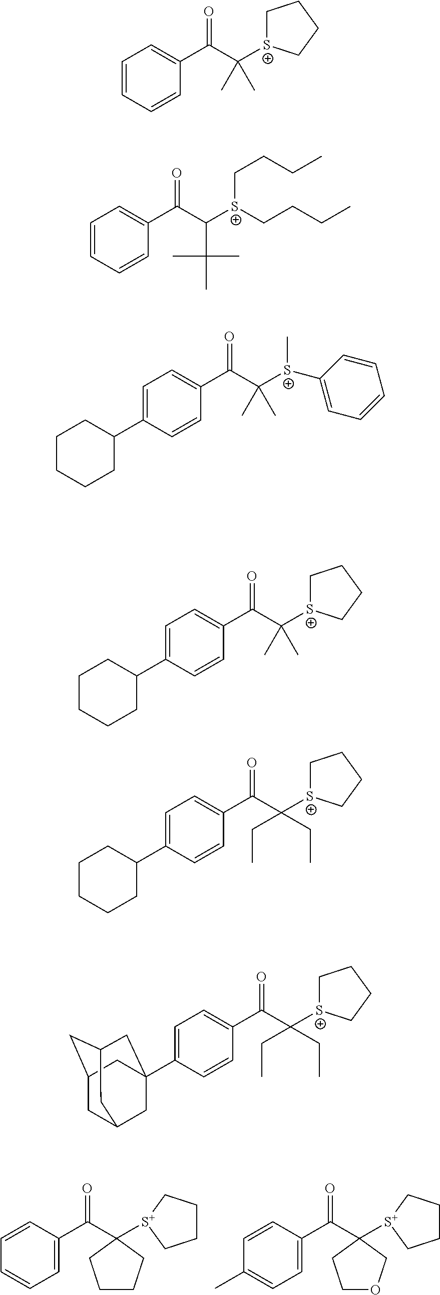

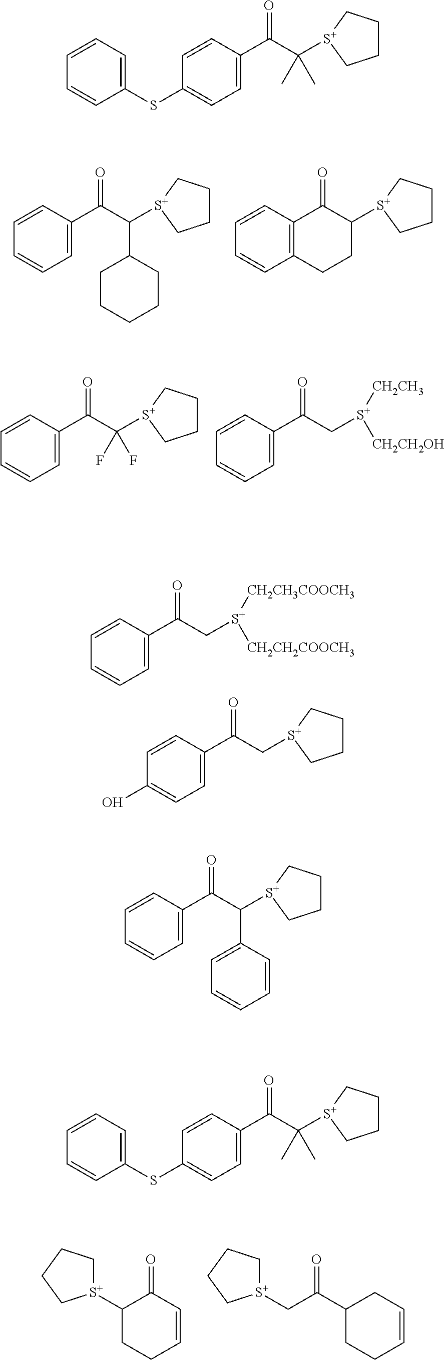

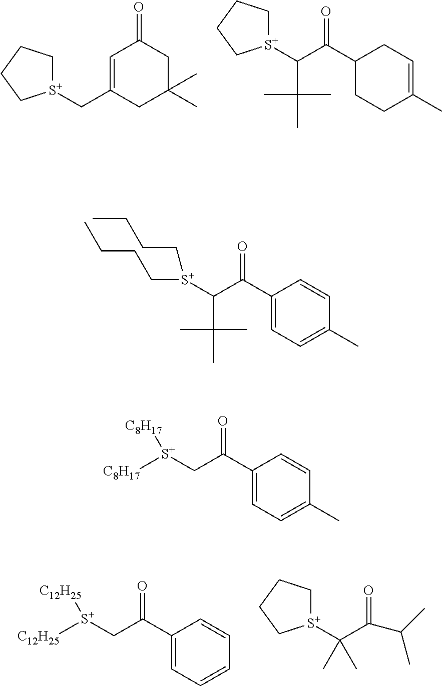

When compound (A) is used in combination with compound (A′), the mass ratio of used photoacid generators (compound (A)/compound (A′)) is preferably in the range of 99/1 to 20/80, more preferably 99/1 to 40/60 and further more preferably 99/1 to 50/50.

[2] Resin (B)

The actinic-ray- or radiation-sensitive resin composition of the present invention in its one aspect can be a positive actinic-ray- or radiation-sensitive resin composition, and in its another aspect can be a negative actinic-ray- or radiation-sensitive resin composition. It is preferred for the resin (B) contained in the composition to be a resin (hereinafter also referred to as “acid-decomposable resin”) that when acted on by an acid, is decomposed to thereby increase its solubility in an alkali developer. In that instance, the resin (B) contains a group (hereinafter also referred to as “acid-decomposable group”) that when acted on by an acid, is decomposed to thereby produce an alkali-soluble group in the principal chain or a side chain, or both the principal chain and a side chain, of the resin. Namely, the resin (B) contains a repeating unit containing an acid-decomposable group.

(1) Repeating unit containing an acid-decomposable group

It is preferred for the acid-decomposable group to have a structure in which an alkali-soluble group is protected by a group leaving by decomposition under the action of an acid.

As preferred alkali-soluble groups, there can be mentioned a carboxyl group, a fluoroalcohol group (preferably a hexafluoroisopropanol group), a sulfonic acid group and the like.

It is preferred for the acid-decomposable group to be a group resulting from the replacement of a hydrogen atom of such an alkali-soluble group with a group leaving under the action of an acid.

As the group leaving under the action of an acid, there can be mentioned, for example, —C(R₃₆) (R₃₇) (R₃₈), —C(R₃₆) (R₃₇) (OR₃₉), —C(R₀₁) (R₀₂) (OR₃₉) or the like.

In the formulae, each of R₃₆ to R₃₉ independently represents an alkyl group, a cycloalkyl group, an aryl group, an aralkyl group or an alkenyl group. R₃₆ and R₃₇ may be bonded to each other to thereby form a ring.

Each of R₀₁ and R₀₂ independently represents a hydrogen atom, an alkyl group, a cycloalkyl group, an aryl group, an aralkyl group or an alkenyl group.

It is preferred for the acid-decomposable group to be a cumyl ester group, an enol ester group, an acetal ester group, a tertiary alkyl ester group or the like. A tertiary alkyl ester group is more preferred.

The repeating unit containing an acid-decomposable group that can be introduced in the resin (B) is preferably any of repeating units of general formula (AI) below.

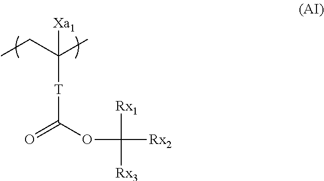

In general formula (AI),

Xa₁ represents a hydrogen atom, an optionally substituted methyl group or any of groups of the formula —CH₂—R₉. R₉ represents a hydroxyl group or a monovalent organic group. The monovalent organic group is, for example, an alkyl group having 5 or less carbon atoms or an acyl group. Preferably, the monovalent organic group is an alkyl group having 3 or less carbon atoms, more preferably a methyl group. Xa₁ is preferably a hydrogen atom, a methyl group, a trifluoromethyl group or a hydroxymethyl group.

T represents a single bond or a bivalent connecting group.

Each of Rx₁ to Rx₃ independently represents an alkyl group (linear or branched) or a cycloalkyl group (mono- or polycycle).

Any two of Rx₁ to Rx₃ may be bonded to each other to thereby form a cycloalkyl group (mono- or polycycle).

As the bivalent connecting group represented by T, there can be mentioned an alkylene group, any of groups of the formula —COO-Rt-, any of groups of the formula —O-Rt- or the like. In the formulae, Rt represents an alkylene group or a cycloalkylene group.

T is preferably a single bond or any of groups of the formula —COO-Rt-. Rt is preferably an alkylene group having 1 to 5 carbon atoms, more preferably a —CH₂— group or a —(CH₂)₃— group.

The alkyl group represented by each of Rx₁ to Rx₃ is preferably a linear or branched alkyl group having 1 to 4 carbon atoms.

The cycloalkyl group represented by each of Rx₁ to Rx₃ is preferably a monocycloalkyl group having 3 to 8 carbon atoms, or a polycycloalkyl group having 7 to 20 carbon atoms.

The cycloalkyl group formed by the mutual bonding of at least two of Rx₁ to Rx₃ is preferably a monocycloalkyl group having 3 to 8 carbon atoms, or a polycycloalkyl group having 7 to 20 carbon atoms. A monocycloalkyl group having 5 or 6 carbon atoms is especially preferred.

In a preferred form of the repeating unit, Rx₁ is a methyl group or an ethyl group, and Rx₂ and Rx₃ are bonded to each other to thereby form any of the above-mentioned cycloalkyl groups.

The content of repeating unit containing an acid-decomposable group, based on all the repeating units of the resin (B), is preferably in the range of 10 to 70 mol %, more preferably 25 to 60 mol %, further more preferably 35 to 55 mol %, and most preferably 45 to 55 mol %.

Particular examples of preferred repeating units containing acid-decomposable groups are shown below, which in no way limit the scope of the present invention. In the formulae, Xa₁ represents H, CH₃, CF₃ or CH₂OH. Each of Rxa and Rxb represents a linear or branched alkyl group having 1 to 4 carbon atoms.

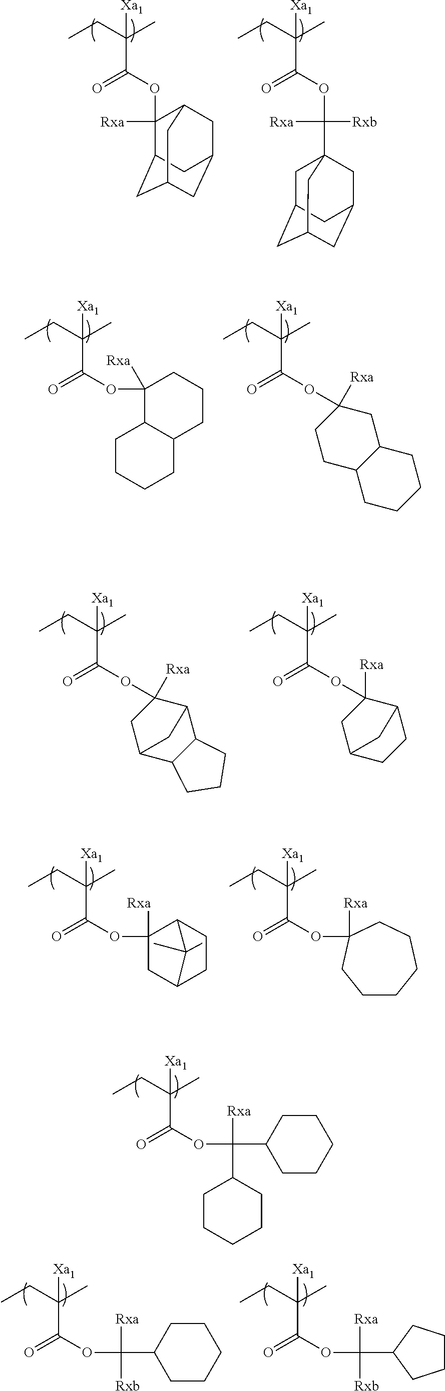

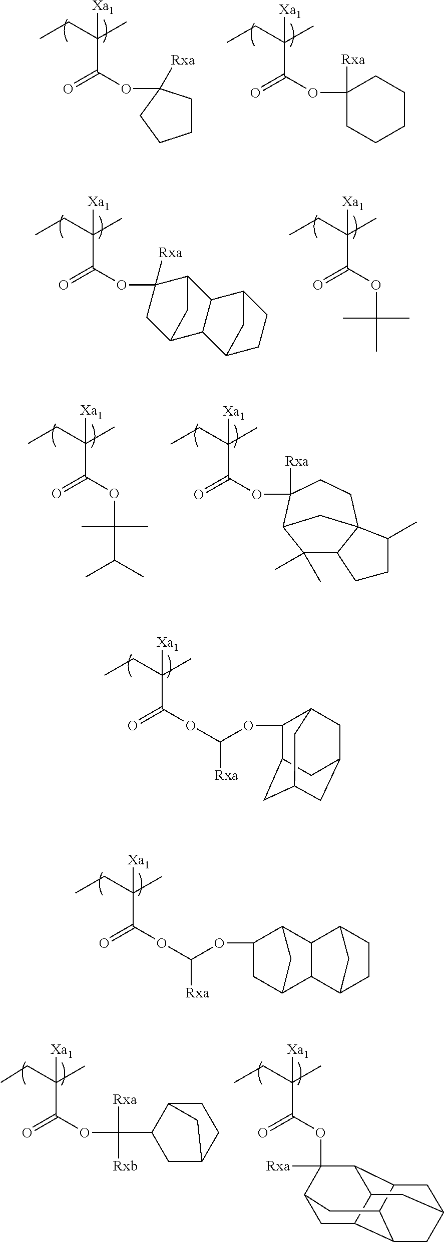

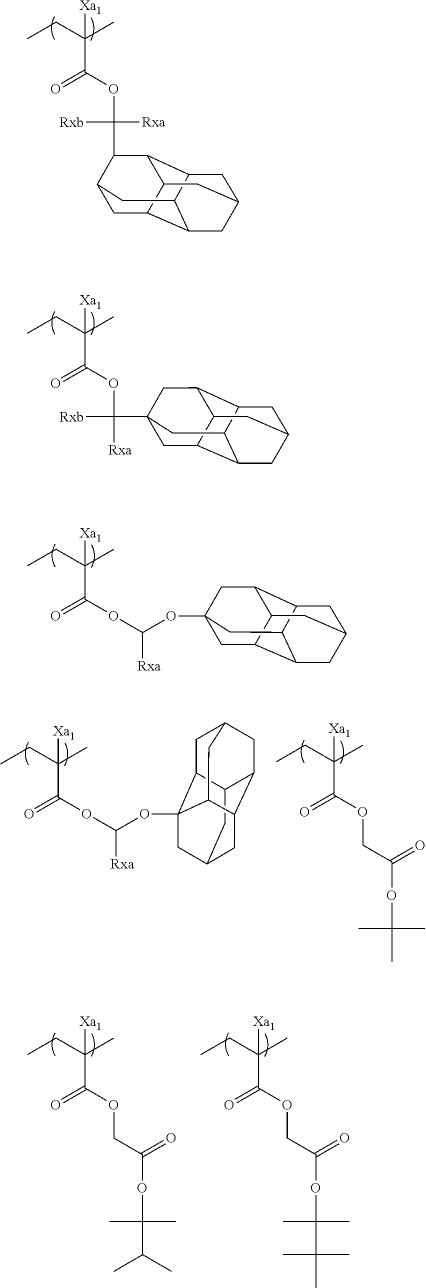

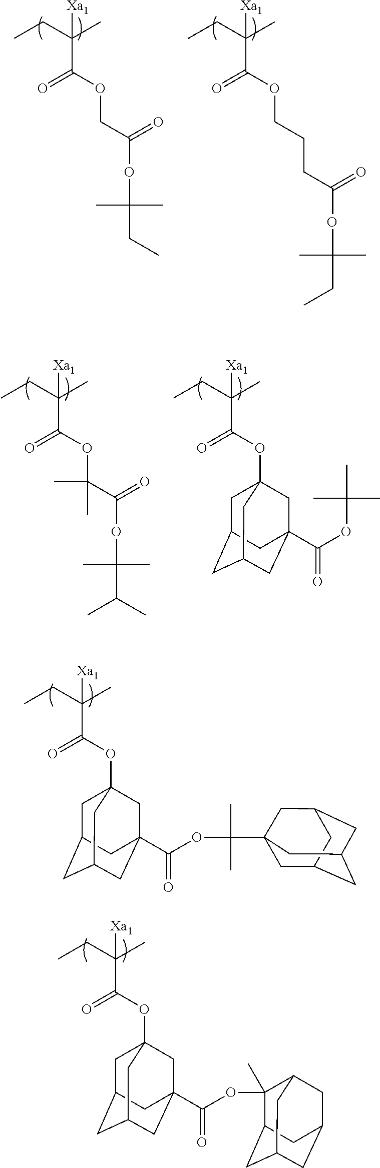

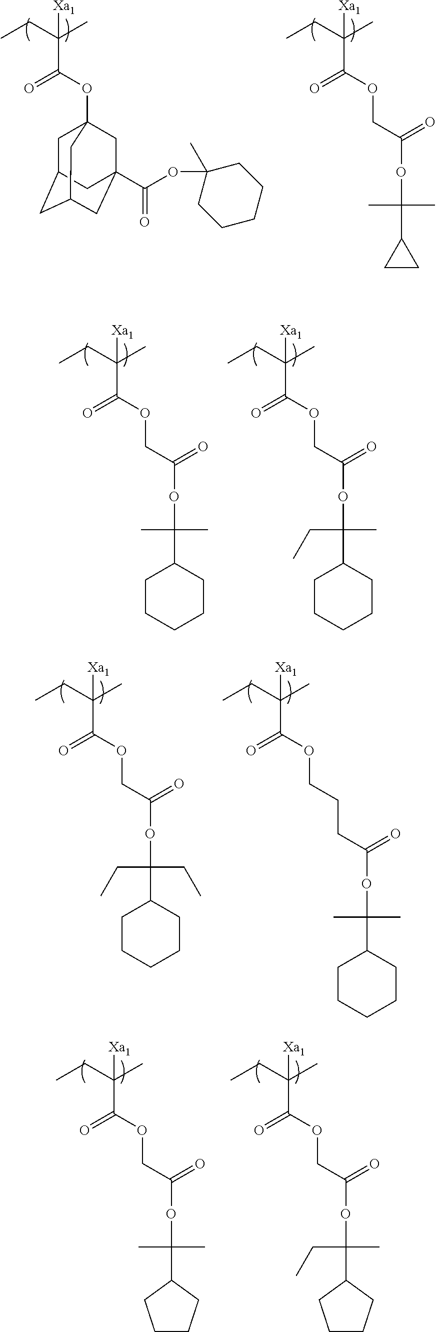

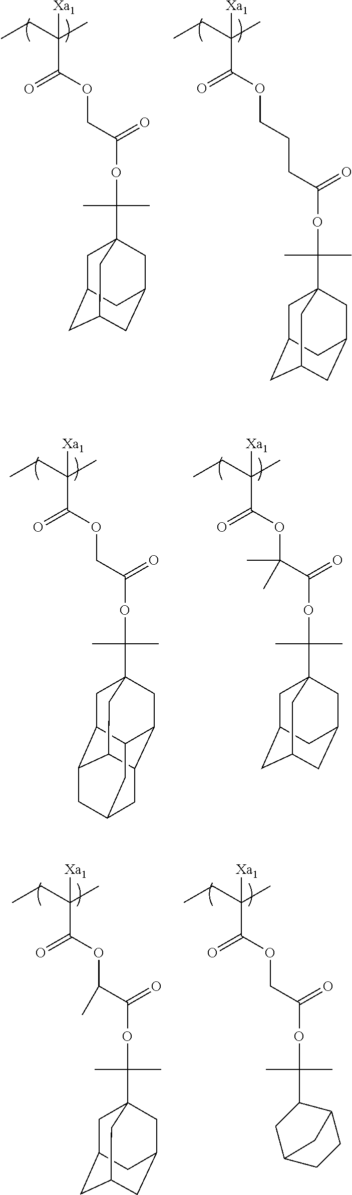

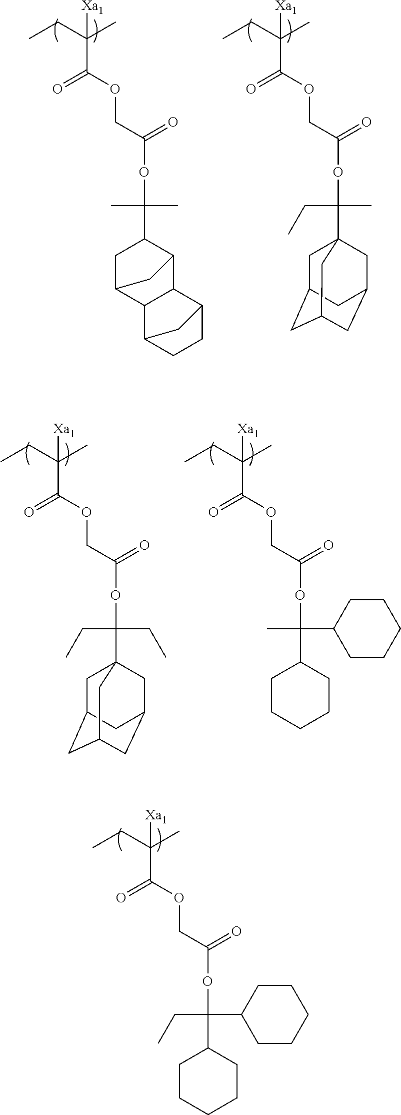

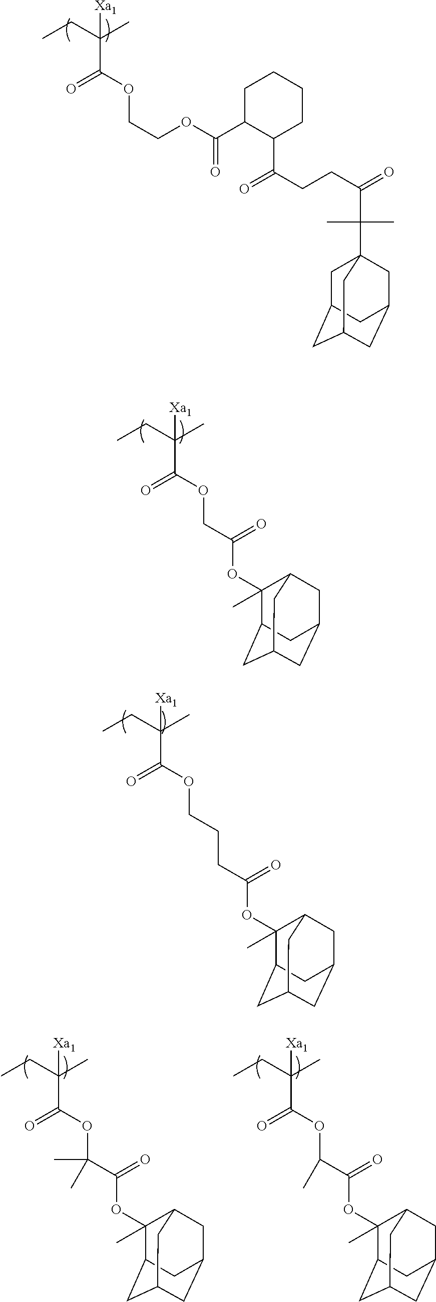

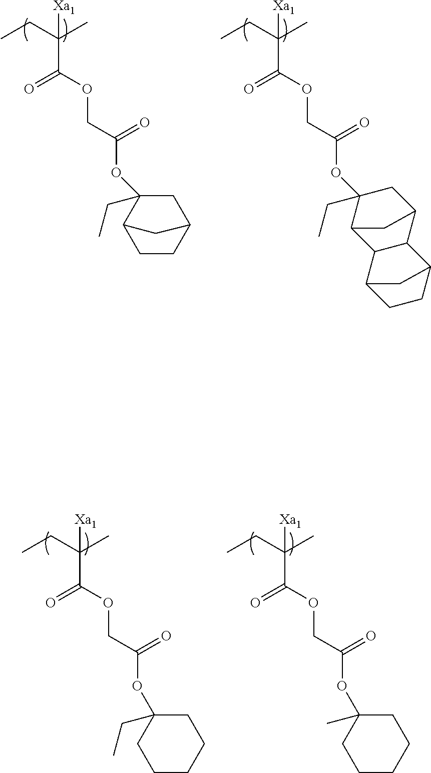

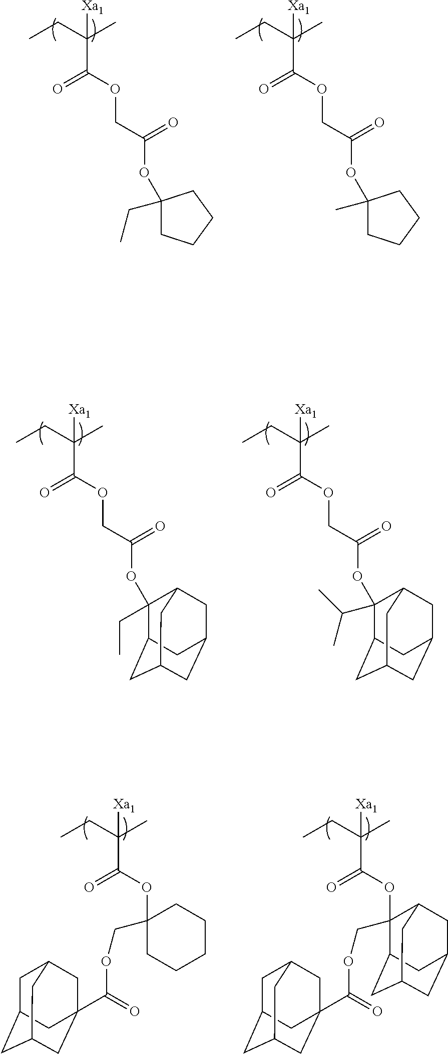

It is preferred for the resin (B) to be a resin containing any of repeating units of general formula (1) below as the repeating unit expressed by general formula (AI).

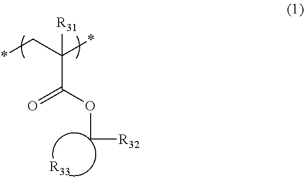

In general formula (1),

R₃₁ represents a hydrogen atom, a fluorine atom, an alkyl group or a fluorinated alkyl group;

R₃₂ represents a methyl group, an ethyl group, an n-propyl group, an isopropyl group, an n-butyl group, an isobutyl group or a sec-butyl group; and

R₃₃ represents an atomic group required to form a monoalicyclic hydrocarbon structure in cooperation with the carbon atom to which R₃₂ is bonded, provided that in the alicyclic hydrocarbon structure, ring-constituting carbon atoms may be partially replaced by a heteroatom or a heteroatom-containing group.

A substituent may be introduced in the alkyl group represented by R₃₁. The substituent is, for example, a fluorine atom or a hydroxyl group.

R₃₁ is preferably a hydrogen atom, a methyl group, a trifluoromethyl group or a hydroxymethyl group.

R₃₂ is preferably a methyl group, an ethyl group, an n-propyl group or an isopropyl group. R₃₂ is more preferably a methyl group or an ethyl group.

The monoalicyclic hydrocarbon structure formed by R₃₃ in cooperation with the carbon atom is preferably a 3- to 8-membered ring, more preferably a 5- or 6-membered ring.

In the monoalicyclic hydrocarbon structure formed by R₃₃ in cooperation with the carbon atom, the heteroatom capable of partially replacing ring-constituting carbon atoms thereof is, for example, an oxygen atom or a sulfur atom. As the group containing a heteroatom, there can be mentioned a carbonyl group or the like. Preferably, however, the group containing a heteroatom is not an ester group (ester bond).

It is preferred for the monoalicyclic hydrocarbon structure formed by R₃₃ in cooperation with the carbon atom to be comprised only of carbon and hydrogen atoms.

It is preferred for the repeating units of general formula (1) to be those of general formula (1′) below.

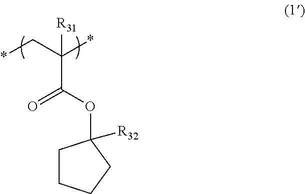

In general formula (1′), R₃₁ and R₃₂ are as defined above in connection with general formula (1).

Nonlimiting particular examples of the repeating units with the structure of general formula (1) are shown below.

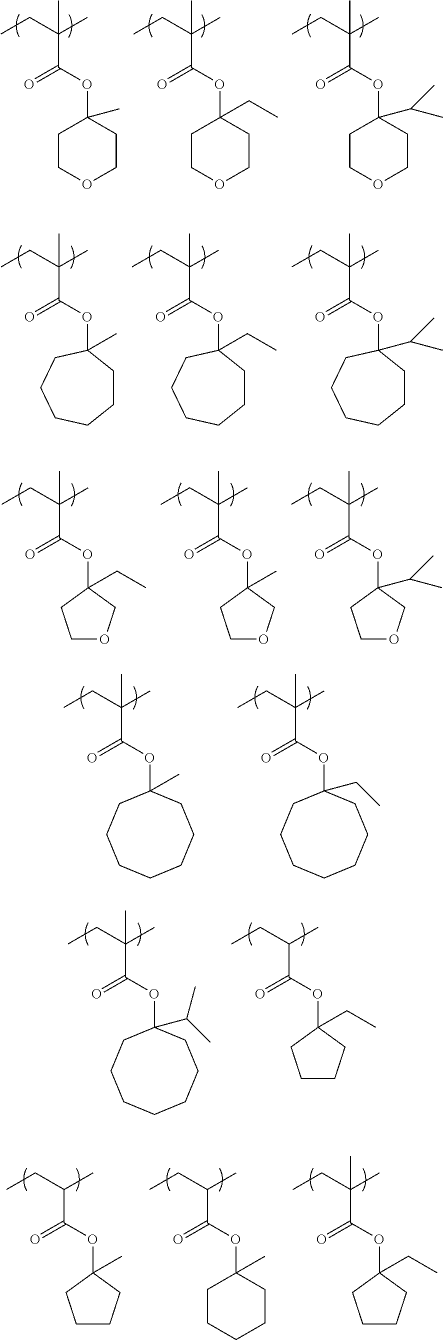

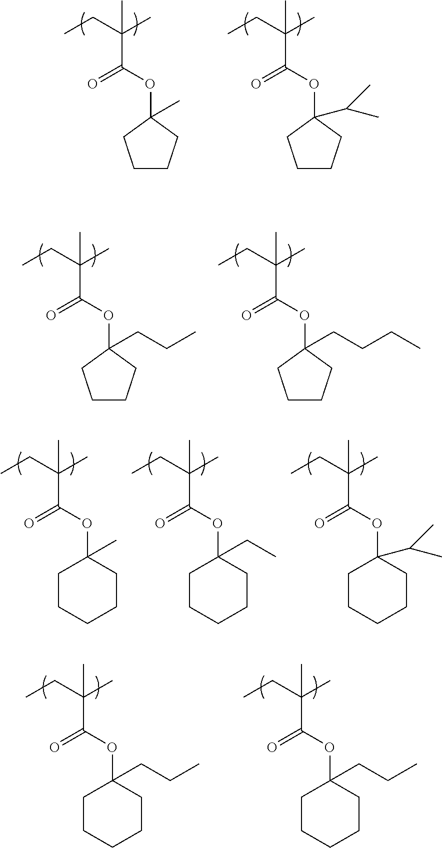

The content of repeating unit with the structure of general formula (1), based on all the repeating units of the resin (B), is preferably in the range of 10 to 70 mol %, more preferably 25 to 65 mol %, and further more preferably 30 to 50 mol %.

In the resin (B), only one type of repeating unit containing an acid-decomposable group may be introduced, or two or more types of repeating units each containing an acid-decomposable group may be used in combination. When two or more types are used, the following combinations of particular structures are preferred. In the formulae, each of R′s independently represents a hydrogen atom or a methyl group.

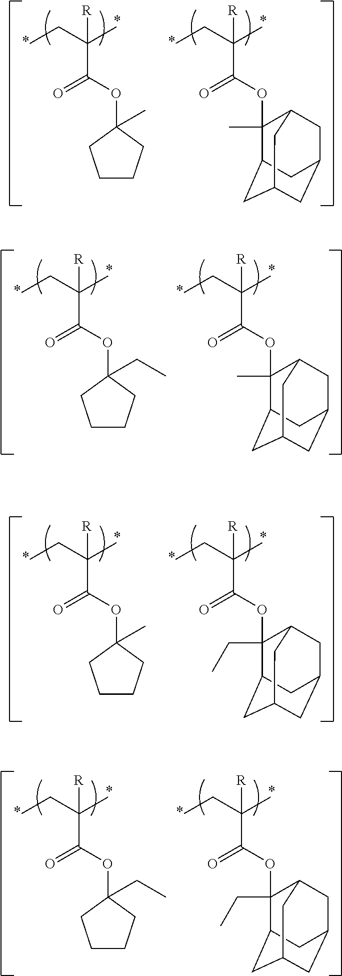

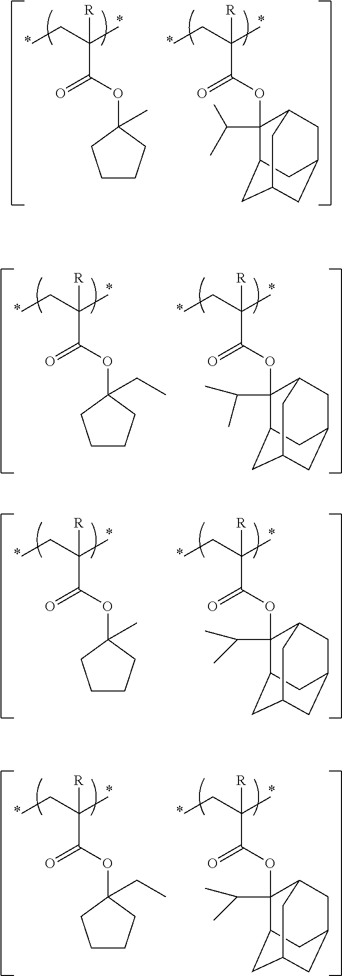

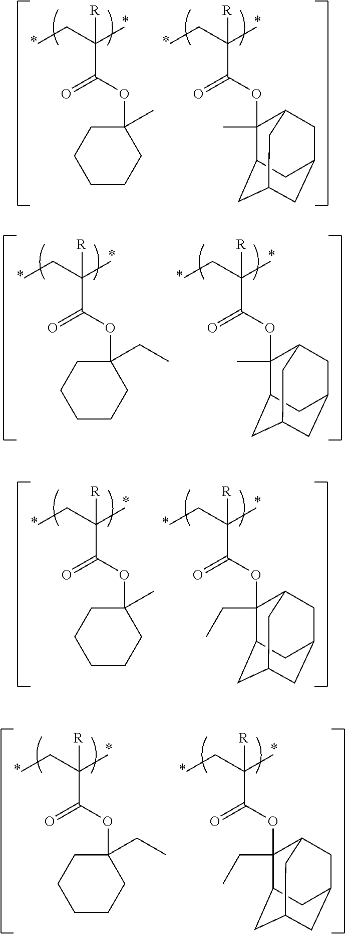

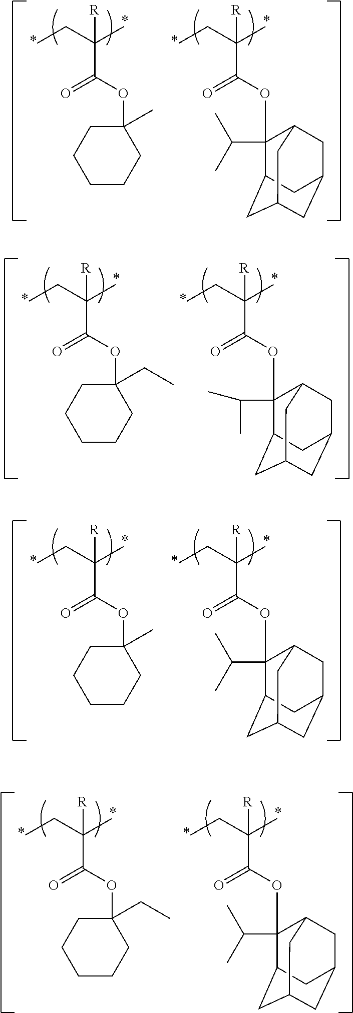

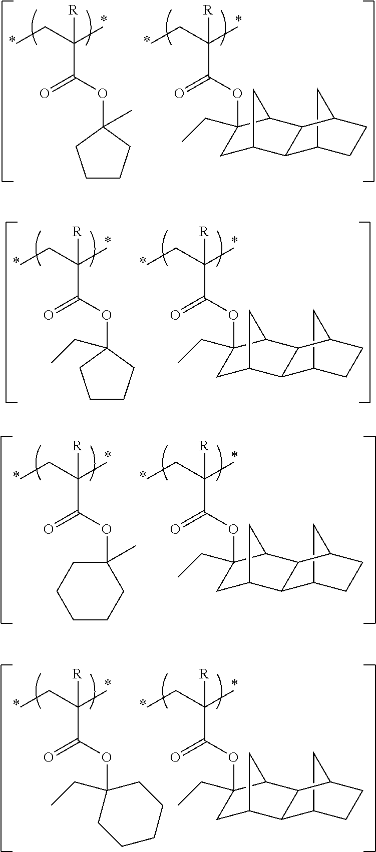

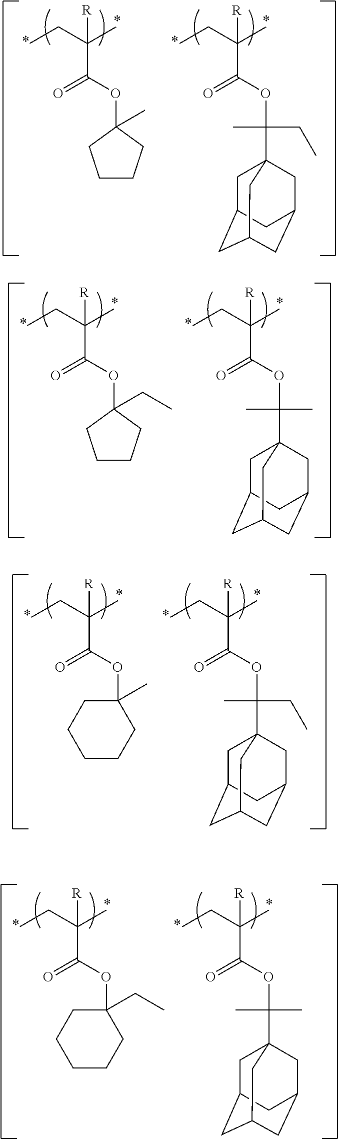

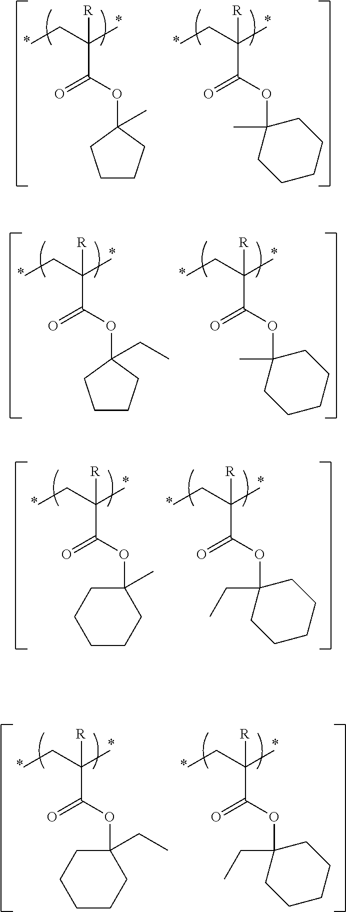

It is preferred for the acid-decomposable resin as a constituent of the actinic-ray- or radiation-sensitive resin composition of the present invention to contain a repeating unit with a cyclic carbonic ester structure. This cyclic carbonic ester structure refers to a structure with a ring containing the bond of the formula —O—C(═O)—O— as an atomic group constructing a ring. The ring containing the bond of the formula —O—C(═O)—O— as an atomic group constructing a ring is preferably a 5- to 7-membered ring, most preferably a 5-membered ring. This ring may be condensed with another ring to thereby form a condensed ring.

It is preferred for the resin (B) according to the present invention to contain any of repeating units of general formula (A-1) below as the repeating unit with a cyclic carbonic ester structure.

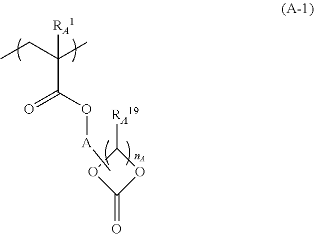

In general formula (A-1), R_{A}¹ represents a hydrogen atom or an alkyl group.

Each of R_{A}¹⁹s independently represents a hydrogen atom or a chain hydrocarbon group.

A represents a single bond, a bivalent or trivalent chain hydrocarbon group, a bivalent or trivalent alicyclic hydrocarbon group or a bivalent or trivalent aromatic hydrocarbon group, provided that when A is trivalent, a carbon atom contained in A is bonded to a carbon atom as a constituent of the cyclic carbonic ester structure to thereby form a ring structure; and

n_{A} is an integer of 2 to 4.

In general formula (A-1), R_{A}¹ represents a hydrogen atom or an alkyl group. A substituent, such as a fluorine atom, may be introduced in the alkyl group represented by R_{A}¹. R_{A}¹ is preferably a hydrogen atom, a methyl group or a trifluoromethyl group, more preferably a methyl group.

Each of R_{A}¹⁹s independently represents a hydrogen atom or a chain hydrocarbon group. The chain hydrocarbon group represented by R_{A}¹⁹ is preferably one having 1 to 5 carbon atoms.

A substituent, such as a hydroxyl group, may be introduced in the chain hydrocarbon group. R_{A}¹⁹ is most preferably a hydrogen atom.

In general formula (A-1), n_{A} is an integer of 2 to 4; and

n_{A} is preferably 2 or 3, more preferably 2.

In general formula (A-1), A represents a single bond, a bivalent or trivalent chain hydrocarbon group, a bivalent or trivalent alicyclic hydrocarbon group or a bivalent or trivalent aromatic hydrocarbon group.

The bivalent or trivalent chain hydrocarbon group is preferably one having 1 to 30 carbon atoms.

The bivalent or trivalent alicyclic hydrocarbon group is preferably one having 3 to 30 carbon atoms.

The bivalent or trivalent aromatic hydrocarbon group is preferably one having 6 to 30 carbon atoms.

A is preferably a bivalent or trivalent chain hydrocarbon group or a bivalent or trivalent alicyclic hydrocarbon group, more preferably a bivalent or trivalent chain hydrocarbon group, and further more preferably a linear alkylene group having 1 to 5 carbon atoms.

Only one of the repeating units of general formula (A-1) may be introduced, or two or more thereof may be introduced in the resin (B). The content of repeating unit with a cyclic carbonic ester structure (preferably repeating unit expressed by general formula (A-1)), based on all the repeating units of the resin (B), is preferably in the range of 3 to 80 mol %, more preferably 3 to 60 mol %, further more preferably 3 to 30 mol %, and most preferably 10 to 15 mol %. The resist developability, low defect probability, low LWR, low PEB temperature dependence, profile, etc. can be enhanced by regulating the content in that range.

Particular examples (repeating units (A-1a) to (A-1w)) of the repeating units of general formula (A-1) are shown below, which in no way limit the scope of the present invention.

In the following particular examples, R_{A}¹ is as defined above in connection with general formula (A-1).

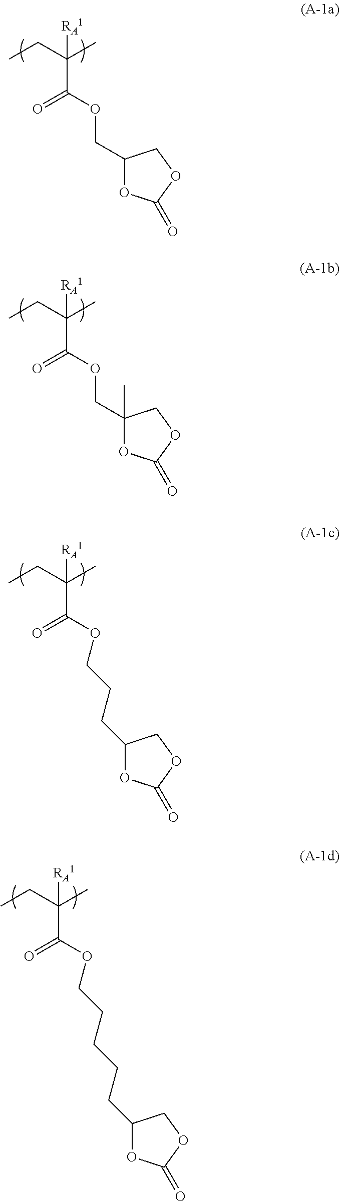

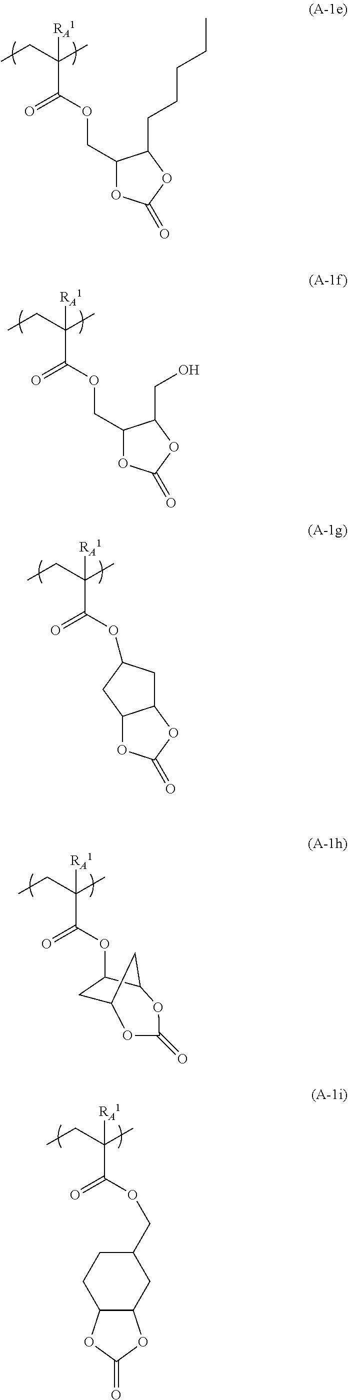

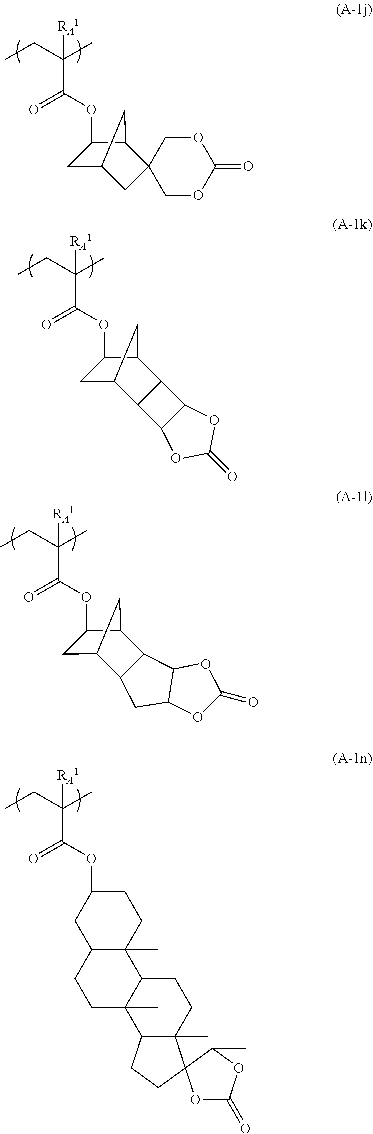

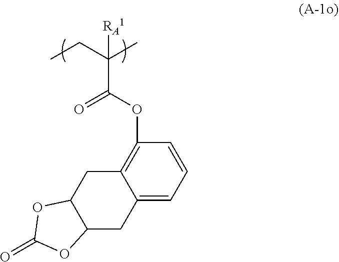

(2) Repeating unit containing at least one group selected from among a lactone group, a hydroxyl group, a cyano group and an alkali-soluble group

It is preferred for the resin (B) to further contain a repeating unit containing at least one group selected from among a lactone group, a hydroxyl group, a cyano group and an alkali-soluble group.

Now, the repeating unit containing a lactone group introducible in the resin (B) will be described.

The lactone group is not limited as long as a lactone structure is introduced therein. A 5 to 7-membered ring lactone structure is preferred, and one resulting from the condensation of a 5 to 7-membered ring lactone structure with another cyclic structure effected in a fashion to form a bicyclo structure or spiro structure is preferred. It is more preferred to introduce a repeating unit containing any of the lactone structures of general formulae (LC1-1) to (LC1-17) below. The lactone structures may be directly bonded to the principal chain. Preferred lactone structures are those of formulae (LC1-1), (LC1-4), (LC1-5), (LC1-6), (LC1-13), (LC1-14) and (LC1-17). The line edge roughness and development defect performance can be enhanced by the introduction of specified lactone structures.

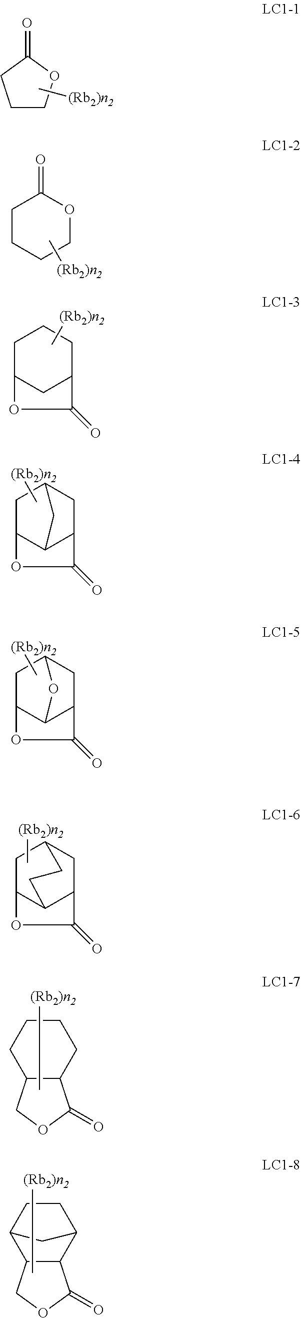

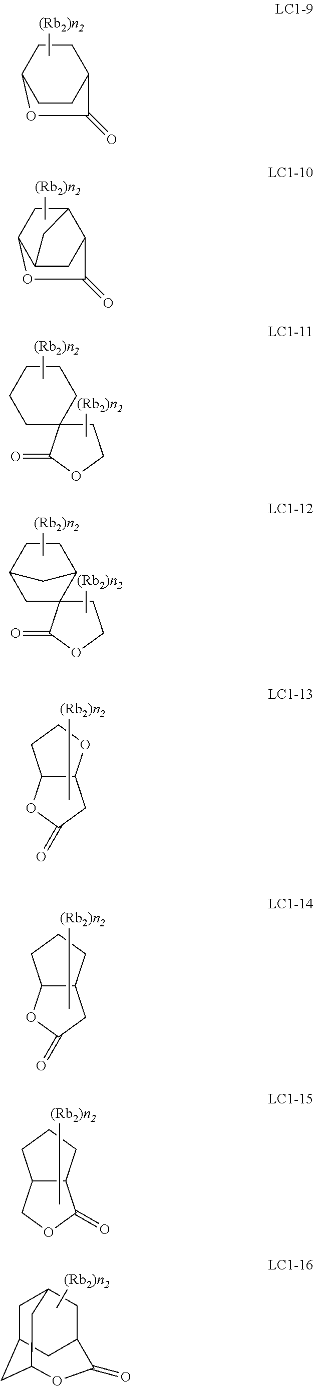

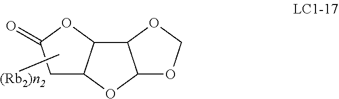

A substituent (Rb₂) is optionally introduced in the portion of the lactone structure. As preferred substituents (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group and an acid-decomposable group and the like. An alkyl group having 1 to 4 carbon atoms, a cyano group and an acid-decomposable group are more preferred. In the formulae, n₂ is an integer of 0 to 4. When n₂ is 2 or greater, the plurality of introduced substituents (Rb₂) may be identical to or different from each other. Further, the plurality of introduced substituents (Rb₂) may be bonded to each other to thereby form a ring.

As the repeating units with lactone structures of any of general formulae (LC1-1) to (LC1-17), there can be mentioned those of general formula (AII) below.

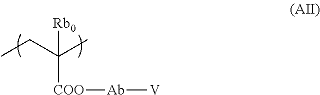

In general formula (AII),

Rb₀ represents a hydrogen atom, a halogen atom or an optionally substituted alkyl group preferably having 1 to 4 carbon atoms. As preferred substituents that may be introduced in the alkyl group represented by Rb₀, there can be mentioned a hydroxyl group and a halogen atom. As the halogen atom represented by Rb₀, there can be mentioned a fluorine atom, a chlorine atom, a bromine atom or an iodine atom. Rb₀ is preferably a hydrogen atom, a methyl group, a hydroxymethyl group or a trifluoromethyl group. A hydrogen atom and a methyl group are especially preferred.

Ab represents a single bond, an alkylene group, a bivalent connecting group with a mono- or polyalicyclic hydrocarbon structure, an ether group, an ester group, a carbonyl group, or a bivalent connecting group resulting from combination of these. Ab is preferably a single bond or any of the bivalent connecting groups of the formula -Ab₁-CO₂—.

Ab₁ represents a linear or branched alkylene group or a mono- or polycycloalkylene group, preferably a methylene group, an ethylene group, a cyclohexylene group, an adamantylene group or a norbornylene group.

V represents a group with any of the structures of general formulae (LC1-1) to (LC1-17) above.

The repeating unit containing a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or higher, more preferably 95% or higher.

The content of repeating unit containing a lactone group, based on all the repeating units of the resin (B), is preferably in the range of 15 to 60 mol %, more preferably 20 to 50 mol % and further more preferably 30 to 50 mol %.

Particular examples of the repeating units each containing a lactone group are shown below, which in no way limit the scope of the present invention.

In the following formulae, Rx represents H, CH₃, CH₂OH or CF₃.

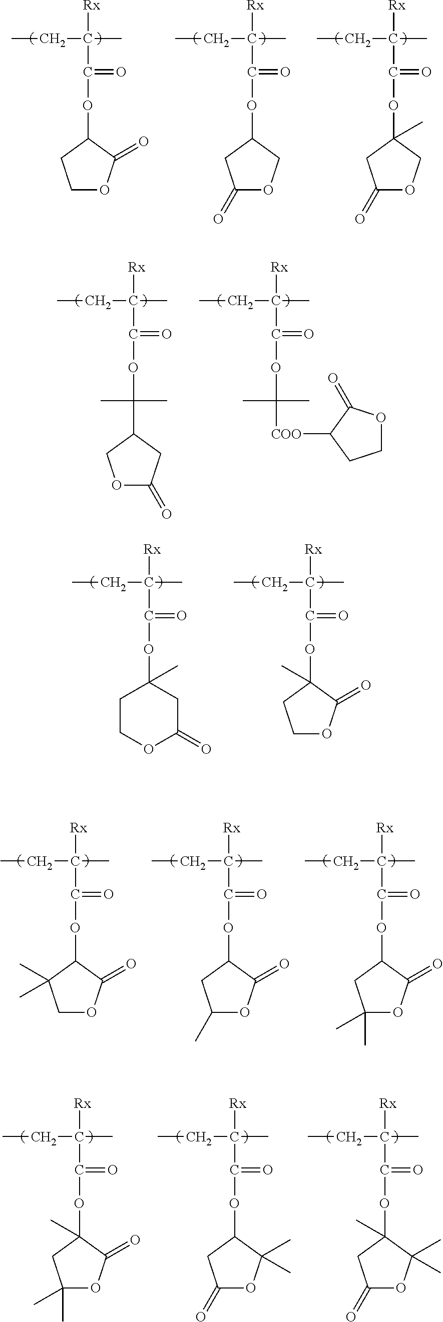

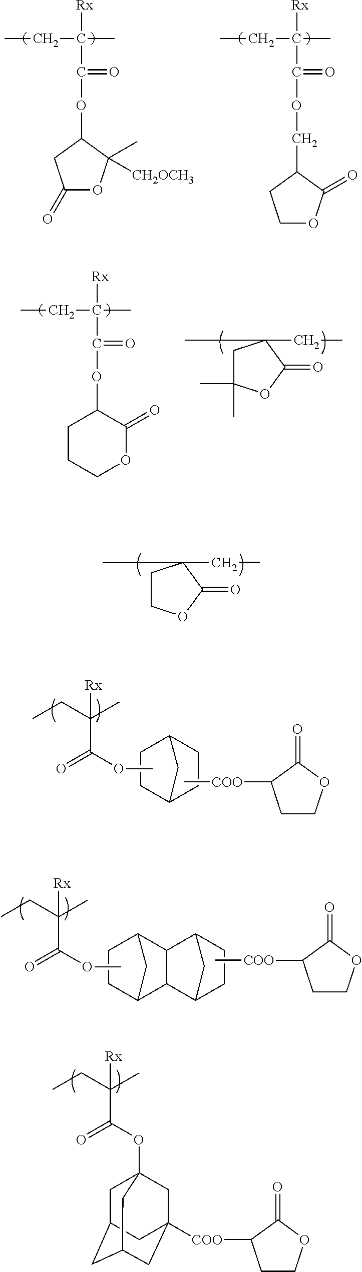

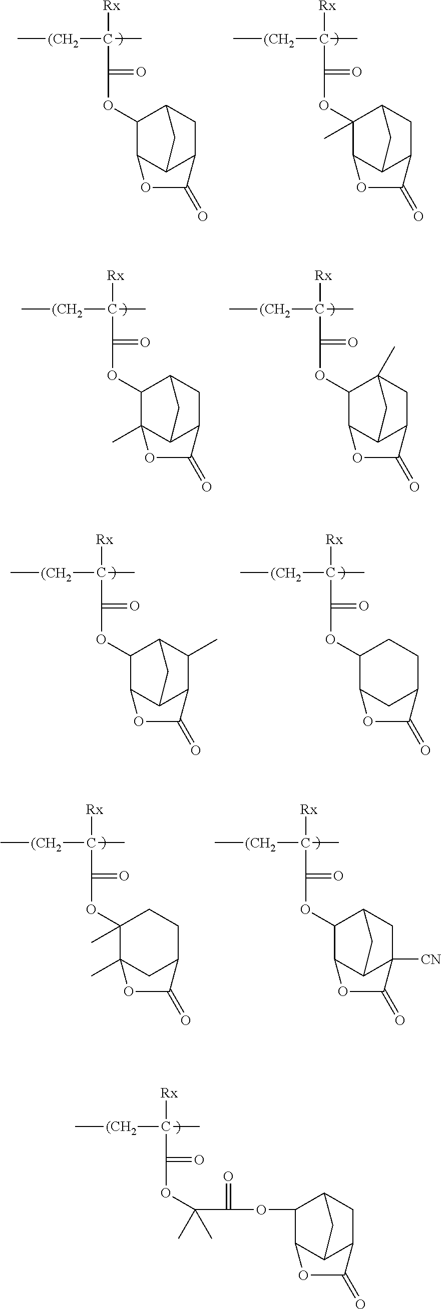

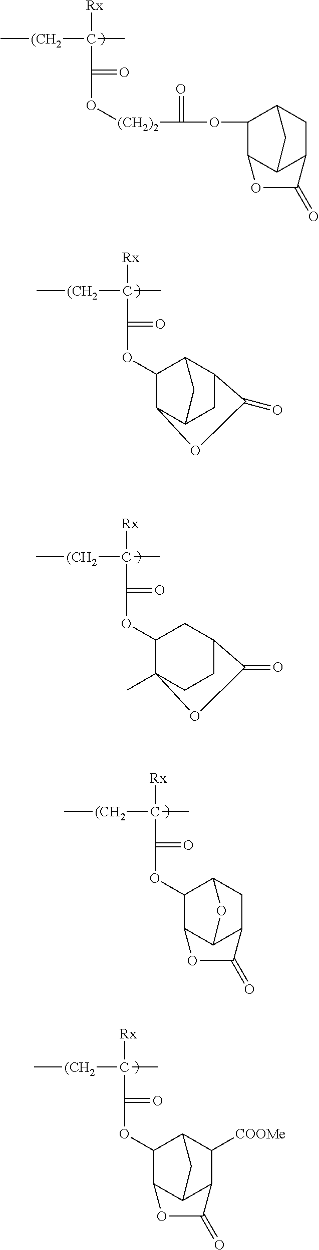

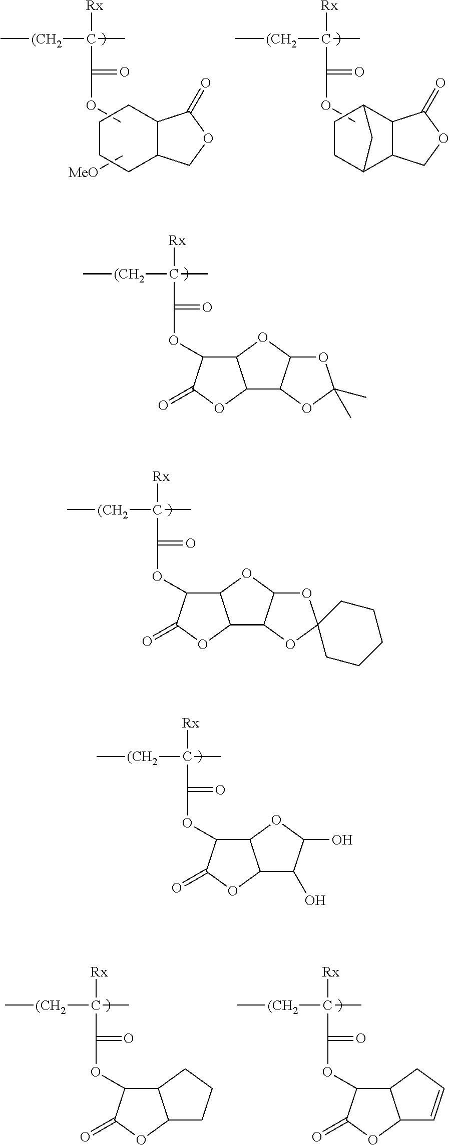

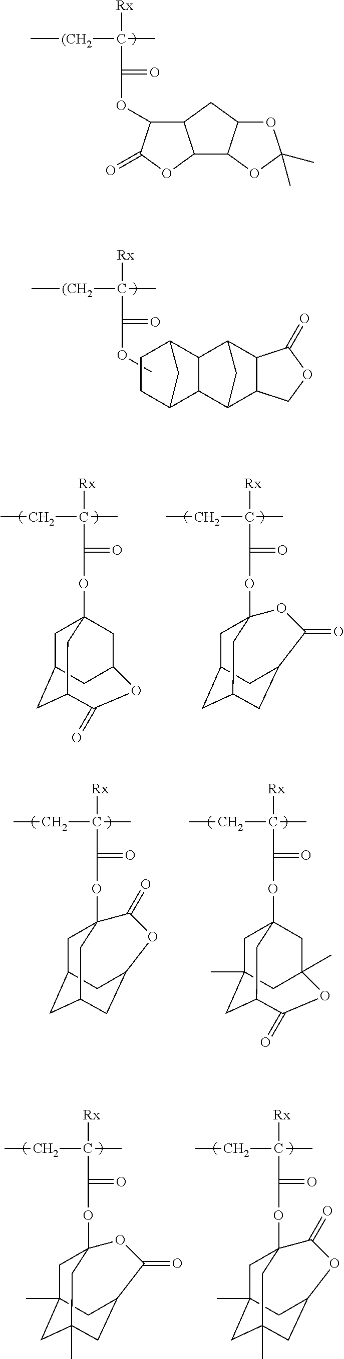

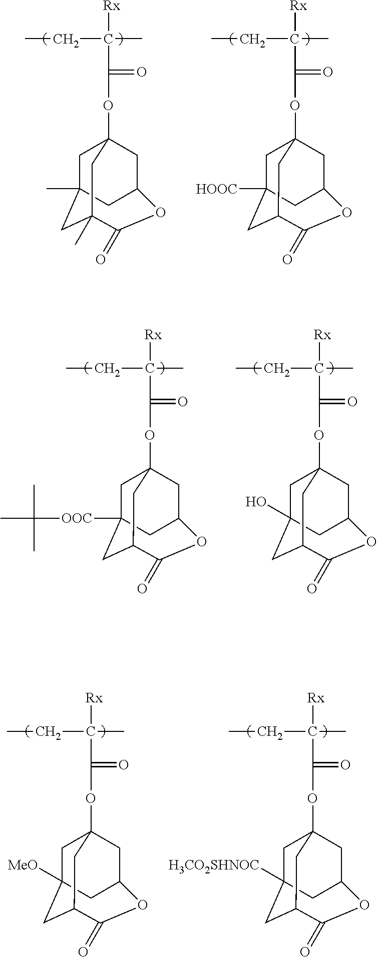

Repeating units containing especially preferred lactone groups are shown below. Enhanced pattern profile and iso/dense bias can be realized by selecting the most appropriate lactone group.

In the formulae, Rx represents H, CH₃, CH₂OH or CF₃.

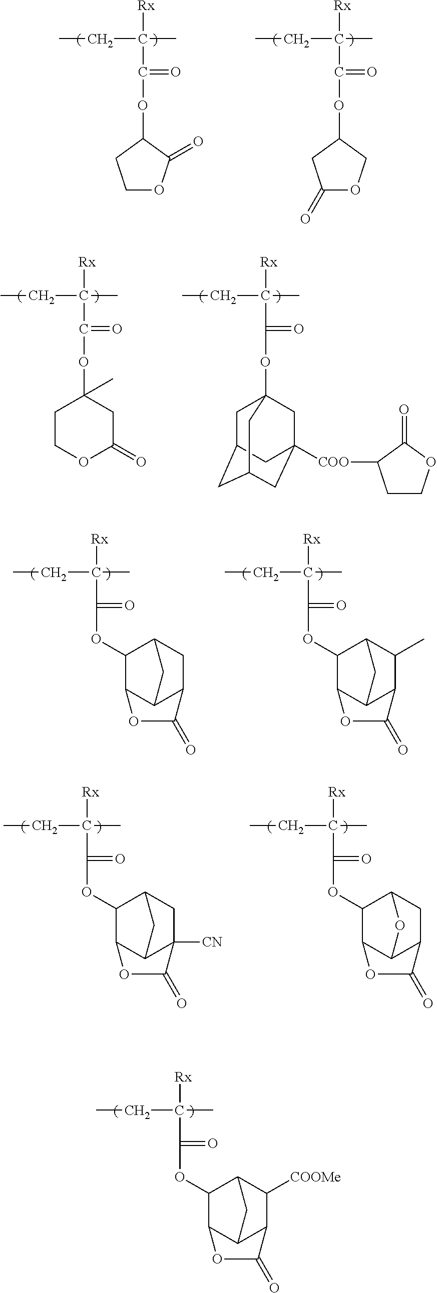

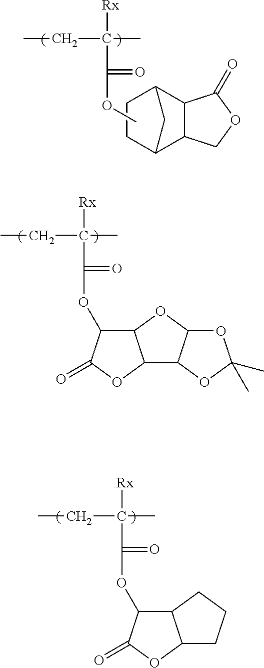

It is preferred for the resin (B) to contain a repeating unit containing a hydroxyl group or a cyano group other than the repeating units of general formulae (AI) and (II). This enhances the adhesion to substrate and developer affinity. The repeating unit containing a hydroxyl group or a cyano group is preferably a repeating unit with an alicyclic hydrocarbon structure substituted with a hydroxyl group or a cyano group, which repeating unit preferably contains no acid-decomposable group. As repeating units with such a structure, there can be mentioned the repeating units of general formulae (AIIa) to (AIId) below.

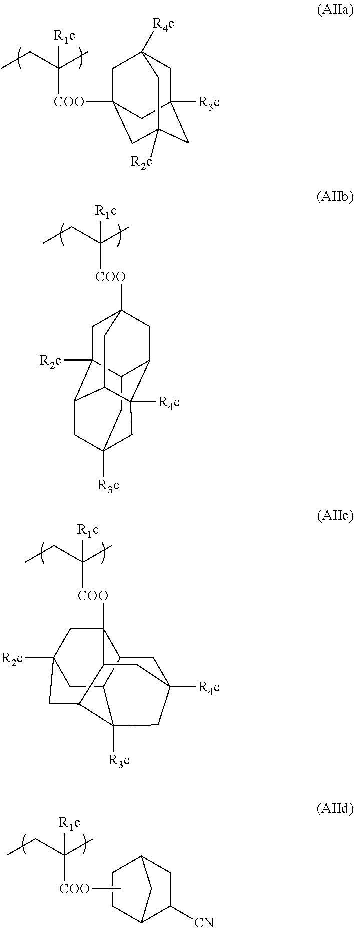

In general formulae (AIIa) to (AIId),

R₁c represents a hydrogen atom, a methyl group, a trifluoromethyl group or a hydroxymethyl group. Each of R₂c to R₄c independently represents a hydrogen atom, a hydroxyl group or a cyano group, provided that at least one of R₂c to R₄c represents a hydroxyl group or a cyano group. Preferably, one or two of R₂c to R₄c are hydroxyl groups and the remainders are hydrogen atoms. More preferably, two of R₂c to R₄c are hydroxyl groups and the remainder is a hydrogen atom.

The content of repeating unit containing a hydroxyl group or a cyano group, based on all the repeating units of the resin (B), is preferably in the range of 5 to 40 mol %, more preferably 5 to 30 mol % and further more preferably 10 to 25 mol %.

Particular examples of the repeating units each containing a hydroxyl group or a cyano group are shown below, which in no way limit the scope of the present invention.

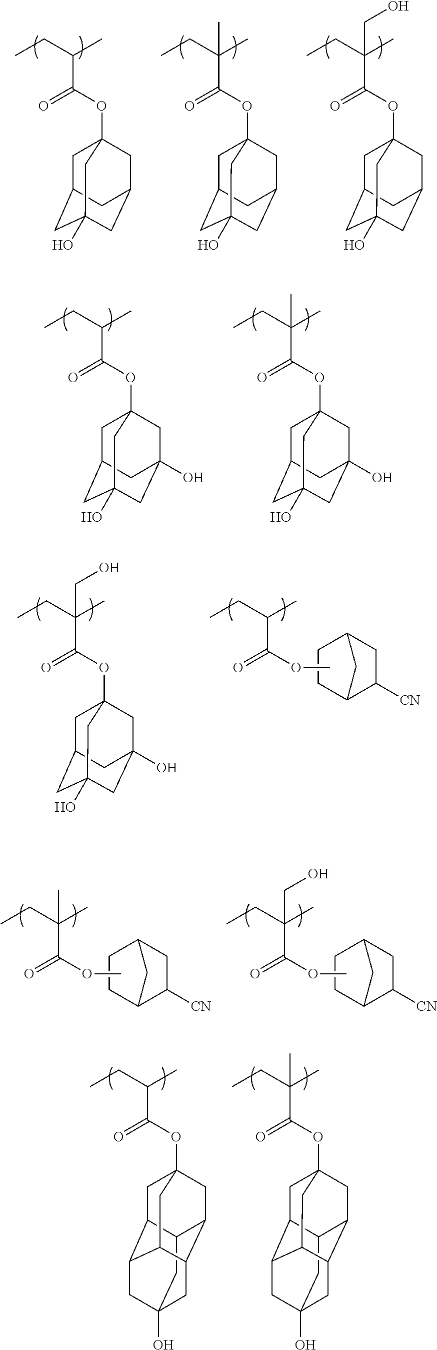

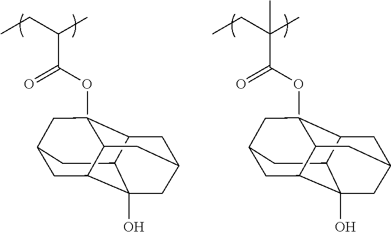

The resin (B) preferably contains a repeating unit containing an alkali-soluble group. As the alkali-soluble group, there can be mentioned a carboxyl group, a sulfonamido group, a sulfonylimido group, a bissulfonylimido group or an aliphatic alcohol substituted at its α-position with an electron-withdrawing group (for example, a hexafluoroisopropanol group). It is preferred for the resin to contain a repeating unit containing a carboxyl group. The incorporation of the repeating unit containing an alkali-soluble group increases the resolution in contact hole usage. The repeating unit containing an alkali-soluble group is preferably any of a repeating unit wherein the alkali-soluble group is directly bonded to the principal chain of a resin, such as a repeating unit of acrylic acid or methacrylic acid; a repeating unit wherein the alkali-soluble group is bonded via a connecting group to the principal chain of a resin; and a repeating unit wherein the alkali-soluble group is introduced in a terminal of a polymer chain by the use of a chain transfer agent or polymerization initiator containing the alkali-soluble group in the stage of polymerization. The connecting group may have a mono- or polycyclohydrocarbon structure. The repeating unit of acrylic acid or methacrylic acid is especially preferred.

The content of repeating unit containing an alkali-soluble group, based on all the repeating units of the resin (B), is preferably in the range of 0 to 20 mol %, more preferably 3 to 15 mol % and further more preferably 5 to 10 mol %.

Specific examples of the repeating units each containing an alkali-soluble group are shown below, which in no way limit the scope of the present invention. In the specific examples, Rx represents H, CH₃, CH₂OH or CF₃.

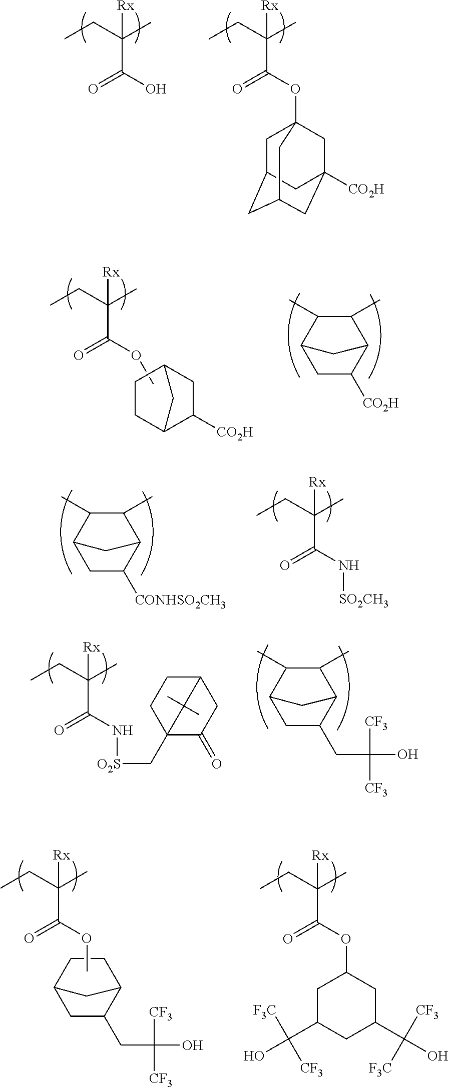

A repeating unit containing at least two groups selected from among a lactone group, a hydroxyl group, a cyano group and an alkali-soluble group is preferred to the repeating unit containing at least one group selected from among a lactone group, a hydroxyl group, a cyano group and an alkali-soluble group. A repeating unit containing a cyano group and a lactone group is more preferred. A repeating unit with a structure comprised of the lactone structure of formula (LC1-4) above substituted with a cyano group is most preferred.

(3) Repeating Unit with an Alicyclic Hydrocarbon Structure Exhibiting No Acid-Decomposability

The resin (B) may further contain a repeating unit with an alicyclic hydrocarbon structure exhibiting no acid-decomposability. This reduces any leaching of low-molecular components from a resist film into an immersion liquid at the time of liquid-immersion exposure. As such a repeating unit, there can be mentioned, for example, any of the repeating units of 1-adamantyl(meth)acrylate, diamantyl(meth)acrylate, tricyclodecanyl(meth)acrylate and cyclohexyl(meth)acrylate.

(4) Repeating Unit Containing Neither a Hydroxyl Group Nor a Cyano Group

It is preferred for the resin (B) according to the present invention to further contain any of repeating units of general formula (III) below containing neither ahydroxyl group nor a cyano group.

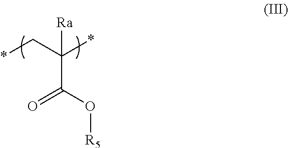

In general formula (III), R₅ represents a hydrocarbon group with at least one cyclic structure in which neither a hydroxyl group nor a cyano group is introduced.

Ra represents a hydrogen atom, an alkyl group or any of groups of the formula —CH₂—O—Ra₂. In this formula, Ra₂ represents a hydrogen atom, an alkyl group or an acyl group.

The cyclic structures introduced in R₅ include a monocyclic hydrocarbon group and a polycyclic hydrocarbon group. As the monocyclic hydrocarbon group, there can be mentioned, for example, a cycloalkyl group having 3 to 12 carbon atoms (preferably 3 to 7 carbon atoms), or a cycloalkenyl group having 3 to 12 carbon atoms.

The polycyclic hydrocarbon groups include ring-assembly hydrocarbon groups and crosslinked-ring hydrocarbon groups. As the crosslinked-ring hydrocarbon rings, there can be mentioned, for example, bicyclic hydrocarbon rings, tricyclic hydrocarbon rings, and tetracyclic hydrocarbon rings. Further, the crosslinked-ring hydrocarbon rings include, for example, condensed rings resulting from the condensation of a plurality of 5- to 8-membered cycloalkane rings.

As preferred crosslinked-ring hydrocarbon rings, there can be mentioned a norbornyl group, an adamantyl group, a bicyclooctanyl group, a tricyclo[5,2,1,0^{2,6}]decanyl group and the like. As more preferred crosslinked-ring hydrocarbon rings, there can be mentioned a norbornyl group and an adamantyl group.

Substituents may be introduced in these alicyclic hydrocarbon groups. As preferred substituents, there can be mentioned a halogen atom, an alkyl group, a hydroxyl group protected by a protective group, an amino group protected by a protective group and the like. The halogen atom is preferably a bromine, chlorine or fluorine atom, and the alkyl group is preferably a methyl, ethyl, butyl or t-butyl group. A substituent may further be introduced in the alkyl group. As the optional further substituent, there can be mentioned a halogen atom, an alkyl group, a hydroxyl group protected by a protective group or an amino group protected by a protective group.

As the protective group, there can be mentioned, for example, an alkyl group, a cycloalkyl group, an aralkyl group, a substituted methyl group, a substituted ethyl group, an alkoxycarbonyl group or an aralkyloxycarbonyl group. The alkyl group is preferably an alkyl group having 1 to 4 carbon atoms. The substituted methyl group is preferably a methoxymethyl, methoxythiomethyl, benzyloxymethyl, t-butoxymethyl or 2-methoxyethoxymethyl group. The substituted ethyl group is preferably 1-ethoxyethyl or 1-methyl-1-methoxyethyl. The acyl group is preferably an aliphatic acyl group having 1 to 6 carbon atoms, such as a formyl, acetyl, propionyl, butyryl, isobutyryl, valeryl or pivaloyl group. The alkoxycarbonyl group is, for example, an alkoxycarbonyl group having 1 to 4 carbon atoms.

The content of repeating unit expressed by general formula (III) in which neither a hydroxyl group nor a cyano group is introduced, based on all the repeating units of the resin (B), is preferably in the range of 0 to 40 mol %, more preferably 0 to 20 mol %.

Particular examples of the repeating units of general formula (III) are shown below, which in no way limit the scope of the present invention. In the formulae, Ra represents H, CH₃, CH₂OH or CF₃.

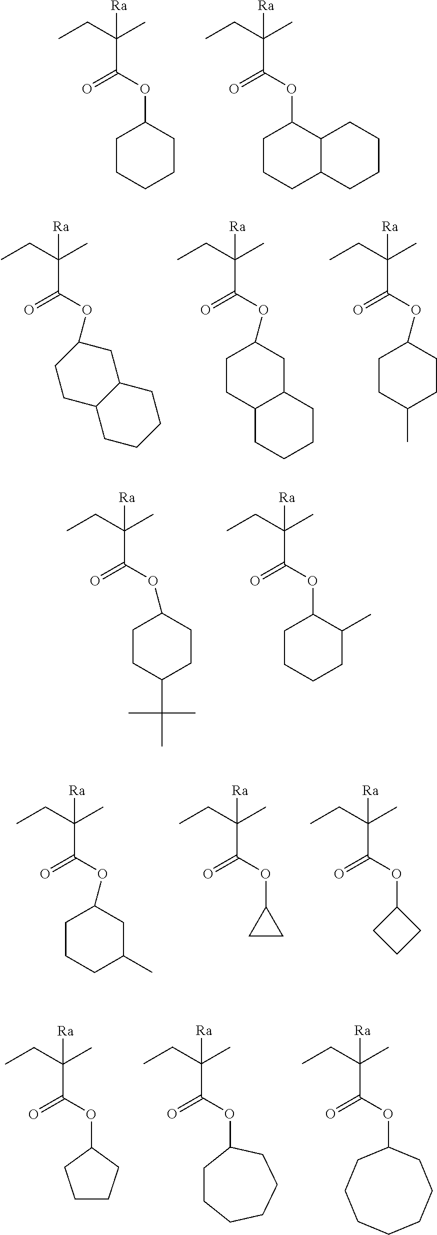

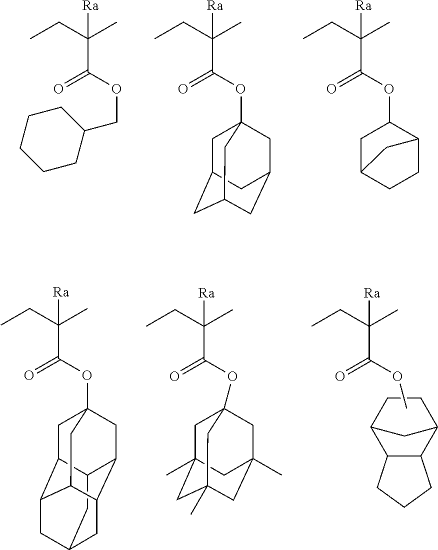

The resin (B) can contain, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which are nonlimiting.

The incorporation of such repeating structural units realizes fine regulation of the required properties of the resin (B), especially:

(1) solubility in application solvents,

(2) film forming easiness (glass transition point),

(3) alkali developability,

(4) film thinning (selections of hydrophilicity/hydrophobicity and alkali-soluble group),

(5) adhesion of unexposed area to substrate,

(6) dry etching resistance, etc.

As appropriate monomers, there can be mentioned, for example, compounds each having one unsaturated bond capable of addition polymerization, selected from among acrylic esters, methacrylic esters, acrylamides, methacrylamides, allyl compounds, vinyl ethers, vinyl esters and the like.

In addition, any unsaturated compound capable of addition polymerization that is copolymerizable with any of the above monomers corresponding to various repeating structural units may be copolymerized therewith.

In the resin (B), the molar ratios of individual repeating structural units contained are appropriately determined from the viewpoint of regulating the dry etching resistance, standard developer adaptability, substrate adhesion and resist profile of the resist and generally required properties of the resist such as resolving power, heat resistance and sensitivity.

When the resist composition of the present invention is one for ArF exposure, from the viewpoint of transparency to ArF light, it is preferred for the resin (B) to contain no aromatic group. Further, from the viewpoint of compatibility with a hydrophobic resin to be described hereinafter, it is preferred for the resin (B) according to the present invention to contain neither a fluorine atom nor a silicon atom.

In the resin (B), preferably, all the repeating units thereof are comprised of (meth)acrylate repeating units. In that instance, use can be made of any of a resin wherein all the repeating units are comprised of methacrylate repeating units, a resin wherein all the repeating units are comprised of acrylate repeating units and a resin wherein all the repeating units are comprised of methacrylate repeating units and acrylate repeating units. It is preferred for the acrylate repeating units to account for 50 mol % or less of all the repeating units. More preferably, the resin (B) is a copolymer comprising 20 to 50 mol % of (meth)acrylate repeating unit containing an acid-decomposable group expressed by general formula (AI) above, 20 to 50 mol % of (meth)acrylate repeating unit containing a lactone group, 5 to 30 mol % of (meth)acrylate repeating unit with an alicyclic hydrocarbon structure substituted with a hydroxyl group or a cyano group and 0 to 20 mol % of other (meth)acrylate repeating unit.

When the resist composition of the present invention is exposed to KrF excimer laser light, electron beams, X-rays or high-energy light rays of 50 nm or less wavelength (for example, EUV), it is preferred for the resin (B) to contain a hydroxystyrene repeating unit in addition to the repeating units of general formula (AI). More preferably, the resin (B) contains a hydroxystyrene repeating unit and an acid-decomposable repeating unit, such as a hydroxystyrene repeating unit protected by an acid-decomposable group or a (meth)acrylic acid tertiary alkyl ester.

As preferred repeating units each containing an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl(meth)acrylate and a dialkyl(1-adamantyl)methyl(meth)acrylate are more preferred.

The resin (B) can be synthesized in accordance with routine methods (for example, radical polymerization). As general synthesizing methods, there can be mentioned, for example, a batch polymerization method in which a monomer species and an initiator are dissolved in a solvent and heated to thereby carry out polymerization, a dropping polymerization method in which a solution of monomer species and initiator is dropped into a heated solvent over a period of 1 to 10 hours, and the like. The dropping polymerization method is preferred. As a reaction solvent, there can be mentioned, for example, an ether such as tetrahydrofuran, 1,4-dioxane or diisopropyl ether, a ketone such as methyl ethyl ketone or methyl isobutyl ketone, an ester solvent such as ethyl acetate, an amide solvent such as dimethylformamide or dimethylacetamide, or the solvent capable of dissolving the composition of the present invention, such as propylene glycol monomethyl ether acetate, propylene glycol monomethyl ether or cyclohexanone, to be described hereinafter. Preferably, the polymerization is carried out with the use of the same solvent as that used in the resist composition of the present invention. This inhibits any particle generation during storage.

The polymerization reaction is preferably carried out in an atmosphere comprised of an inert gas, such as nitrogen or argon. The polymerization is initiated by use of a commercially available radical initiator (azo initiator, peroxide, etc.) as a polymerization initiator. Among the radical initiators, an azo initiator is preferred, and azo initiators containing an ester group, a cyano group and a carboxyl group are especially preferred. As specific preferred initiators, there can be mentioned azobisisobutyronitrile, azobisdimethylvaleronitrile, dimethyl 2,2′-azobis(2-methylpropionate) and the like. If desirable, the initiator may be supplemented, or may be added in fractional amounts. After the completion of the reaction, the reaction liquid is poured into a solvent, and the intended polymer is recovered by a method of powder or solid recovery or the like. The reaction concentration is in the range of 5 to 50 mass %, preferably 10 to 30 mass %. The reaction temperature is generally in the range of 10 to 150° C., preferably 30 to 120° C. and more preferably 60 to 100° C.

The weight average molecular weight of the resin (B), in terms of polystyrene-equivalent value measured by GPC, is preferably in the range of 1000 to 200,000. It is more preferably in the range of 2000 to 20,000, further more preferably 3000 to 15,000 and most preferably 3000 to 10,000. By regulating the weight average molecular weight so as to fall within the range of 1000 to 200,000, not only can any deteriorations of heat resistance and dry etching resistance be prevented but also any deterioration of developability and any increase of viscosity leading to poor film forming property can be prevented.

The polydispersity index (molecular weight distribution) of the resin is generally in the range of 1 to 3, preferably 1 to 2.6, more preferably 1 to 2 and most preferably 1.4 to 1.7. The narrower the molecular weight distribution, the more outstanding the resolution and resist shape. Further, the side wall of the resist pattern can be smooth to thereby ensure excellent roughness characteristics.

In the resist composition of the present invention, the content of resin (B) in the whole composition is preferably in the range of 50 to 99 mass %, more preferably 60 to 95 mass %, based on the total solids of the composition.

In the present invention, one type of rein (B) may be used alone, or two or more types thereof may be used in combination.

[3] Hydrophobic Resin

The actinic-ray- or radiation-sensitive resin composition of the present invention may further comprise a hydrophobic resin (hereinafter also referred to as “hydrophobic resin (HR)”) containing at least either a fluorine atom or a silicon atom, especially when a liquid immersion exposure is applied thereto. This localizes the hydrophobic resin (HR) in the surface layer of the film. Accordingly, when the immersion medium is water, the static/dynamic contact angle of the surface of the resist film with respect to water can be increased, thereby enhancing the immersion liquid tracking property.

Although the hydrophobic resin (HR) is localized in the interface as mentioned above, as different from surfactants, the hydrophobic resin does not necessarily have to contain a hydrophilic group in its molecule and does not need to contribute toward uniform mixing of polar/nonpolar substances.

The hydrophobic resin typically contains a fluorine atom and/or a silicon atom. In the hydrophobic resin (HR), the fluorine atom and/or silicon atom may be introduced in the principal chain of the resin, or a side chain thereof.

When the hydrophobic resin contains a fluorine atom, it is preferred for the resin to comprise, as a partial structure containing a fluorine atom, an alkyl group containing a fluorine atom, a cycloalkyl group containing a fluorine atom or an aryl group containing a fluorine atom.

The alkyl group containing a fluorine atom is a linear or branched alkyl group having at least one hydrogen atom thereof replaced by a fluorine atom. The alkyl group preferably has 1 to 10 carbon atoms, more preferably 1 to 4 carbon atoms. Further, other substituents may be introduced therein.

The cycloalkyl group containing a fluorine atom is a mono- or polycycloalkyl group having at least one hydrogen atom thereof replaced by a fluorine atom. Further, other substituents may be introduced therein.

As the aryl group containing a fluorine atom, there can be mentioned an aryl group, such as a phenyl or naphthyl group, having at least one hydrogen atom thereof replaced by a fluorine atom. Further, other substituents may be introduced therein.

As preferred alkyl groups containing a fluorine atom, cycloalkyl groups containing a fluorine atom and aryl groups containing a fluorine atom, there can be mentioned groups of any of general formulae (F2) to (F4) below, which however in no way limit the scope of the present invention.

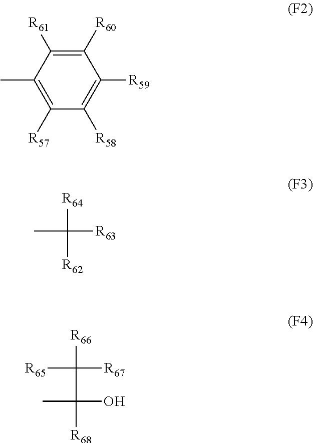

In general formulae (F2) to (F4),

each of R₅₇ to R₆₈ independently represents a hydrogen atom, a fluorine atom or an alkyl group (linear or branched), provided that at least one of R₅₇-R₆₁, at least one of R₆₂-R₆₄, and at least one of R₆₅-R₆₈, represents a fluorine atom or an alkyl group (preferably having 1 to 4 carbon atoms) having at least one hydrogen atom thereof replaced by a fluorine atom.

It is preferred for all of R₅₇ to R₆₁ and R₆₅ to R₆₇ to represent fluorine atoms. Each of R₆₂, R₆₃ and R₆₈ is preferably a fluoroalkyl group (especially having 1 to 4 carbon atoms), more preferably a perfluoroalkyl group having 1 to 4 carbon atoms. When R₆₂ and R₆₃ are perfluoroalkyl groups, it is preferred for R₆₄ to be a hydrogen atom. R₆₂ and R₆₃ may be connected to each other to thereby form a ring.

Specific examples of the groups of general formula (F2) include a p-fluorophenyl group, a pentafluorophenyl group, a 3,5-di(trifluoromethyl)phenyl group and the like.

Specific examples of the groups of general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro (2-methyl) isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups of general formula (F4) include —C(CF₃)₂OH, —C(C₂F₅)₂OH, —C(CF₃) (CH₃) OH, —CH(CF₃) OH and the like. —C(CF₃)₂OH is preferred.

Each of the partial structures containing a fluorine atom may be directly bonded to the principal chain, or may be bonded to the principal chain via a group selected from the group consisting of an alkylene group, a phenylene group, an ether bond, a thioether bond, a carbonyl group, an ester bond, an amide bond, a urethane bond and a ureylene bond, or via a group composed of a combination of two or more of these.

Preferred repeating units each containing a fluorine atom are shown below.

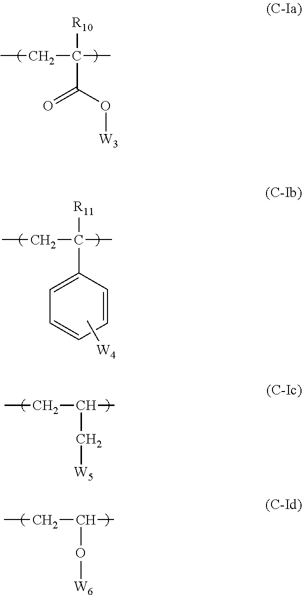

In formulae (C-Ia) to (C-Id), each of R₁₀ and R₁₁ independently represents a hydrogen atom, a fluorine atom or an alkyl group. The alkyl group is preferably a linear or branched alkyl group having 1 to 4 carbon atoms. A substituent may be introduced therein. In particular, a fluoroalkyl group can be mentioned as a substituted alkyl group.

Each of W₃ to W₆ independently represents an organic group containing at least one fluorine atom. As examples thereof, there can be mentioned the atomic groups of general formulae (F2) to (F4) above.

Further, the hydrophobic resin may contain any of the following repeating units other than those mentioned above as a repeating unit containing a fluorine atom.

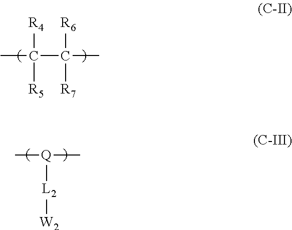

In formulae (C-II) and (C-III), each of R₄ to R₇ independently represents a hydrogen atom, a fluorine atom or an alkyl group. The alkyl group is preferably a linear or branched alkyl group having 1 to 4 carbon atoms. A substituent may be introduced therein. In particular, a fluoroalkyl group can be mentioned as a substituted alkyl group.

However, at least one of R₄ to R₇ represents a fluorine atom. A ring may be formed by R₄ in cooperation with R₅, or R₆ in cooperation with R₇.

W₂ represents an organic group containing at least one fluorine atom. As examples thereof, there can be mentioned the atomic groups of general formulae (F2) to (F4) above.

L₂ represents a single bond or a bivalent connecting group. The bivalent connecting group refers to a substituted or unsubstituted arylene group, a substituted or unsubstituted alkylene group, a substituted or unsubstituted cycloalkylene group, —O—, —SO₂—, —CO—, —NR— (in the formula, R represents a hydrogen atom or an alkyl group), —NHSO₂— or a bivalent connecting group comprised of a combination of two or more of these.

Q represents an alicyclic structure. A substituent may be introduced in the alicyclic structure. The alicyclic structure may be monocyclic or polycyclic. The alicyclic structure when being polycyclic may be a bridged one. The alicyclic structure when being monocyclic is preferably a cycloalkyl group having 3 to 8 carbon atoms. As such, there can be mentioned, for example, a cyclopentyl group, a cyclohexyl group, a cyclobutyl group, a cyclooctyl group or the like. As the polycyclic one, there can be mentioned a group with, for example, a bicyclo, tricyclo or tetracyclo structure having 5 or more carbon atoms. A cycloalkyl group having 6 to 20 carbon atoms is preferred. As such, there can be mentioned, for example, an adamantyl group, a norbornyl group, a dicyclopentyl group, a tricyclodecanyl group, a tetracyclododecyl group or the like. At least one carbon atom of the cycloalkyl group may be replaced with a heteroatom, such as an oxygen atom. It is especially preferred for Q to represent a norbornyl group, a tricyclodecanyl group, a tetracyclododecyl group or the like.

The hydrophobic resin may contain a silicon atom.

It is preferred for the hydrophobic resin to contain an alkylsilyl structure (preferably a trialkylsilyl group) or a cyclosiloxane structure as a partial structure containing a silicon atom.

As the alkylsilyl structure or cyclosiloxane structure, there can be mentioned, for example, any of the groups of general formulae (CS-1) to (CS-3) below or the like.

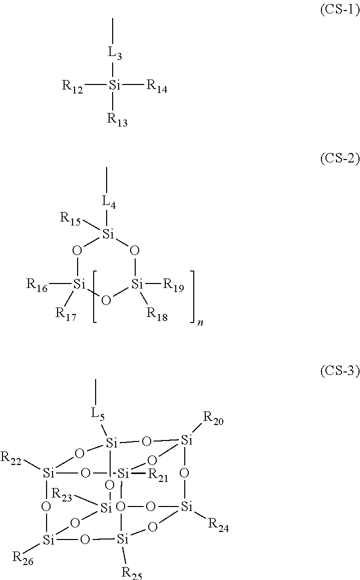

In general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one, or a combination of two or more members, selected from the group consisting of an alkylene group, a phenylene group, an ether bond, a thioether bond, a carbonyl group, an ester bond, an amide bond, a urethane bond and a ureylene bond.

In the formulae, n is an integer of 1 to 5, preferably an integer of 2 to 4.

The repeating unit containing at least either a fluorine atom or a silicon atom is preferably comprised of a (meth)acrylate repeating unit.

Particular examples of the repeating units each containing at least either a fluorine atom or a silicon atom are shown below, which in no way limit the scope of the present invention. In the particular examples, X₁ represents a hydrogen atom, —CH₃, —F or —CF₃, and X₂ represents —F or —CF.

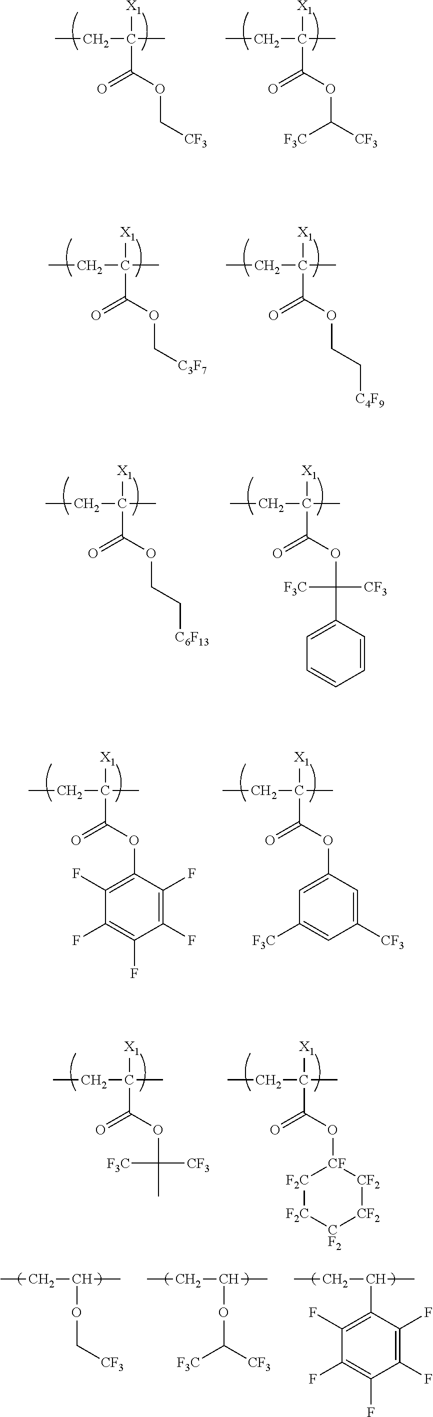

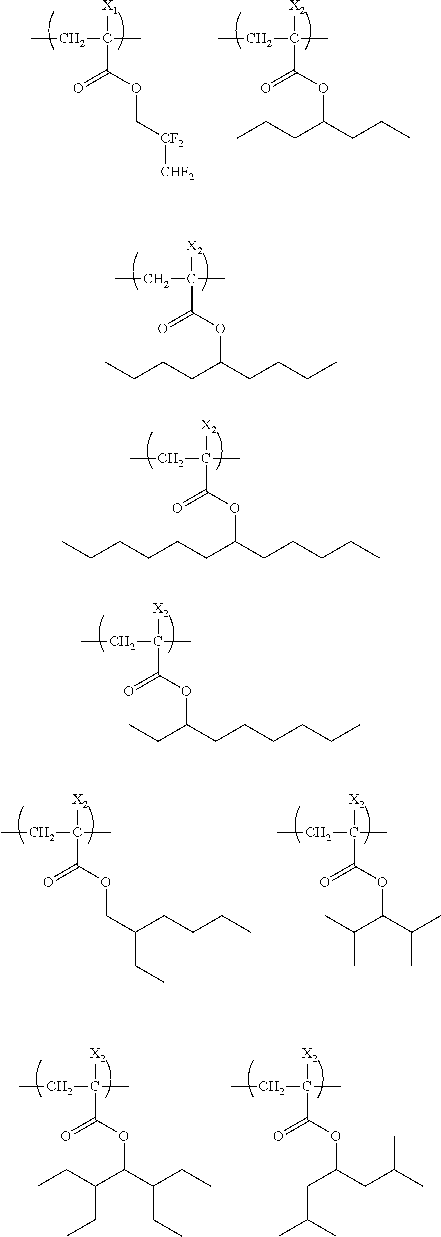

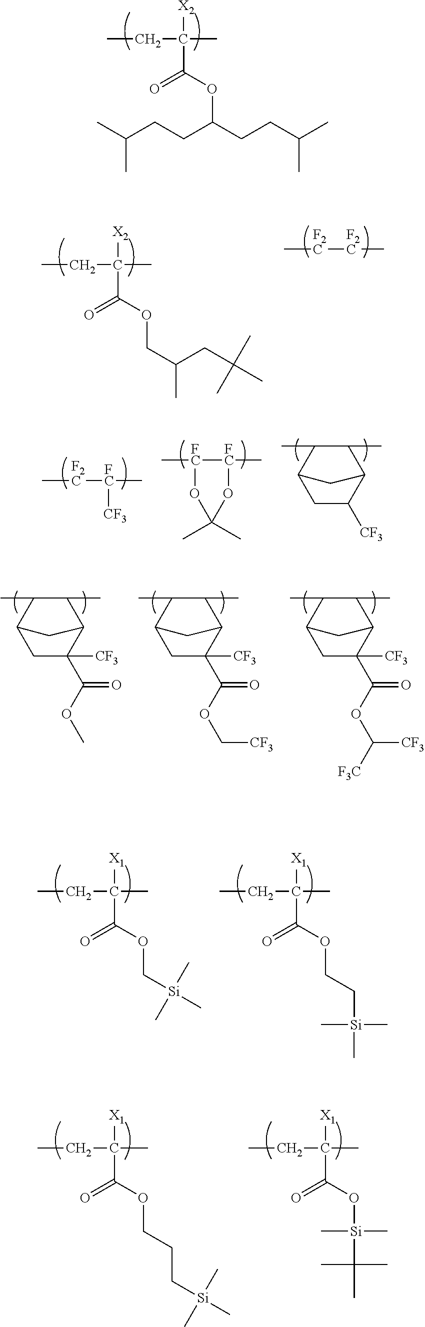

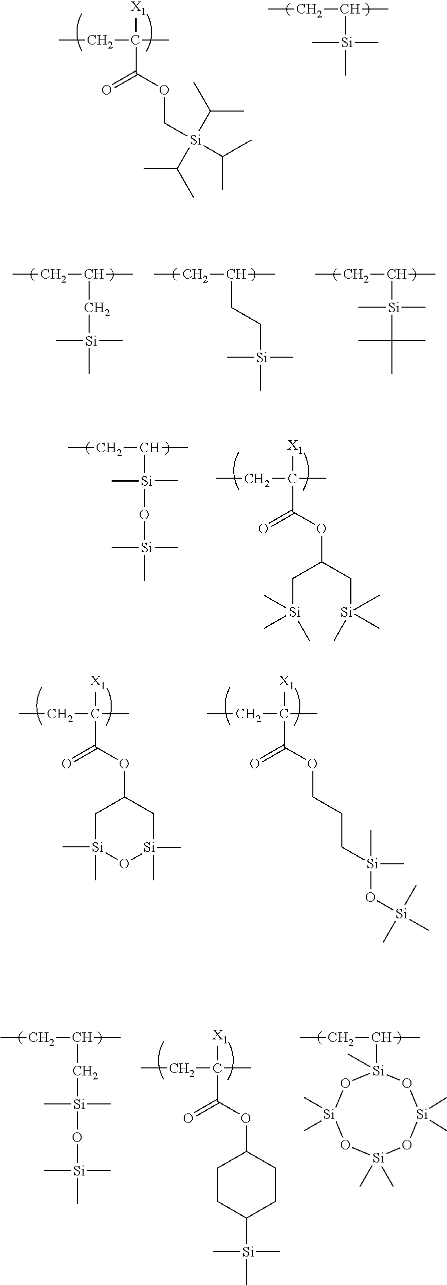

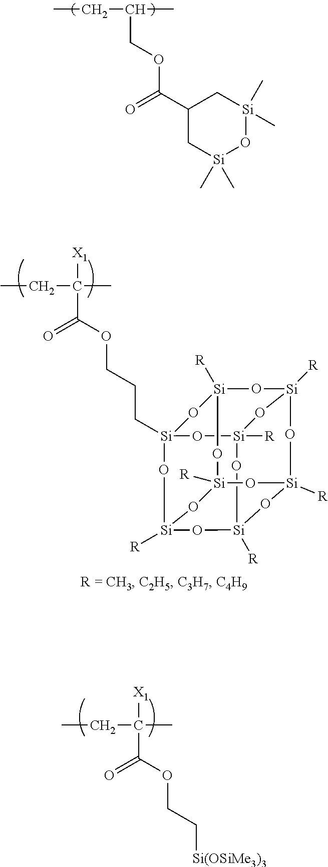

It is preferred for the hydrophobic resin to contain a repeating unit (b) containing at least one group selected from the group consisting of the following groups (x) to (z).

Namely,

(x) an alkali-soluble group,

(y) a group (hereinafter also referred to as polarity conversion group) that when acted on by an alkali developer, is decomposed to thereby increase its solubility in the alkali developer, and

(z) a group that when acted on by an acid, is decomposed to thereby increase its solubility in an alkali developer.

The following varieties of repeating units (b) can be mentioned.

Namely, the repeating unit (b) may be:

a repeating unit (b′) containing at least either a fluorine atom or a silicon atom and at least one group selected from the group consisting of the above groups (x) to (z) simultaneously introduced in one side chain thereof,

a repeating unit (b*) containing at least one group selected from the group consisting of the above groups (x) to (z) but containing neither a fluorine atom nor a silicon atom, or

a repeating unit (b″) in which at least one group selected from the group consisting of the above groups (x) to (z) is introduced in its one side chain while at least either a fluorine atom or a silicon atom is introduced in a side chain other than the above side chain within the same repeating unit.

It is preferred for the hydrophobic resin to contain the repeating unit (b′) as the repeating unit (b). Namely, it is preferred for the repeating unit (b) containing at least one group selected from the group consisting of the above groups (x) to (z) to further contain at least either a fluorine atom or a silicon atom.

When the hydrophobic resin contains the repeating unit (b*), it is preferred for the hydrophobic resin to be a copolymer with a repeating unit (repeating unit other than the above-mentioned repeating units (b′) and (b″)) containing at least either a fluorine atom or a silicon atom. In the repeating unit (b″), it is preferred for the side chain containing at least one group selected from the group consisting of the above groups (x) to (z) and the side chain containing at least either a fluorine atom or a silicon atom to be bonded to the same carbon atom of the principal chain, namely, to be in a positional relationship shown in formula (K1) below.

In the formula, B1 represents a partial structure containing at least one group selected from the group consisting of the above groups (x) to (z), and B2 represents a partial structure containing at least either a fluorine atom or a silicon atom.

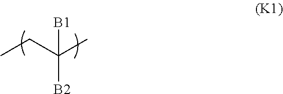

The group selected from the group consisting of the above groups (x) to (z) is preferably (x) an alkali-soluble group or (y) a polarity conversion group, more preferably (y) a polarity conversion group.

As the alkali-soluble group (x), there can be mentioned a phenolic hydroxyl group, a carboxylic acid group, a fluoroalcohol group, a sulfonic acid group, a sulfonamido group, a sulfonylimido group, an (alkylsulfonyl) (alkylcarbonyl)methylene group, an (alkylsulfonyl) (alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a fluoroalcohol group (preferably hexafluoroisopropanol), a sulfonylimido group and a bis(alkylcarbonyl)methylene group.

As the repeating unit (bx) containing an alkali-soluble group (x), there can be mentioned, for example, a repeating unit resulting from direct bonding of an alkali-soluble group to the principal chain of a resin, such as a repeating unit of acrylic acid or methacrylic acid, or a repeating unit resulting from bonding, via a connecting group, of an alkali-soluble group to the principal chain of a resin. Further, such a repeating unit can be obtained by conducting polymerization with the use of a chain transfer agent or polymerization initiator containing an alkali-soluble group to thereby introduce the same in a polymer chain terminal. All of these repeating units are preferred.

When the repeating unit (bx) is a repeating unit containing at least either a fluorine atom or a silicon atom (namely, when corresponding to the above-mentioned repeating unit (b′) or repeating unit (b″)), the partial structure containing a fluorine atom contained in the repeating unit (bx) can be the same as set forth above in connection with the repeating unit containing at least either a fluorine atom or a silicon atom. As such, preferably, there can be mentioned any of the groups of general formulae (F2) to (F4) above. Also in that instance, the partial structure containing a silicon atom contained in the repeating unit (bx) can be the same as set forth above in connection with the repeating unit containing at least either a fluorine atom or a silicon atom. As such, preferably, there can be mentioned any of the groups of general formulae (CS-1) to (CS-3) above.

The content of repeating unit (bx) containing an alkali-soluble group (x) is preferably in the range of 1 to 50 mol %, more preferably 3 to 35 mol % and further more preferably 5 to 20 mol %, based on all the repeating units of the hydrocarbon resin.

Particular examples of the repeating units (bx) each containing an alkali-soluble group (x) are shown below, which in no way limit the scope of the present invention. In the particular examples, X₁ represents a hydrogen atom, —CH₃, —F or CF₃, and Rx represents H, CH₃, CF₃ or CH₂OH.

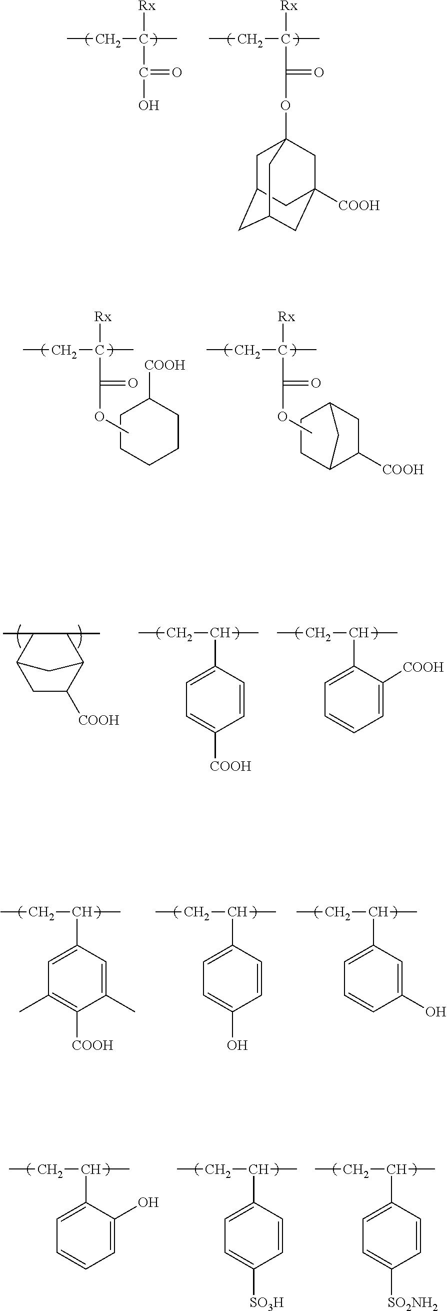

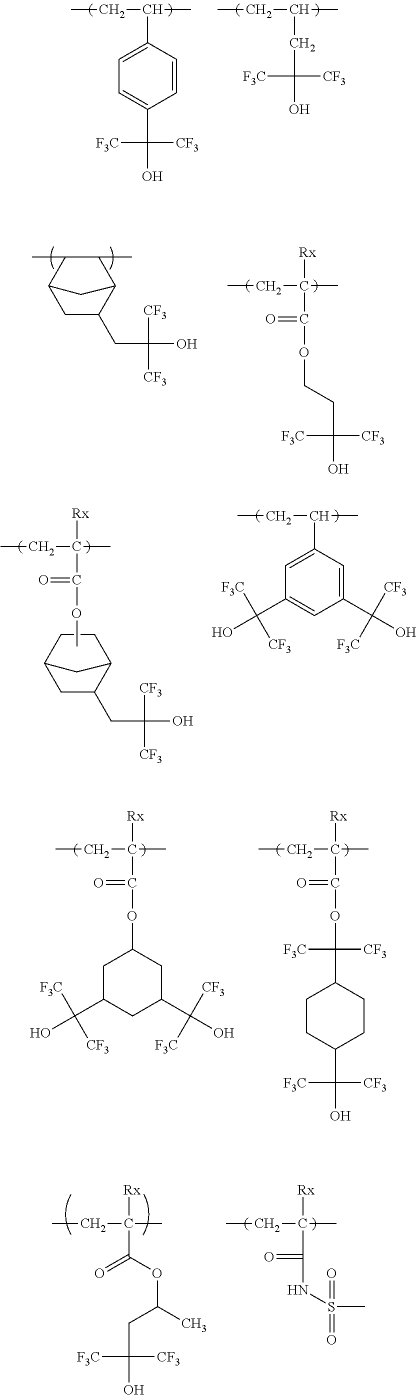

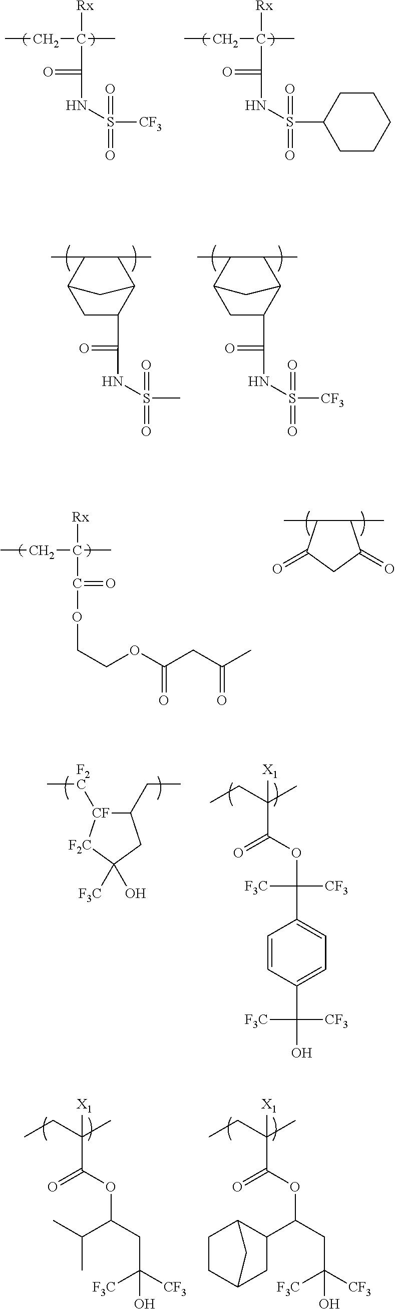

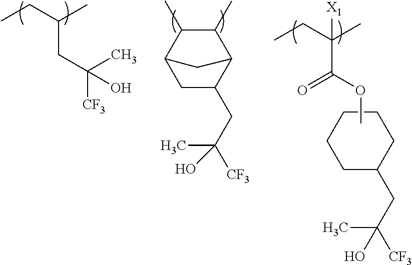

As the polarity conversion group (y), there can be mentioned, for example, a lactone group, a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—), a sulfonic ester group (—SO₂O—) or the like. A lactone group is preferred.

Both the form in which the polarity conversion group (y) is contained in a repeating unit of, for example, acrylic ester or methacrylic ester and thus introduced in a side chain of the resin and the form in which the polarity conversion group (y) is introduced in a polymer chain terminal by conducting polymerization with the use of a chain transfer agent or polymerization initiator containing the polarity conversion group (y) are preferred.

As particular examples of the repeating units (by) each containing the polarity conversion group (y), there can be mentioned the repeating units each having a lactone structure of formulae (KA-1-1) to (KA-1-17) to be shown hereinafter.

It is preferred for the repeating unit (by) containing the polarity conversion group (y) to be one further containing at least either a fluorine atom or a silicon atom (namely, corresponding to the above-mentioned repeating unit (b′) or repeating unit (b″)) Any resin comprising this repeating unit (by) is hydrophobic and is especially preferred from the viewpoint of suppression of development defects.

As the repeating unit (by), there can be mentioned, for example, any of the repeating units of formula (K0) below.

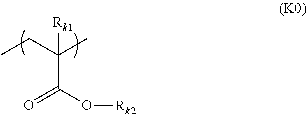

In the formula, Rₖ₁ represents a hydrogen atom, a halogen atom, a hydroxyl group, an alkyl group, a cycloalkyl group, an aryl group or a group containing a polarity conversion group, and

Rₖ₂ represents an alkyl group, a cycloalkyl group, an aryl group or a group containing a polarity conversion group,

provided that at least one of Rₖ₁ and Rₖ₂ is a group containing a polarity conversion group.

The polarity conversion group, as mentioned above, refers to a group that is decomposed by the action of an alkali developer to thereby increase its solubility in the alkali developer. It is preferred for the polarity conversion group to be a group represented by X in the partial structures of general formulae (KA-1) and (KB-1) below.

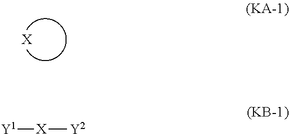

In general formulae (KA-1) and (KB-1), X represents a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—) or a sulfonic ester group (—SO₂O—).

Y¹ and Y² may be identical to or different from each other and each represent an electron withdrawing group.

The repeating unit (by) contains a group whose solubility in an alkali developer is preferably increased by containing a group with the partial structure of general formula (KA-1) or (KB-1). When the partial structure has no bonding hand, as in the case of the partial structure of general formula (KA-1) or the partial structure of general formula (KB-1) in which Y¹ and Y² are monovalent, the above group with the partial structure refers to a group containing a monovalent or higher-valent group resulting from the removal of at least one arbitrary hydrogen atom from the partial structure.

The partial structure of general formula (KA-1) or (KB-1) is linked at its arbitrary position to the principal chain of the hydrocarbon resin via a substituent.

The partial structure of general formula (KA-1) is a structure in which a ring structure is formed in cooperation with a group represented by X.

In general formula (KA-1), X is preferably a carboxylic ester group (namely, in the case of the formation of a lactone ring structure as KA-1), an acid anhydride group or a carbonic ester group. More preferably, X is a carboxylic ester group.

A substituent may be introduced in the ring structure of general formula (KA-1). For example, nka substituents each represented by Zₖₐ₁ may be introduced therein.

Zₖₐ₁, or each of a plurality of Zₖₐ₁S independently, represents a halogen atom, an alkyl group, a cycloalkyl group, an ether group, a hydroxyl group, an amido group, an aryl group, a lactone ring group or an electron withdrawing group.

Zₖₐ₁S may be connected to each other to thereby form a ring. As the ring formed by the mutual connection of Zₖₐ₁s, there can be mentioned, for example, a cycloalkyl ring or a heterocycle (for example, a cycloether ring or a lactone ring).

The above nka is an integer of 0 to 10, preferably 0 to 8, more preferably 0 to 5, further more preferably 1 to 4 and most preferably 1 to 3.

The electron withdrawing groups represented by Zₖₐ₁ are the same as mentioned above in connection with Y¹ and Y². These electron withdrawing groups may be substituted with other electron withdrawing groups.

Zₖₐ₁ is preferably an alkyl group, a cycloalkyl group, an ether group, a hydroxyl group or an electron withdrawing group. Zₖₐ₁ is more preferably an alkyl group, a cycloalkyl group or an electron withdrawing group. It is preferred for the ether group to be one substituted with, for example, an alkyl group or a cycloalkyl group, namely, to be an alkyl ether group or the like. The electron withdrawing group is as mentioned above.

Impurities, such as metals, should naturally be in low quantities in the hydrophobic resin, as in the above-described resin (B). Further, the amount of residual monomers and oligomer components is preferably 0 to 10 mass %, more preferably 0 to 5 mass % and further more preferably 0 to 1 mass %. Accordingly, there can be obtained a resist composition that is free from any change over time of in-liquid foreign matter, sensitivity, etc. From the viewpoint of resolution, resist shape, side wall of resist pattern, roughness, etc., the molecular weight distribution (Mw/Mn, also referred to as polydispersity index) of the hydrophobic resin is preferably in the range of 1 to 3, more preferably 1 to 2, further more preferably 1 to 1.8 and most preferably 1 to 1.5.

A variety of commercially available products can be used as the hydrophobic resin. Alternatively, the hydrophobic resin can be synthesized in accordance with routine methods (for example, radical polymerization). As general synthesizing methods, there can be mentioned, for example, a batch polymerization method in which a monomer species and an initiator are dissolved in a solvent and heated to thereby carry out polymerization, a dropping polymerization method in which a solution of monomer species and initiator is dropped into a heated solvent over a period of 1 to 10 hours, etc. The dropping polymerization method is preferred.

The reaction solvent, polymerization initiator, reaction conditions (temperature, concentration, etc.) and purification method after reaction are the same as described above in connection with the resin (B).

Specific examples of the hydrophobic resins (HR) are shown below. Table 1 below lists the molar ratio of individual repeating units (the positional relationship of individual repeating units of each of the resins shown in the specific examples corresponds to the positional relationship of component ratio numeric values in Table 1), weight average molecular weight and polydispersity index with respect to each of the resins.

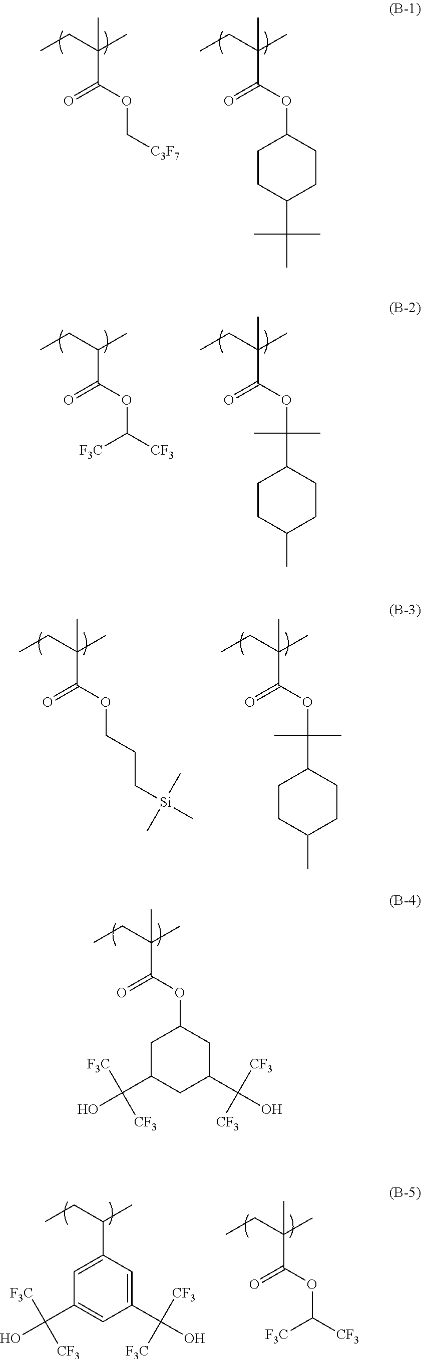

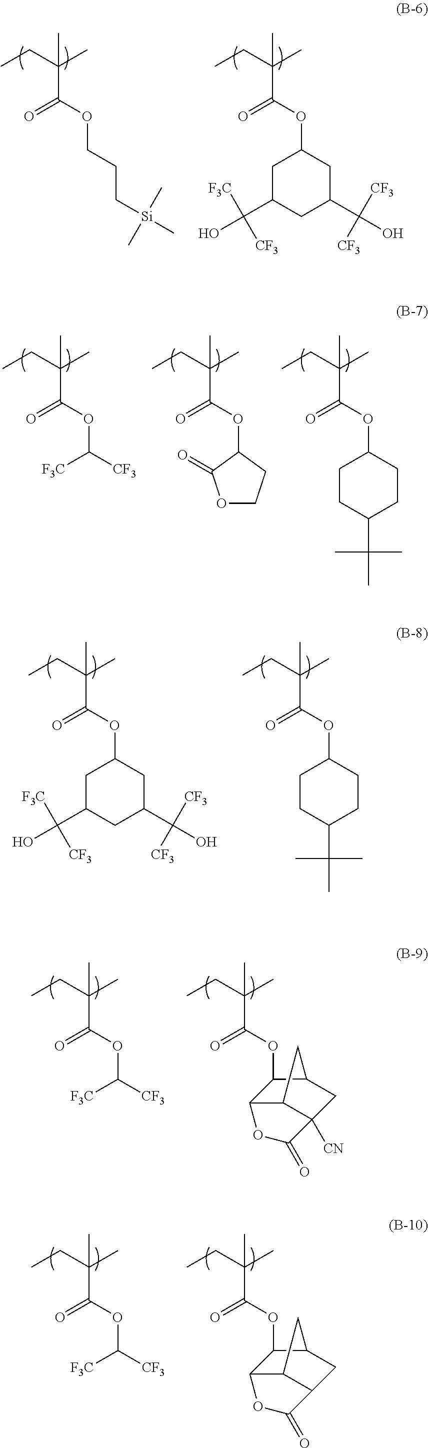

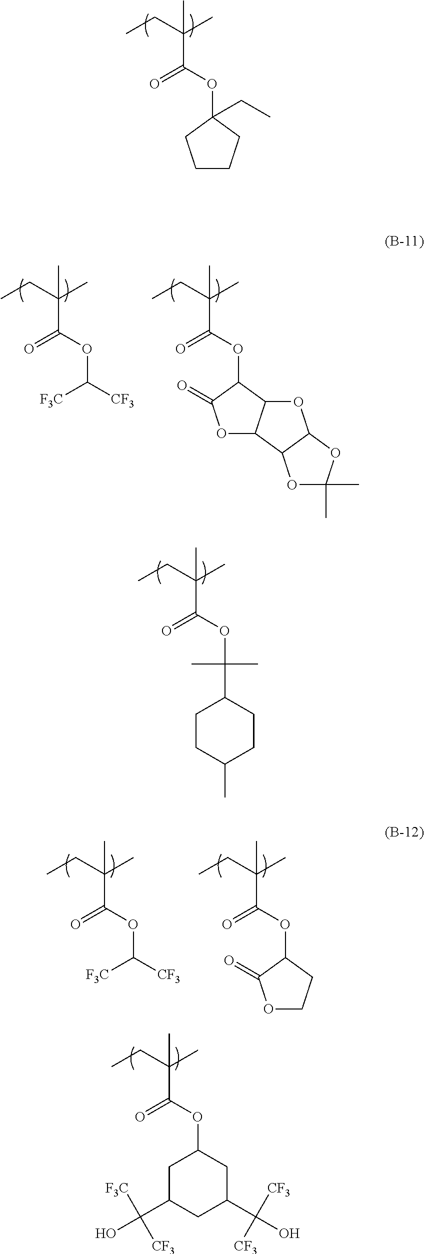

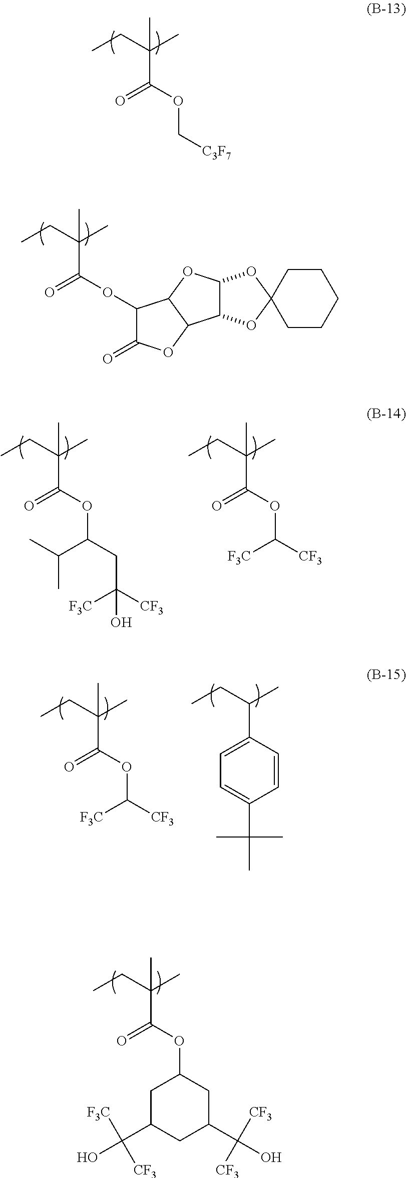

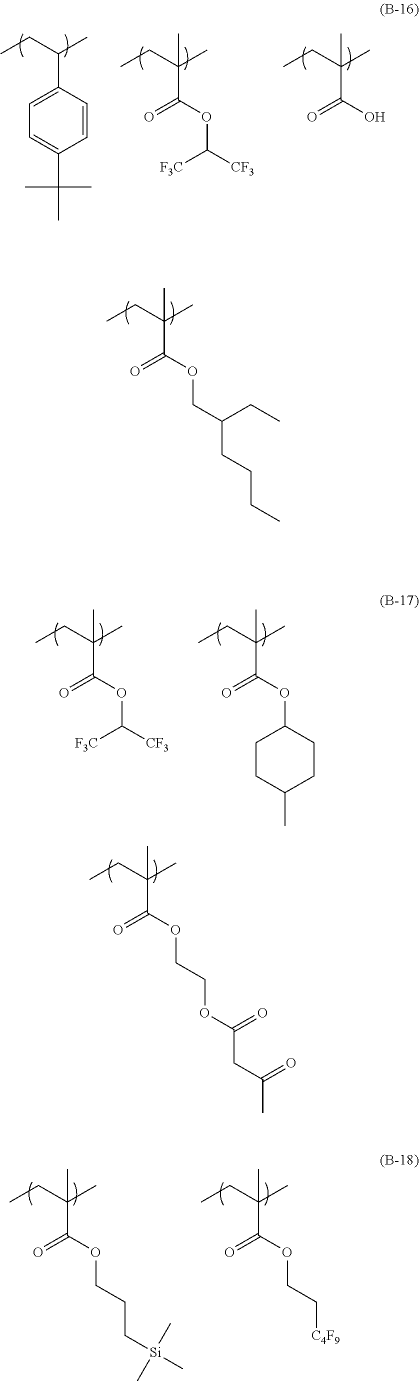

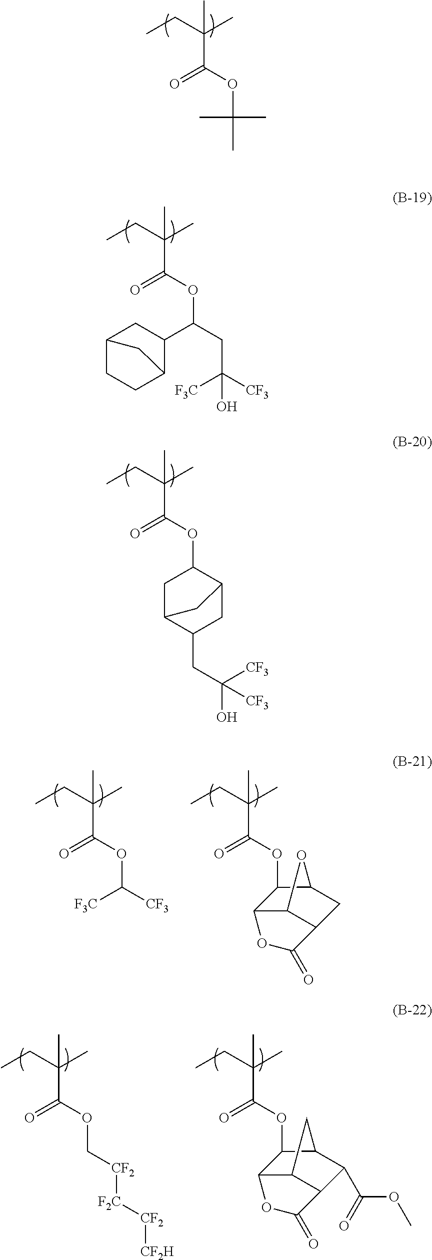

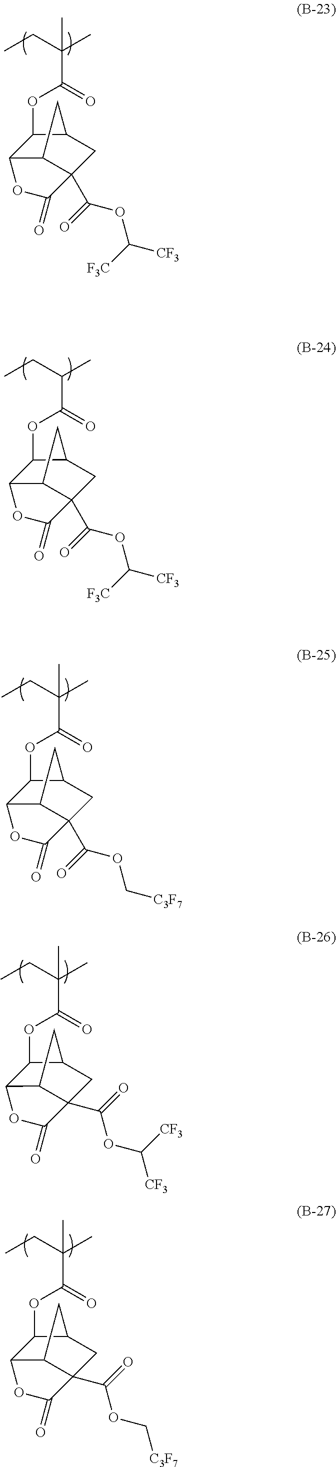

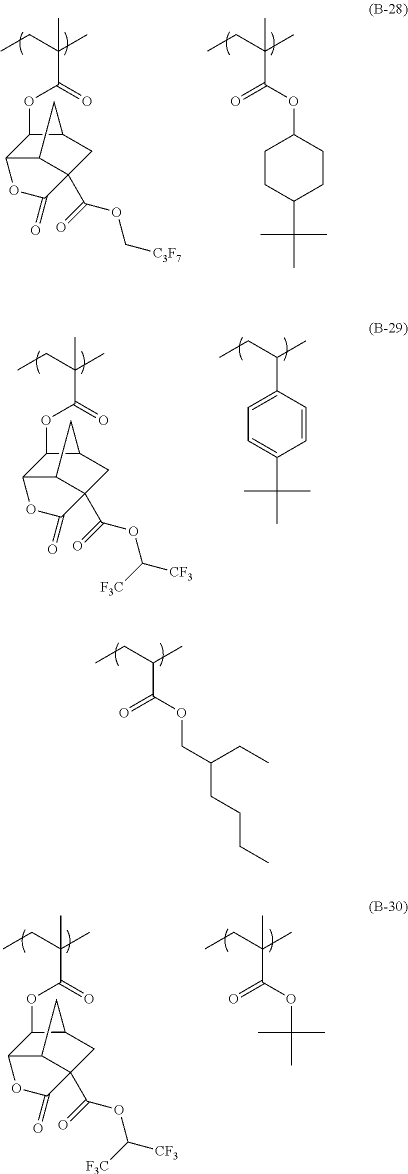

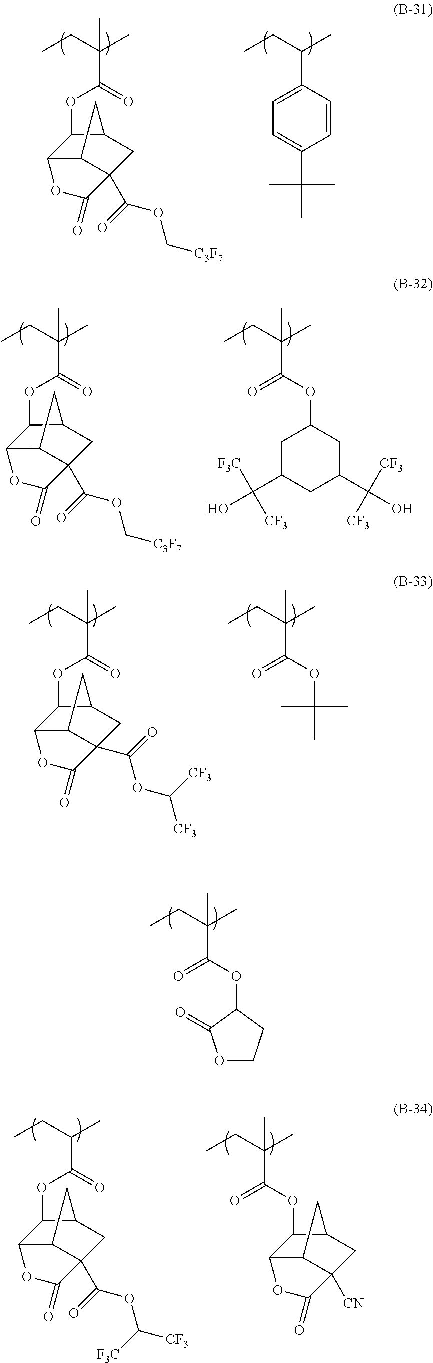

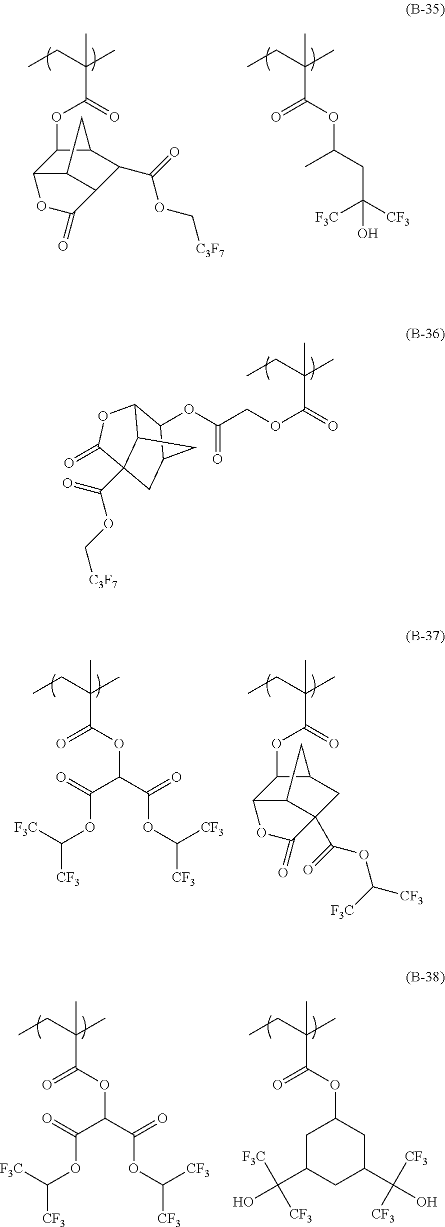

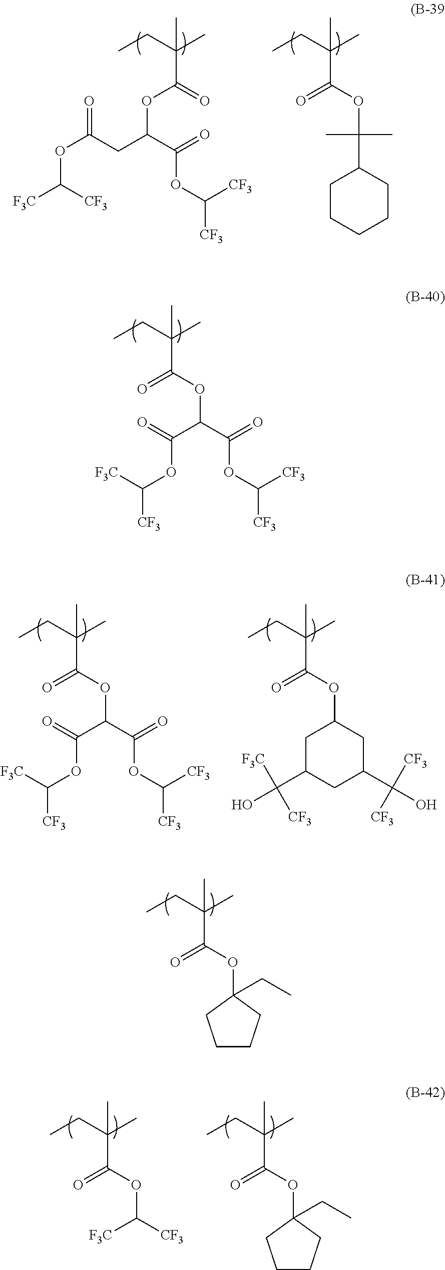

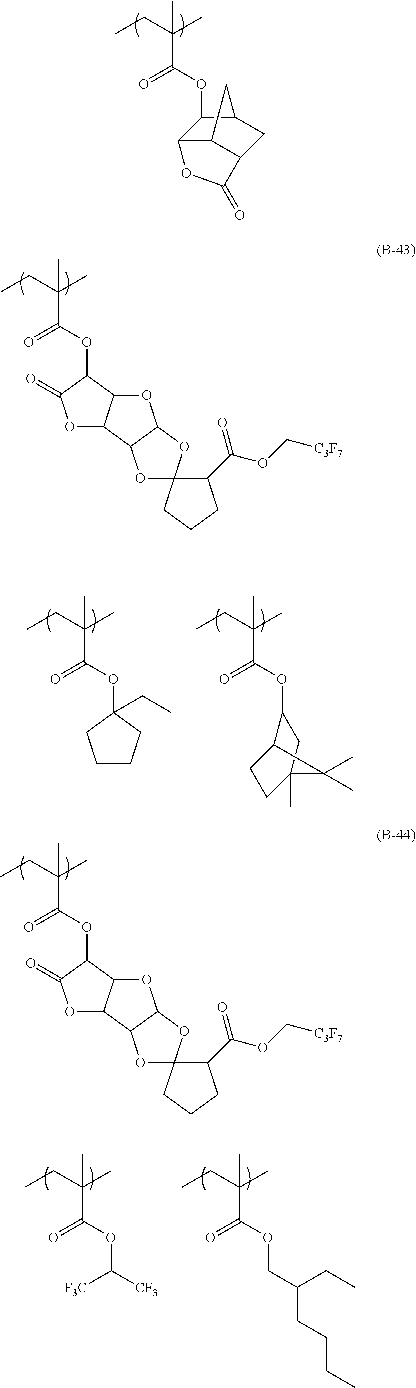

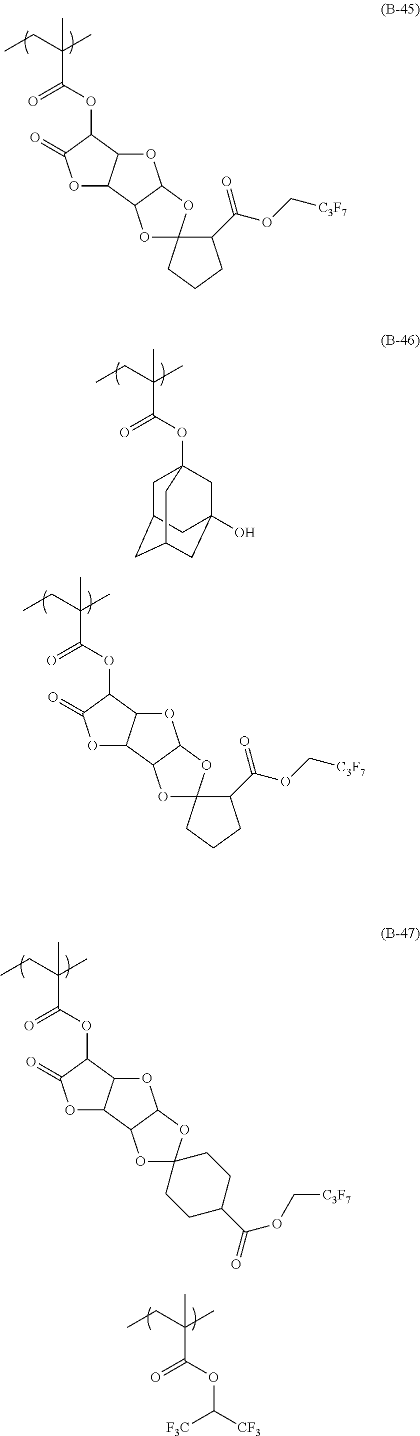

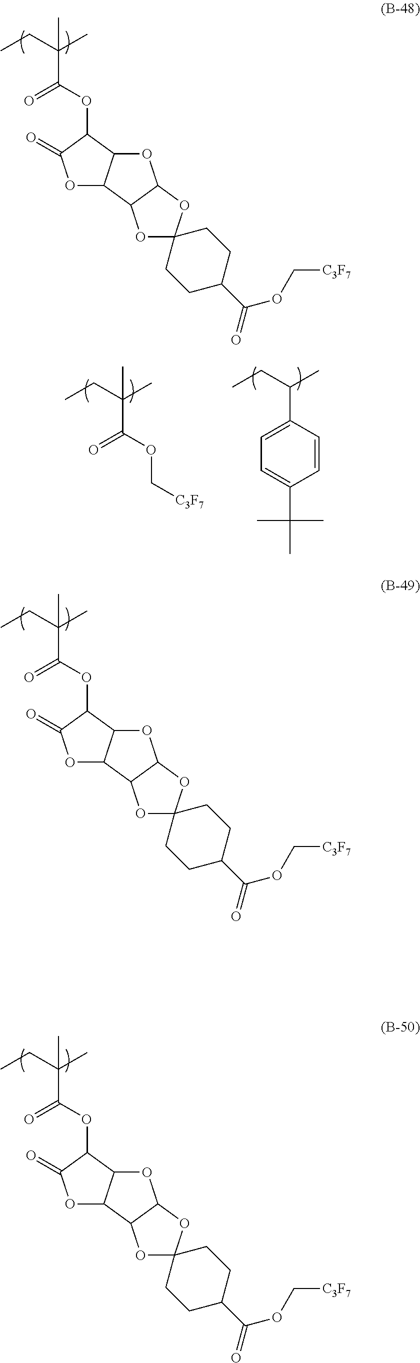

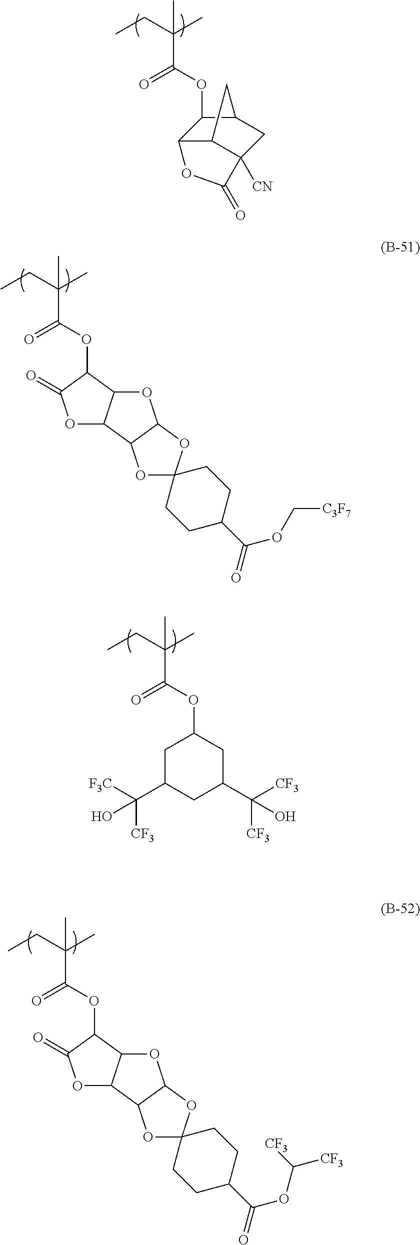

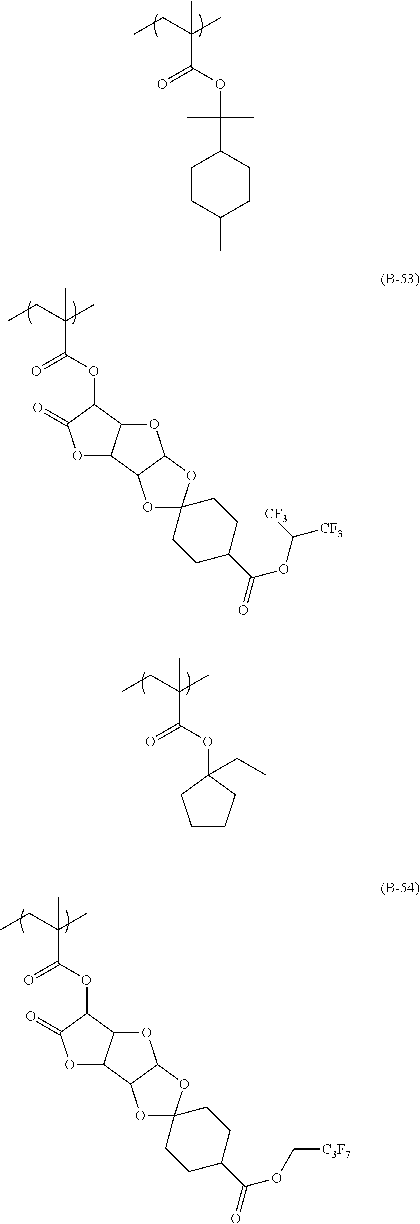

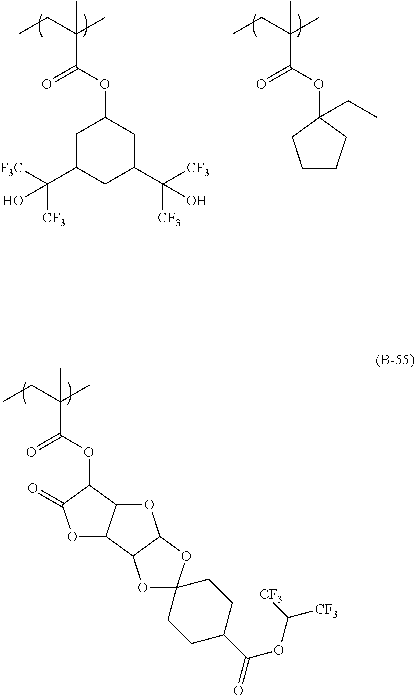

TABLE 1

| | Component. | | |
|---|---|---|---|
| | ratio | | |
| Resin | (mol %) | Mw | Mw/Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

When the hydrophobic resin containing at least either a fluorine atom or a silicon atom is contained in the actinic-ray- or radiation-sensitive resin composition of the present invention, the hydrophobic resin is localized in a surface layer of the film formed from the actinic-ray- or radiation-sensitive resin composition, so that in the use of water as a liquid-immersion medium, the receding contact angle of the surface of the film after bake but before exposure with water can be increased to thereby enhance the immersion liquid tracking property.

The receding contact angle of the post-bake but pre-exposure film from the actinic-ray- or radiation-sensitive resin composition of the present invention, as measured at exposure temperature, generally room temperature 23±3° C. in a humidity of 45±5%, is preferably in the range of 60° to 90°, more preferably 65° or greater, further more preferably 70° or greater and most preferably 75° or greater.

Although the hydrophobic resin is localized in an interface as mentioned above, as different from surfactants, the hydrophobic resin does not necessarily have to contain a hydrophilic group in its molecule and does not need to contribute toward uniform mixing of polar/nonpolar substances.

In the operation of liquid-immersion exposure, it is needed for the immersion liquid to move on a wafer while tracking the movement of an exposure head conducting high-speed scanning on the wafer and thus forming an exposure pattern. Therefore, the contact angle of the immersion liquid with respect to the resist film in dynamic condition is important, and it is required for the resist to be capable of tracking the high-speed scanning of the exposure head without leaving any droplets.

As the hydrophobic resin is hydrophobic, the problems of development residue (scum) and blob defect after alkali development are likely to become serious. However, improvement with respect to the development residue (scum) and blob defect can be attained by an increase of alkali dissolution rate that is realized by containing three or more polymer chains combined together via at least one branch moiety, as compared with linear chain resins.

When the hydrophobic resin contains a fluorine atom, the content of fluorine atom based on the molecular weight of the hydrophobic resin is preferably in the range of 5 to 80 mass %, more preferably 10 to 80 mass %. The repeating unit containing a fluorine atom is preferably contained in an amount of 10 to 100 mol %, more preferably 30 to 100 mol %, based on all the repeating units of the hydrophobic resin.

When the hydrophobic resin contains a silicon atom, the content of silicon atom based on the molecular weight of the hydrophobic resin is preferably in the range of 2 to 50 mass %, more preferably 2 to 30 mass %. The repeating unit containing a silicon atom is preferably contained in an amount of 10 to 90 mol %, more preferably 20 to 80 mol %, based on all the repeating units of the hydrophobic resin.

The weight average molecular weight of the hydrophobic resin is preferably in the range of 1000 to 100,000, more preferably 2000 to 50,000 and further more preferably 3000 to 35,000. Herein, the weight average molecular weight of the resin refers to a polystyrene-equivalent molecular weight measured by GPC (carrier: tetrahydrofuran (THF)).

The content of hydrophobic resin in the actinic-ray- or radiation-sensitive resin composition is appropriately regulated so that the receding contact angle of the actinic-ray- or radiation-sensitive resin film falls within the above-mentioned range before the use of the composition. Based on the total solids of the actinic-ray- or radiation-sensitive resin composition, the content is preferably in the range of 0.01 to 20 mass %, more preferably 0.1 to 15 mass %, further more preferably 0.1 to 10 mass % and most preferably 0.2 to 8 mass %.

One type of hydrophobic resin may be used alone, or two or more types thereof may be used in combination.

[4](D) Low-molecular compound containing a nitrogen atom and containing a group leaving under the action of an acid

The composition of the present invention may contain a low-molecular compound (hereinafter also referred to as “low-molecular compound (D)” or “compound (D)”) containing a nitrogen atom and containing a group leaving under the action of an acid.

The group leaving under the action of an acid is not particularly limited. However, the group is preferably an acetal group, a carbonate group, a carbamate group, a tertiary ester group, a tertiary hydroxyl group or a hemiaminal ether group, most preferably a carbamate group or a hemiaminal ether group.

The molecular weight of the low-molecular compound (D) containing a group leaving under the action of an acid is preferably in the range of 100 to 1000, more preferably 100 to 700 and most preferably 100 to 500.

It is preferred for the compound (D) to be an amine derivative in which the group leaving under the action of an acid is contained on its nitrogen atom.

The compound (D) may contain a carbamate group in which a protective group is provided on its nitrogen atom. The protective group as a constituent of the carbamate group can be expressed by general formula (d-1) below.

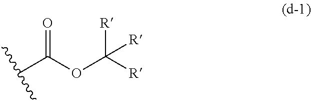

In general formula (d-1),

each of R's independently represents a hydrogen atom, a linear or branched alkyl group, a cycloalkyl group, an aryl group, an aralkyl group or an alkoxyalkyl group. R's may be bonded to each other to thereby form a ring.

Preferably, R′ is a linear or branched alkyl group, a cycloalkyl group or an aryl group, more preferably a linear or branched alkyl group or a cycloalkyl group.

Particular examples of these groups are shown below.

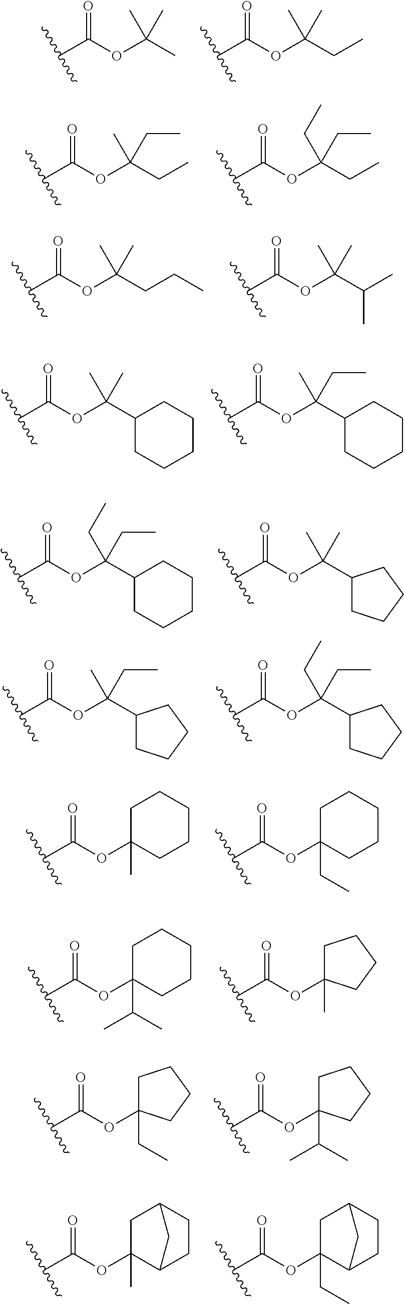

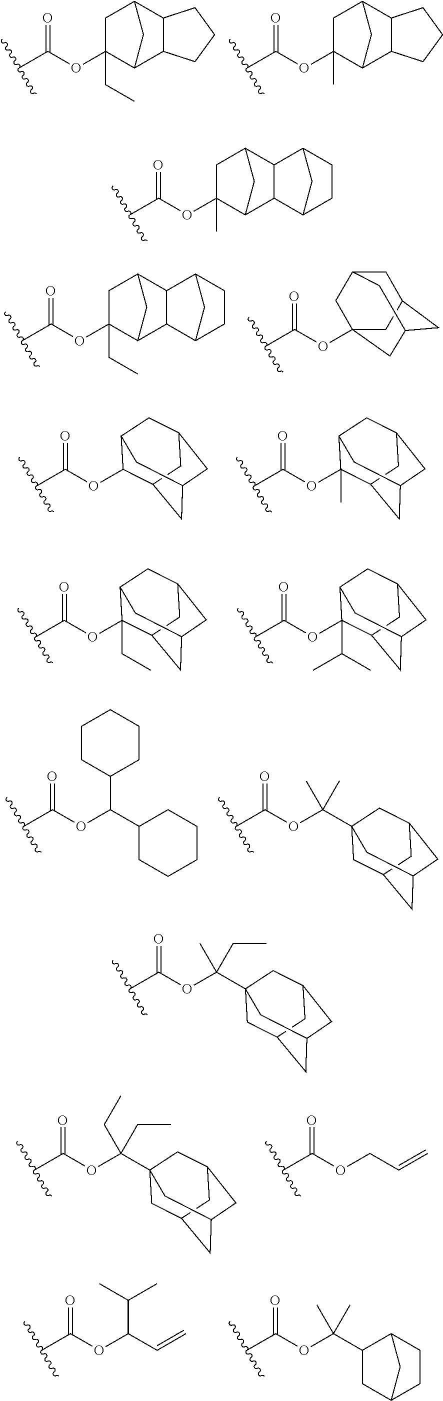

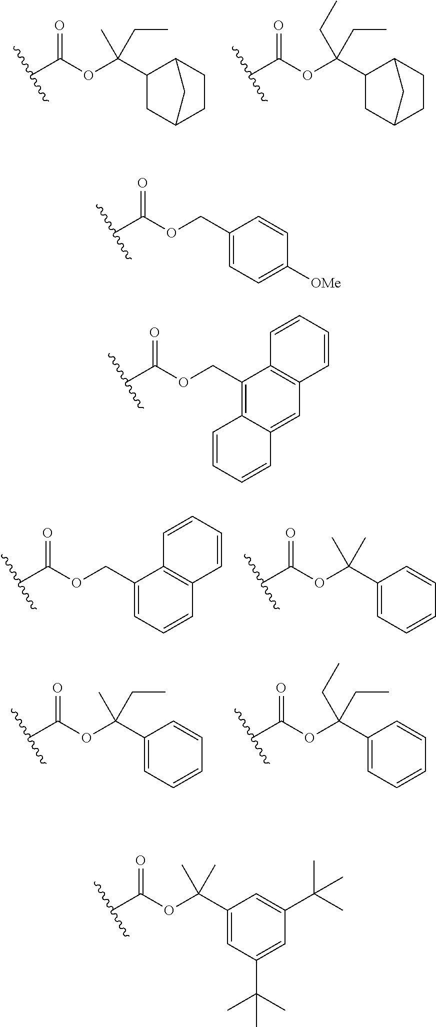

The compound (D) can also be constructed of an arbitrary combination of any of basic compounds to be described hereinafter with any of the structures of general formula (d-1).

It is especially preferred for the compound (D) to have any of the structures of general formula (A) below.

The compound (D) may be any of compounds corresponding to the basic compounds as long as it is a low-molecular compound containing a group leaving under the action of an acid.

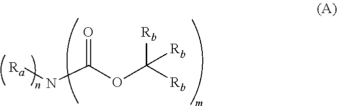

In general formula (A), Ra represents a hydrogen atom, an alkyl group, a cycloalkyl group, an aryl group or an aralkyl group. When n is 2, two Ra's may be identical to or different from each other, and two Ra's may be bonded to each other to thereby form a heterocyclic hydrocarbon group (preferably up to 20 carbon atoms) or a derivative thereof in cooperation with the nitrogen atom to which Ra's are bonded.

Each of Rb's independently represents a hydrogen atom, an alkyl group, a cycloalkyl group, an aryl group, an aralkyl group or an alkoxyalkyl group, provided that in the moiety —C(Rb) (Rb) (Rb), when one or more Rb's are a hydrogen atom, at least one of the remaining Rb's is a cyclopropyl group, a 1-alkoxyalkyl group or an aryl group.

At least two Rb's may be bonded to each other to thereby form an alicyclic hydrocarbon group, an aromatic hydrocarbon group, a heterocyclic hydrocarbon group or a derivative thereof.

In the formula, n is an integer of 0 to 2, and m is an integer of 1 to 3, provided that n+m=3.

In general formula (A), each of the alkyl groups, cycloalkyl groups, aryl groups and aralkyl groups represented by Ra and Rb may be substituted with a functional group, such as a hydroxyl group, a cyano group, an amino group, a pyrrolidino group, a piperidino group, a morpholino group or an oxo group, as well as an alkoxy group or a halogen atom. With respect to the alkoxyalkyl group represented by Rb, the same substitution can be performed.

As the alkyl group, cycloalkyl group, aryl group and aralkyl group represented by Ra and/or Rb (these alkyl group, cycloalkyl group, aryl group and aralkyl group may be substituted with the above functional group, alkoxy group or halogen atom), there can be mentioned, for example,

a group derived from a linear or branched alkane, such as methane, ethane, propane, butane, pentane, hexane, heptane, octane, nonane, decane, undecane or dodecane; a group as obtained by substituting the above alkane-derived group with at least one or at least one type of cycloalkyl group, such as a cyclobutyl group, a cyclopentyl group or a cyclohexyl group;

a group derived from a cycloalkane, such as cyclobutane, cyclopentane, cyclohexane, cycloheptane, cyclooctane, norbornane, adamantane or noradamantane; a group as obtained by substituting the above cycloalkane-derived group with at least one or at least one type of linear or branched alkyl group, such as a methyl group, an ethyl group, an n-propyl group, an i-propyl group, an n-butyl group, a 2-methylpropyl group, a 1-methylpropyl group or a t-butyl group;

a group derived from an aromatic compound, such as benzene, naphthalene or anthracene; a group as obtained by substituting the above aromatic-compound-derived group with at least one or at least one type of linear or branched alkyl group, such as a methyl group, an ethyl group, an n-propyl group, an i-propyl group, an n-butyl group, a 2-methylpropyl group, a 1-methylpropyl group or a t-butyl group;

a group derived from a heterocyclic compound, such as pyrrolidine, piperidine, morpholine, tetrahydrofuran, tetrahydropyran, indole, indoline, quinoline, perhydroquinoline, indazole or benzimidazole; a group as obtained by substituting the above heterocyclic-compound-derived group with at least one or at least one type of linear or branched alkyl group or aromatic-compound-derived group;

a group as obtained by substituting the above linear or branched-alkane-derived group or cycloalkane-derived group with at least one or at least one type of aromatic-compound-derived group, such as a phenyl group, a naphthyl group or an anthracenyl group; any of groups as obtained by substituting the above substituents with a functional group, such as a hydroxyl group, a cyano group, an amino group, a pyrrolidino group, a piperidino group, a morpholino group or an oxo group; and the like.

As the bivalent heterocyclic hydrocarbon group (preferably 1 to 20 carbon atoms) formed by the mutual bonding of Ra's, or derivative thereof, there can be mentioned, for example, a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline or 1,5,9-triazacyclododecane; a group as obtained by substituting the above heterocyclic-compound-derived group with at least one or at least one type of linear or branched-alkane-derived group, cycloalkane-derived group, aromatic-compound-derived group, heterocyclic-compound-derived group or functional group, such as a hydroxyl group, a cyano group, an amino group, a pyrrolidino group, a piperidino group, a morpholino group or an oxo group; or the like.

Particular examples of compounds (D) especially preferred in the present invention are shown below, which in no way limit the scope of the present invention.

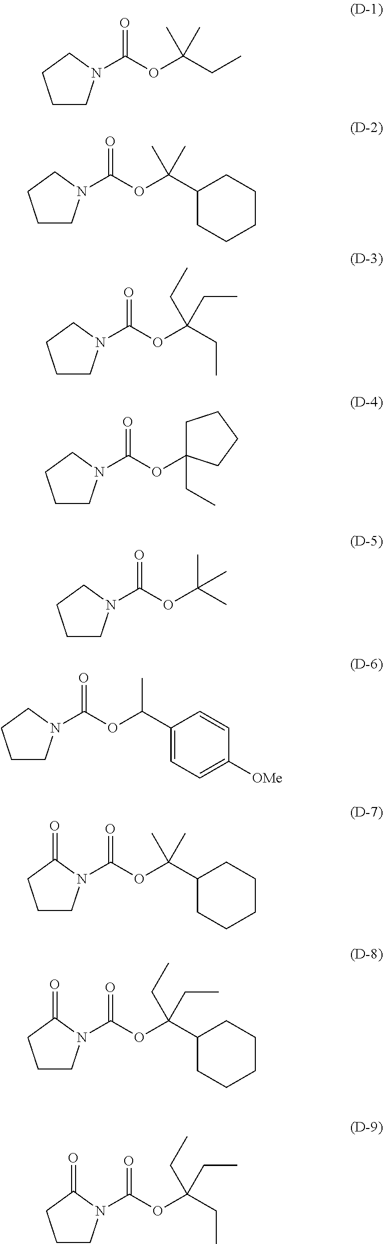

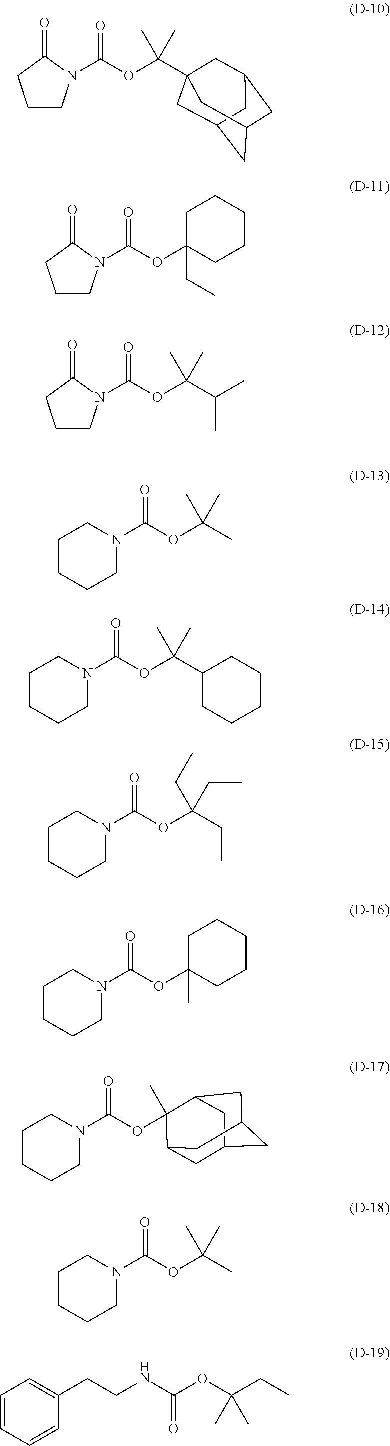

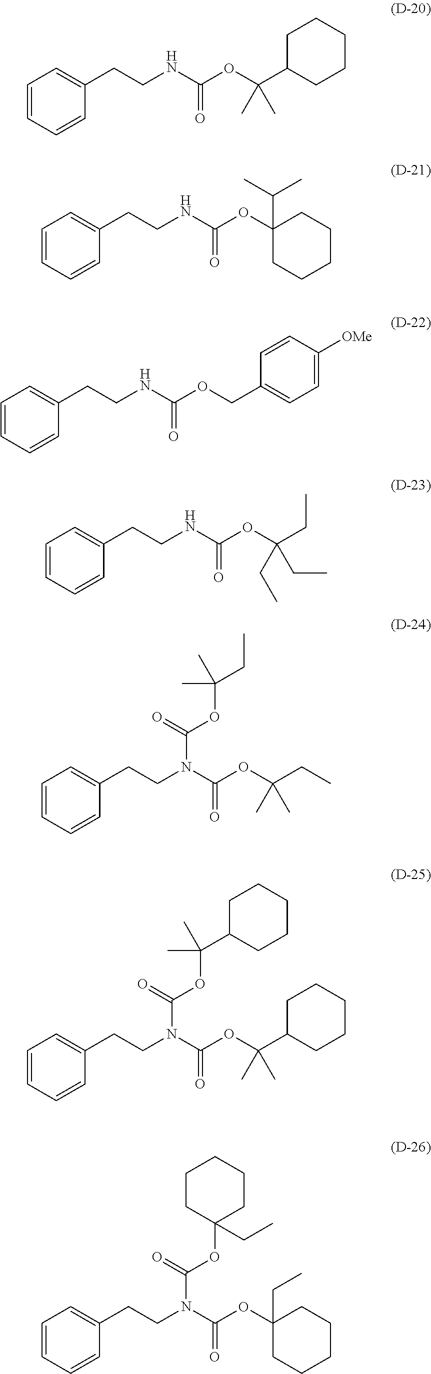

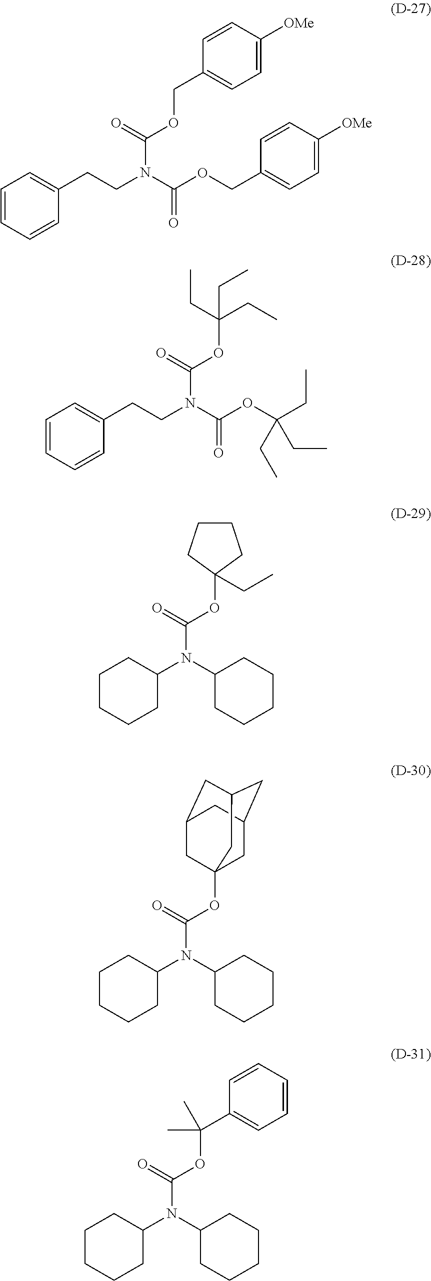

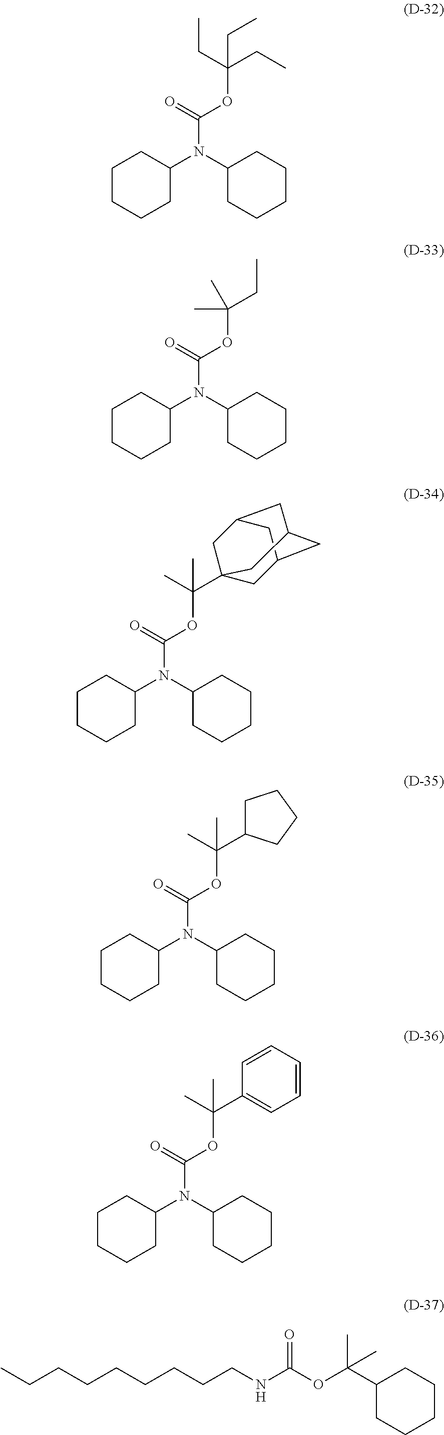

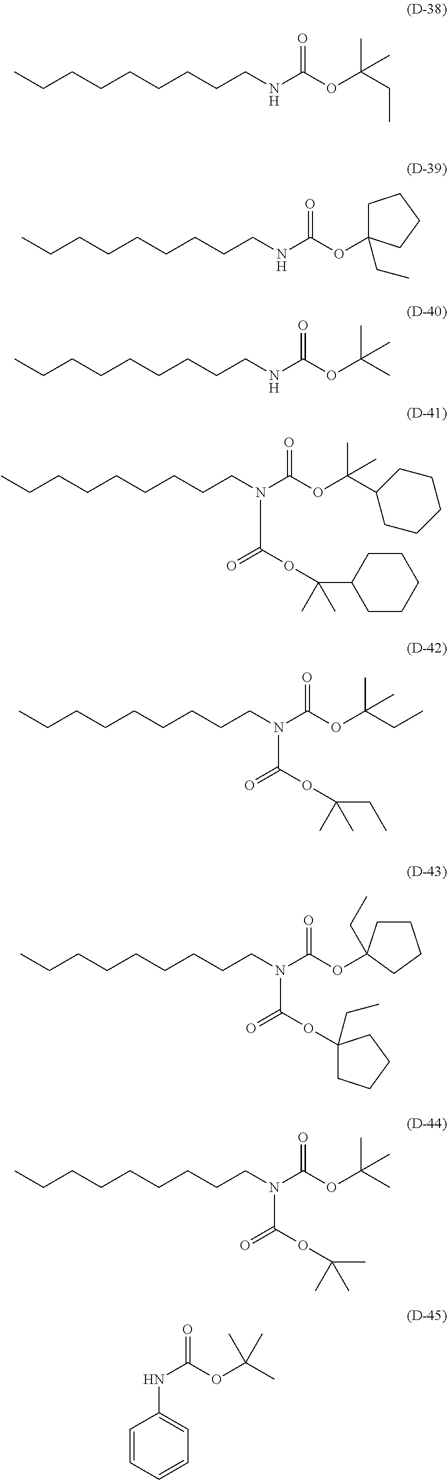

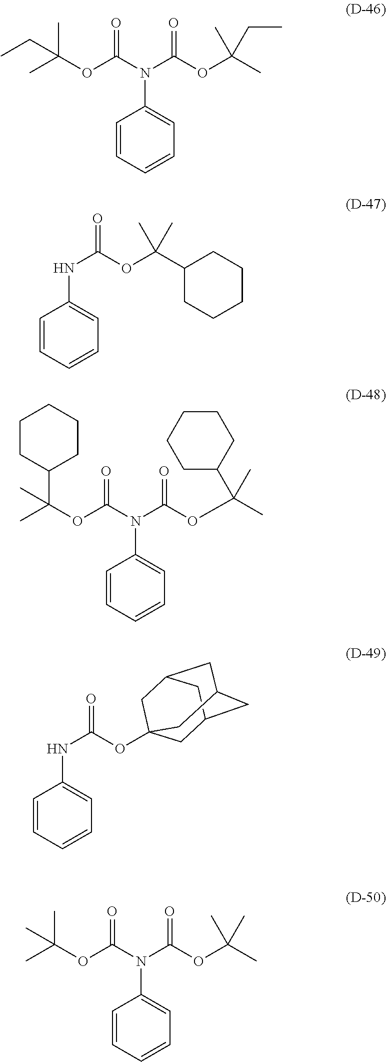

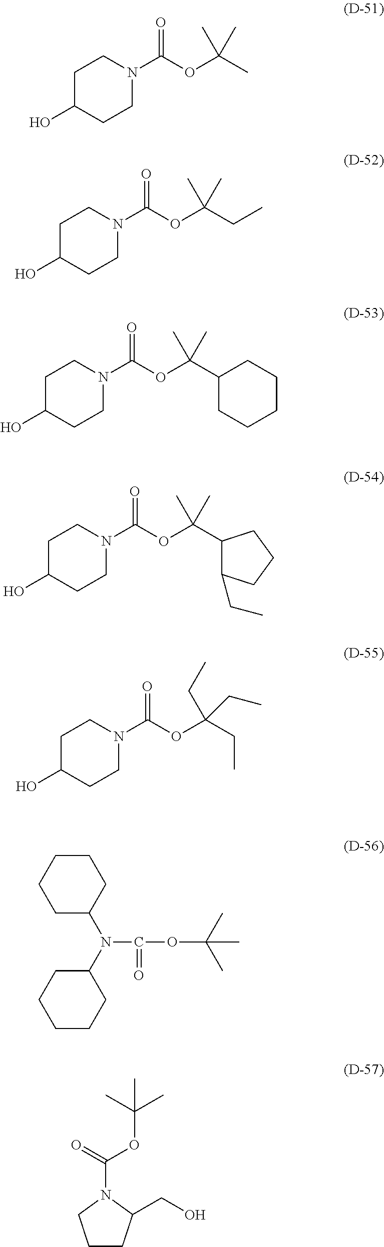

The compounds of general formula (A) can be synthesized in accordance with the methods described in, for example, JP-A-2007-298569 and JP-A-2009-199021.

In the present invention, one type of low-molecular compound (D) containing a nitrogen atom and containing a group leaving under the action of an acid may be used alone, or two or more types thereof may be used in a mixture.

It is optional for the composition of the present invention to contain a low-molecular compound (D) containing a nitrogen atom and containing a group leaving under the action of an acid. When the compound (D) is contained, the content of compound (D), based on the total solids of the composition in which a basic compound to be described hereinafter is incorporated, is generally in the range of 0.001 to 20 mass %, preferably 0.001 to 10 mass % and more preferably 0.01 to 5 mass %.

With respect to the ratio between acid generator and compound (D) used in the composition, it is preferred for the molar ratio of acid generator/[compound (D)+basic compound to be described hereinafter] to be in the range of 2.5 to 300. Namely, the molar ratio is preferred to be 2.5 or higher from the viewpoint of sensitivity and resolution, and the molar ratio is preferred to be 300 or below from the viewpoint of inhibiting any deterioration of resolution by thickening of resist pattern over time from exposure to baking treatment. The molar ratio of acid generator/[compound (D)+basic compound to be described hereinafter] is more preferably in the range of 5.0 to 200, further more preferably 7.0 to 150.

[5] Solvent

As a solvent that can be used for dissolving the above-mentioned components into a resist composition, there can be mentioned, for example, an organic solvent, such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate or an alkyl pyruvate.

As preferred alkylene glycol monoalkyl ether carboxylates, there can be mentioned, for example, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

As preferred alkylene glycol monoalkyl ethers, there can be mentioned, for example, propylene glycol monomethyl ether, propylene glycol monoethyl ether, propylene glycol monopropyl ether, propylene glycol monobutyl ether, ethylene glycol monomethyl ether and ethylene glycol monoethyl ether.

As preferred alkyl lactates, there can be mentioned, for example, methyl lactate, ethyl lactate, propyl lactate and butyl lactate.

As preferred alkyl alkoxypropionates, there can be mentioned, for example, ethyl 3-ethoxypropionate, methyl 3-methoxypropionate, methyl 3-ethoxypropionate and ethyl 3-methoxypropionate.

As preferred cyclolactones, there can be mentioned, for example, β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

As preferred optionally cyclized monoketone compounds, there can be mentioned, for example, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

As preferred alkylene carbonates, there can be mentioned, for example, propylene carbonate, vinylene carbonate, ethylene carbonate and butylene carbonate.

As preferred alkyl alkoxyacetates, there can be mentioned, for example, acetic acid 2-methoxyethyl ester, acetic acid 2-ethoxyethyl ester, acetic acid 2-(2-ethoxyethoxy) ethyl ester, acetic acid 3-methoxy-3-methylbutyl ester and acetic acid 1-methoxy-2-propyl ester.

As preferred alkyl pyruvates, there can be mentioned, for example, methyl pyruvate, ethyl pyruvate and propyl pyruvate.

As a preferably employable solvent, there can be mentioned a solvent having a boiling point of 130° C. or above measured at ordinary temperature under ordinary pressure. For example, there can be mentioned cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid 2-ethoxyethyl ester, acetic acid 2-(2-ethoxyethoxyl)ethyl ester or propylene carbonate.

In the present invention, one of these solvents may be used alone, or two or more thereof may be used in combination.

In the present invention, a mixed solvent comprised of a mixture of a solvent containing a hydroxyl group in its structure and a solvent containing no hydroxyl group may be used as the organic solvent.

The solvent containing a hydroxyl group and the solvent containing no hydroxyl group can be appropriately selected from among the compounds set forth above by way of example. The solvent containing a hydroxyl group is preferably an alkylene glycol monoalkyl ether, an alkyl lactate or the like, more preferably propylene glycol monomethyl ether or ethyl lactate. The solvent containing no hydroxyl group is preferably an alkylene glycol monoalkyl ether acetate, an alkyl alkoxypropionate, an optionally cyclized monoketone compound, a cyclolactone, an alkyl acetate or the like. Of these, propylene glycol monomethyl ether acetate, ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

The mixing ratio (mass) of a solvent containing a hydroxyl group to a solvent containing no hydroxyl group is in the range of 1/99 to 99/1, preferably 10/90 to 90/10 and more preferably 20/80 to 60/40. The mixed solvent containing a solvent containing no hydroxyl group in an amount of 50 mass % or more is especially preferred from the viewpoint of uniform applicability.

It is preferred for the solvent to be a mixed solvent comprised of two or more solvents in which propylene glycol monomethyl ether acetate is contained.

[6] Basic compound

From the viewpoint of diminishing any performance change over time from exposure to baking, it is preferred for the resist composition of the present invention to contain a basic compound.

As preferred basic compounds, there can be mentioned the compounds with structures of the following formulae (A) to (E).

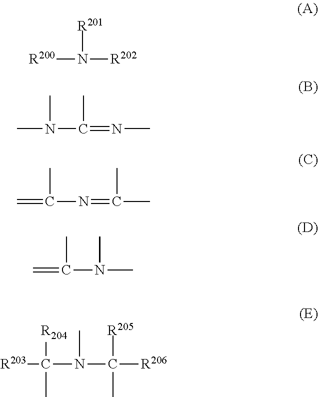

In general formulae (A) and (E),

R²⁰⁰, R²⁰¹ and R²⁰² may be identical to or different from each other, and each represent a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded to each other to thereby form a ring. R²⁰³, R²⁰⁴, R²⁰⁵ and R²⁰⁶ may be identical to or different from each other, and each represent an alkyl group having 1 to 20 carbon atoms.

With respect to the above alkyl group, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

In general formulae (A) and (E), it is preferred for the alkyl groups to be unsubstituted.

As preferred basic compounds, there can be mentioned guanidine, aminopyrrolidine, pyrazole, pyrazoline, piperazine, aminomorpholine, aminoalkylmorpholines, piperidine and the like. As further preferred compounds, there can be mentioned compounds with an imidazole structure, a diazabicyclo structure, an onium hydroxide structure, an onium carboxylate structure, a trialkylamine structure, an aniline structure and a pyridine structure; alkylamine derivatives containing a hydroxyl group and/or an ether bond; aniline derivatives containing a hydroxyl group and/or an ether bond; and the like.

As the compounds with an imidazole structure, there can be mentioned imidazole, 2,4,5-triphenylimidazole, benzimidazole, 2-phenylbenzimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned tetrabutylammonium hydroxide, a triarylsulfonium hydroxide, phenacylsulfonium hydroxide, and sulfonium hydroxides containing a 2-oxoalkyl group, such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. The compounds with an onium carboxylate structure correspond to the compounds with an onium hydroxide structure wherein the anion moiety is a carboxylate, and as such, there can be mentioned, for example, an acetate, adamantane-1-carboxylate, a perfluoroalkyl carboxylate and the like. As the compounds with a trialkylamine structure, there can be mentioned tri(n-butyl)amine, tri(n-octyl)amine and the like. As the aniline compounds, there can be mentioned 2,6-diisopropylaniline, N,N-dimethylaniline, N,N-dibutylaniline, N,N-dihexylaniline and the like. As the alkylamine derivatives containing a hydroxyl group and/or an ether bond, there can be mentioned ethanolamine, diethanolamine, triethanolamine, N-phenyldiethanolamine, tris(methoxyethoxyethyl)amine and the like. As the aniline derivatives containing a hydroxyl group and/or an ether bond, there can be mentioned N,N-bis(hydroxyethyl)aniline and the like.

As preferred basic compounds, there can be further mentioned an amine compound containing a phenoxy group, an ammonium salt compound containing a phenoxy group, an amine compound containing a sulfonic ester group and an ammonium salt compound containing a sulfonic ester group.

Each of the above amine compound containing a phenoxy group, ammonium salt compound containing a phenoxy group, amine compound containing a sulfonic ester group and ammonium salt compound containing a sulfonic ester group preferably contains at least one alkyl group bonded to the nitrogen atom thereof. Further preferably, the alkyl group in its chain contains an oxygen atom, thereby forming an oxyalkylene group. The number of oxyalkylene groups in each molecule is one or more, preferably 3 to 9 and more preferably 4 to 6. Among the oxyalkylene groups, the structures of —CH₂CH₂O—, —CH(CH₃)CH₂O— and —CH₂CH₂CH₂O— are preferred.

As specific examples of the above amine compound containing a phenoxy group, ammonium salt compound containing a phenoxy group, amine compound containing a sulfonic ester group and ammonium salt compound containing a sulfonic ester group, there can be mentioned the compounds (C1-1) to (C3-3) shown as examples in Section[0066] of U.S. Patent Application Publication No. 2007/0224539 A, which are however nonlimiting.

One of these basic compounds may be used alone, or two or more thereof may be used in combination.

The amount of basic compound added is generally in the range of 0.001 to 10 mass %, preferably 0.01 to 5 mass %, based on the total solids of the resist composition.

With respect to the ratio of the acid generator to basic compound used in the composition, it is preferred for the molar ratio of acid generator/basic compound to fall within the range of 2.5 to 300. The reason is as follows. It is preferred for the molar ratio to be 2.5 or higher from the viewpoint of sensitivity and resolution. It is preferred for the molar ratio to be 300 or below from the viewpoint of suppressing any resolution deterioration due to thickening of resist pattern over time from exposure to baking treatment. The molar ratio of acid generator/basic compound is more preferably in the range of 5.0 to 200, further more preferably 7.0 to 150.

[7] Surfactant

The actinic-ray- or radiation-sensitive resin composition may further contain a surfactant. When a surfactant is contained, it is preferred for the composition to contain any one, or two or more, of fluorinated and/or siliconized surfactants (fluorinated surfactant, siliconized surfactant and surfactant containing both fluorine and silicon atoms).

When a surfactant as mentioned above is contained in the composition according to the present invention, in the use of an exposure light source of 250 nm or below, especially 220 nm or below, a resist pattern of reduced adhesion and development defects can be produced with favorable sensitivity and resolution.

As the fluorinated and/or siliconized surfactants, there can be mentioned those described in section[0276] of US Patent Application Publication No. 2008/0248425. For example, there can be mentioned Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by DIC Corporation), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA SOLUTIONS, INC.), and FTX-204G, 208G, 218G, 230G, 204D, 208D, 212D, 218D and 222D (produced by NEOS). Further, polysiloxane polymer KP-341 (produced by Shin-Etsu Chemical Co., Ltd.) can be employed as a siliconized surfactant.

As the surfactant, besides the above generally known surfactants, use can be made of a surfactant based on a polymer containing a fluoroaliphatic group derived from a fluoroaliphatic compound, which polymer can be produced by a telomerization technique (also known as a telomer process) or an oligomerization technique (also known as an oligomer process). The fluoroaliphatic compound can be synthesized by the process described in JP-A-2002-90991.

The polymer containing a fluoroaliphatic group is preferably a copolymer from a monomer containing a fluoroaliphatic group and a poly(oxyalkylene) acrylate and/or a poly(oxyalkylene) methacrylate, which copolymer may have an irregular distribution or may result from block copolymerization. As the poly(oxyalkylene) group, there can be mentioned a poly(oxyethylene) group, a poly(oxypropylene) group, a poly(oxybutylene) group or the like. Further, use can be made of a unit comprising alkylene groups of different chain lengths in a single chain, such as poly(oxyethylene-oxypropylene-oxyethylene block concatenation) or poly(oxyethylene-oxypropylene block concatenation). Moreover, the copolymer from a monomer containing a fluoroaliphatic group and a poly(oxyalkylene) acrylate (or methacrylate) is not limited to two-monomer copolymers and may be a three or more-monomer copolymer obtained by simultaneous copolymerization of two or more different monomers each having a fluoroaliphatic group, two or more different poly(oxyalkylene) acrylates (or methacrylates), etc.

For example, there can be mentioned, as commercially available surfactants, Megafac F178, F-470, F-473, F-475, F-476 and F-472 (produced by DIC Corporation); a copolymer from an acrylate (or methacrylate) containing a C₆F₁₃ group and a poly(oxyalkylene) acrylate (or methacrylate); a copolymer from an acrylate (or methacrylate) containing a C₃F₇ group, poly(oxyethylene) acrylate (or methacrylate) and poly(oxypropylene) acrylate (or methacrylate); and the like.

Moreover, in the present invention, use can be made of surfactants other than the fluorinated and/or siliconized surfactants, described in section [0280] of US Patent Application Publication No. 2008/0248425.

One of these surfactants may be used alone, or two or more thereof may be used in combination.

The amount of surfactant added is preferably in the range of 0 to 2 mass %, more preferably 0.0001 to 2 mass % and most preferably 0.0005 to 1 mass %, based on the total solids (whole amount excluding the solvent) of the actinic-ray- or radiation-sensitive resin composition.

[8] Carboxylic Acid Onium Salt

The resist composition of the present invention may contain a carboxylic acid onium salt. The carboxylic acid onium salt is preferably an iodonium salt or a sulfonium salt. As the anion moiety thereof, it is preferred to employ a C₁ to C₃₀ linear, branched, monocyclic or polycyclic alkyl carboxylate anion. A carboxylate anion wherein the alkyl group is partially or wholly fluorinated is more preferred. An oxygen atom may be introduced in the alkyl chain. By virtue of the incorporation of the carboxylic acid onium salt, the transparency to light of wavelength 220 nm or shorter can be ensured, and the sensitivity and resolving power can be enhanced. Further, the iso/dense bias and exposure margin can be enhanced.

As the fluorinated carboxylate anion, there can be mentioned, for example, any of the anions of fluoroacetic acid, difluoroacetic acid, trifluoroacetic acid, pentafluoropropionic acid, heptafulorobutyric acid, nonafluoropentanoic acid, perfluorododecanoic acid, perfluorotridecanoic acid, perfluorocyclohexanecarboxylic acid and 2,2-bistrifluoromethylpropionic acid.

The content of carboxylic acid onium salt in the composition is generally in the range of 0.1 to 20 mass %, preferably 0.5 to 10 mass % and further more preferably 1 to 7 mass %, based on the total solids of the composition.

[9] Dissolution Inhibiting Compound of 3000 or Less Molecular Weight that when Acted on by an Acid, is Decomposed to Thereby Increase its Solubility in an Alkali Developer

From the viewpoint of avoiding any lowering of the transmission of light of 220 nm or shorter wavelength, it is preferred for the dissolution inhibiting compound (hereinafter also referred to as “dissolution inhibiting compound”) of 3000 or less molecular weight that when acted on by an acid, is decomposed to thereby increase its solubility in an alkali developer to be an alicyclic or aliphatic compound containing an acid-decomposable group, such as any of cholic acid derivatives containing an acid-decomposable group described in Proceeding of SPIE, 2724, 355 (1996). The acid-decomposable group and alicyclic structure can be the same as described above in connection with the resin as component (B).

When the resist composition of the present invention is exposed to a KrF excimer laser or irradiated with electron beams, a compound with a structure resulting from the substitution of the phenolic hydroxyl group of a phenol compound with an acid-decomposable group is preferably used as the dissolution inhibiting compound. The phenol compound preferably contains 1 to 9 phenol skeletons, more preferably 2 to 6 phenol skeletons.

The amount of dissolution inhibiting compound added, based on the total solids of the resist composition, is preferably in the range of 3 to 50 mass %, more preferably 5 to 40 mass %.

Specific examples of the dissolution inhibiting compounds are shown below, which in no way limit the scope of the present invention.

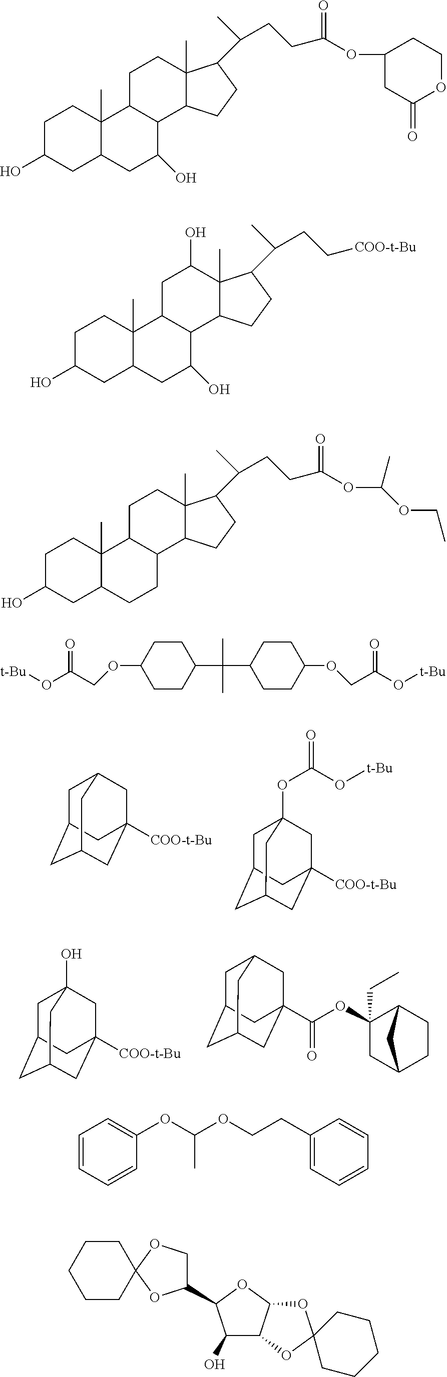

[10] Other Additive

According to necessity, the resist composition of the present invention may further contain a dye, a plasticizer, a photosensitizer, a light absorber, a compound capable of accelerating the dissolution in a developer (for example, a phenolic compound of 1000 or less molecular weight, or a carboxylated alicyclic or aliphatic compound), etc.

The above phenolic compound of 1000 or less molecular weight can be easily synthesized by persons of ordinary skill in the art to which the present invention pertains while consulting the processes described in, for example, JP-A's H4-122938 and H2-28531, U.S. Pat. No. 4,916,210 and European Patent 219294.

As the carboxylated alicyclic or aliphatic compound, there can be mentioned, for example, a carboxylic acid derivative with a steroid structure, such as cholic acid, deoxycholic acid or lithocholic acid, an adamantanecarboxylic acid derivative, adamantanedicarboxylic acid, cyclohexanecarboxylic acid, cyclohexanedicarboxylic acid or the like. These are however nonlimiting.

[11] Method of Forming Pattern

From the viewpoint of enhancement of resolving power, the resist composition of the present invention is preferably used in a film thickness of 30 to 250 nm. More preferably, the composition is used in a film thickness of 30 to 200 nm. This film thickness can be attained by setting the solid content of the resist composition within an appropriate range so as to cause the composition to have an appropriate viscosity, thereby improving the applicability and film forming property.

The total solid content of the resist composition is generally in the range of 1 to 10 mass %, preferably 1 to 8.0 mass % and more preferably 1.0 to 6.0 mass %.

The resist composition of the present invention is used in such a manner that above-mentioned individual components are dissolved in a given organic solvent, preferably above-mentioned mixed solvent, filtered and applied onto a given support to be mentioned below. The filter used is preferably made of a polytetrafluoroethylene, polyethylene or nylon having a pore size of 0.1 μm or less, preferably 0.05 μm or less and more preferably 0.03 μm or less.

For example, the resist composition is applied onto a substrate, such as one for use in the production of precision integrated circuit elements (e.g., silicon/silicon dioxide coating), by appropriate application means, such as a spinner or a coater. Thereafter, the composition is dried, thereby attaining the formation of a resist film.

The thus formed resist film is exposed through a given mask to actinic rays or radiation, preferably baked (heated), developed and rinsed. As a result, a desirable pattern can be obtained.

As the actinic rays or radiation, there can be mentioned, for example, infrared light, visible light, ultraviolet light, far-ultraviolet light, extreme ultraviolet (EUV), X-rays or electron beams. It is preferred to employ far-ultraviolet light of wavelength preferably 250 nm or shorter, more preferably 220 nm or shorter and most preferably 1 to 200 nm, such as a KrF excimer laser (248 nm), an ArF excimer laser (193 nm) or an F₂ excimer laser (157 nm), EUV (13 nm), X-rays, electron beams or the like. An ArF excimer laser, an F₂ excimer laser, EUV (13 nm) and electron beams are more preferred.

Prior to the formation of the resist film, an antireflection film may be applied to the substrate.

As the antireflection film, use can be made of not only an inorganic film of titanium, titanium dioxide, titanium nitride, chromium oxide, carbon, amorphous silicon or the like but also an organic film comprised of a light absorbing agent and a polymer material. Also, as an organic antireflection film, use can be made of any of commercially available organic antireflection films, such as DUV-30 Series and DUV-40 Series produced by Brewer Science Inc. and AR-2, AR-3 and AR-5 produced by Shipley Co., Ltd.

The developer for use in the operation of developing the resist film formed from the actinic-ray- or radiation-sensitive resin composition of the present invention is not particularly limited. For example, use can be made of an alkali developer or a developer comprising an organic solvent (hereinafter also referred to as an organic developer).

A solution of quaternary ammonium salt whose representative is tetramethylammonium hydroxide is generally used as the alkali developer. Besides this, use can be made of an alkaline aqueous solution containing an inorganic alkali, a primary amine, a secondary amine, a tertiary amine, an alcoholamine, a cycloamine or the like. Appropriate amounts of an alcohol and a surfactant may further be added to the above alkali developer before use. The alkali concentration of the alkali developer is generally in the range of 0.1 to 20 mass %. The pH value of the alkali developer is generally in the range of 10.0 to 15.0.

Appropriate amounts of an alcohol and a surfactant may further be added to the above alkaline aqueous solution before use.

As the organic developer, use can be made of a polar solvent, such as a ketone solvent, an ester solvent, an alcohol solvent, an amide solvent or an ether solvent, and a hydrocarbon solvent.

As the ketone solvent, there can be mentioned, for example, 1-octanone, 2-octanone, 1-nonanone, 2-nonanone, acetone, 2-heptanone(methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate or the like.

As the ester solvent, there can be mentioned, for example, methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl 3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate or the like.

As the alcohol solvent, there can be mentioned, for example, an alcohol, such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol or n-decanol; a glycol solvent, such as ethylene glycol, diethylene glycol or triethylene glycol; a glycol ether solvent, such as ethylene glycol monomethyl ether, propylene glycol monomethyl ether, ethylene glycol monoethyl ether, propylene glycol monoethyl ether, diethylene glycol monomethyl ether, triethylene glycol monoethyl ether or methoxymethylbutanol; or the like.

As the ether solvent, there can be mentioned, for example, not only any of the above-mentioned glycol ether solvents but also dioxane, tetrahydrofuran or the like.

As the amide solvent, there can be mentioned, for example, N-methyl-2-pyrrolidone, N,N-dimethylacetamide, N,N-dimethylformamide, hexamethylphosphoric triamide, 1,3-dimethyl-2-imidazolidinone or the like.

As the hydrocarbon solvent, there can be mentioned, for example, an aromatic hydrocarbon solvent, such as toluene or xylene, or an aliphatic hydrocarbon solvent, such as pentane, hexane, octane or decane.

Any two or more of these solvents may be mixed together before use. Alternatively, any of the solvents may be mixed with a solvent other than those mentioned above or water before use. It is preferred for the content of water in the organic developer to be less than 10 mass %. More preferably, the organic developer contains substantially no trace of water.

Namely, the amount of organic solvent used in the organic developer is preferably in the range of 90 to 100 mass %, more preferably 95 to 100 mass %, based on the whole amount of the developer.

It is especially preferred for the organic developer to be a developer comprising at least one organic solvent selected from the group consisting of a ketone solvent, an ester solvent, an alcohol solvent, an amide solvent and an ether solvent.

According to necessity, an appropriate amount of surfactant can be added to the organic developer.

The surfactant is not particularly limited. For example, use can be made of any of ionic and nonionic fluorinated and/or siliconized surfactants and the like. As such fluorinated and/or siliconized surfactants, there can be mentioned, for example, those described in JP-A's S62-36663, S61-226746, S61-226745, S62-170950, S63-34540, H7-230165, H8-62834, H9-54432 and H9-5988, and USPs 5405720, 5360692, 5529881, 5296330, 5436098, 5576143, 5294511 and 5824451. Nonionic surfactants are preferred. Although nonionic surfactants are not particularly limited, using a fluorinated surfactant or siliconized surfactant is preferred. The amount of surfactant added is generally in the range of 0.001 to 5 mass %, preferably 0.005 to 2 mass % and more preferably 0.01 to 0.5 mass %, based on the whole amount of the developer.

Pure water is used as a rinse liquid. Before use, an appropriate amount of surfactant may be added to the rinse liquid.

Further, the development operation or rinse operation may be followed by an operation of removing any developer or rinse liquid adhering on the pattern by use of a supercritical fluid.

Furthermore, the present invention relates to a process for manufacturing an electronic device, in which the above-described pattern forming method of the present invention is included, and relates to an electronic device manufactured by the process.

The electronic device of the present invention can be appropriately mounted in electrical and electronic equipments (household electronic appliance, OA/media-related equipment, optical apparatus, telecommunication equipment and the like).

### Examples

### Synthesis of Resin B-1

In a nitrogen gas stream, 14.2 g of cyclohexanone was placed in a three-necked flask and heated at 85° C. Thus, solvent 1 was obtained. Subsequently, the following monomer 1 (8.89 g), monomer 2 (3.55 g) and monomer 3 (8.20 g) were dissolved in cyclohexanone (56.9 g), thereby obtaining a monomer solution. Polymerization initiator V601 (produced by Wako Pure Chemical Industries, Ltd.) was added to the monomer solution in an amount of 8.0 mol % based on the total amount of monomers, and dissolved. The thus obtained solution was dropped into the solution 1 over a period of 6 hours. After the completion of the dropping, reaction was continued at 85° C. for 2 hours. The thus obtained reaction liquid was allowed to stand still to cool, and was dropped into a mixed solvent comprised of 506 g of heptane and 217 g of ethyl acetate. The thus precipitated powder was collected by filtration and dried, thereby obtaining 16.5 g of resin (B-1). With respect to the obtained resin (B-1), the weight average molecular weight (Mw) was 8500, and the polydispersity index (Mw/Mn) was 1.56.

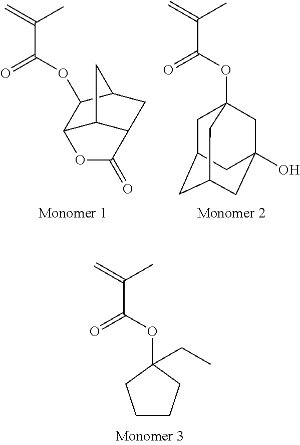

The resins (B-2), (B-3) and (B-X) used in Examples were synthesized in the same manner as described above in connection with the resin (B−1).

(Synthesis of Photoacid Generator A-1)

Photoacid generator A-1 was synthesized in accordance with a synthesizing method described in PCT International Publication No. 2012/056901 (pamphlet). In the same manner, photoacid generator A-2 was synthesized.

<Preparation of Resist>

Individual components were dissolved in solvents, as indicated in Table 2 to be shown hereinafter. Thus, solutions each of 4 mass % solid content were obtained. The solutions were each passed through a polyethylene filter of 0.05 μm pore size, thereby obtaining actinic-ray- or radiation-sensitive resin compositions (hereinafter also referred to as resist compositions). The thus obtained actinic-ray- or radiation-sensitive resin compositions were evaluated by the following methods, and the results are given in Table 2.

<Evaluation of Resist>

(ArF Liquid Immersion Exposure)

An organic antireflection film ARC29SR (produced by Nissan Chemical Industries, Ltd.) was applied onto a 12-inch silicon wafer and baked at 205° C. for 60 seconds, thereby forming a 98 nm-thick antireflection film. Each of the above prepared actinic-ray- or radiation-sensitive resin compositions was applied thereonto and baked at 95° C. for 60 seconds, thereby forming a 120 nm-thick resist film. The resultant wafer was exposed through a 6% half-tone mask of 48 nm line width 1:1 line and space pattern to light by means of an ArF excimer laser liquid immersion scanner (manufactured by ASML, XT1700i, NA1.20, C-Quad, outer sigma 0.981, inner sigma 0.895, XY deflection). Ultrapure water was used as the immersion liquid. Thereafter, the exposed wafer was baked at 90° C. for 60 seconds, developed by puddling with an aqueous solution of tetramethylammonium hydroxide (2.38 mass %) for 30 seconds, rinsed by puddling with pure water and spin dried, thereby obtaining a pattern.

(Evaluation of LWR)

The thus obtained line pattern of line/space=1/1 (ArF liquid-immersion exposure: 48 nm line width) was observed by means of a scanning electron microscope (model S9380 manufactured by Hitachi, Ltd.). In an edge 2 μm region along the longitudinal direction of the line pattern, the line width was measured at 50 points. With respect to the dispersion of measurements, the standard deviation was determined, and 3σ was computed therefrom. The smaller the value thereof, the more favorable the performance exhibited.

(Evaluation of Focal Depth Latitude (DOF))

The optimum exposure amount and optimum focal depth were respectively defined as the exposure amount and focal depth that reproduced the 48 nm line width 1:1 line-and-space resist pattern. The focal depth was varied from the optimum focal depth (defocused) while fixing the exposure amount at the optimum exposure amount, and the focal depth width allowing any line width of the above line width ±10% (namely, 48 nm ±10%) was measured. The greater the value of the focal depth width, the favorably greater the defocusing latitude.

(Temporal Stability of Resist)

The temporal stability of resist was assessed by a guaranteed period in which the resist performance did not change. The temporal stability of resist was evaluated by the following temporal stability test of line width.

The line widths of patterns obtained from the resist solutions respectively aged at 40° C., 50° C. and 60° C. for 30 days were compared with that from the resist solution (reference resist) aged at 0° C. for 30 days, and the stability was evaluated by any pattern line width differences therebetween.

In particular, first, with respect to the line width of pattern obtained from the resist solution aged at 0° C. for 30 days, the exposure amount (E₁) that reproduced a 45 nm line width 1:1 line-and-space mask pattern was determined. Subsequently, resist films were formed from three types of resist solutions aged at raised temperatures for 30 days, and exposure amounting to E₁ was performed on each of the films. The line widths of thus obtained patterns were measured by means of a scanning electron microscope (model S-9260 manufactured by Hitachi, Ltd.), and pattern line width variations from the line width (45 nm) of pattern formed from the reference resist solution were calculated.

On the basis of thus obtained 3-point data (above-mentioned pattern line width variation values), plotting was performed on a semilogarithmic graph wherein the X-axis indicated the reciprocal of aging temperature (Celsius converted to Kelvin) while the Y-axis indicated the reciprocal of line width variation value per day (namely, quotient of the determined line width variation value divided by 30), and a collinear approximation was applied. On the thus obtained line, the Y-coordinate value at the X-coordinate corresponding to the aging temperature 25° C. was read. The thus read Y-coordinate value was denoted as the 1 nm-line-width guaranteed days in room temperature condition (25° C.)

(Evaluation Mark Indicating 1 Nm-Line-Width Guaranteed Days)

A: 500 days or more

B: 300 days to less than 500 days

C: 100 days to less than 300 days

D: 1 day to less than 100 days

TABLE 2

| | Photoacid | | Basic | Hydrophobic | | | | | |
|---|---|---|---|---|---|---|---|---|---|
| | generator | Resin | compound | resin | Solvent | Surfactant | LWR | DOF | Temporal |
| | (g) | (10 g) | (g) | (35 mg) | (mass ratio) | (10 mg) | (nm) | (μm) | stability |
| Ex. 1 | A-1 | B-1 | C-X | B-4 | A1 | W-1 | 5.9 | 0.1 | B |
| | (0.6) | | (0.36) | | (100) | | | | |
| Ex. 2 | A-1 | B-2 | C-X | B-18 | A1/A2 | W-1 | 5.4 | 0.12 | B |
| | (0.8) | | (0.28) | | (70/30) | | | | |
| Ex. 3 | A-2 | B-3 | C-1 | B-16 | A1/B1 | W-3 | 5.0 | 0.12 | A |
| | (0.5) | | (0.39) | | (60/40) | | | | |
| Ex. 4 | A-3 | B-3 | C-1 | B-3 | A1 | W-1 | 5.0 | 0.13 | A |
| | (0.8) | | (0.35) | | (100) | | | | |
| Ex. 5 | A-2 | B-1/B-2 | C-X | B-13 | A1/A2 | W-2 | 5.1 | 0.12 | B |
| | (0.7) | (5 g/5 g) | (0.33) | | (70/30) | | | | |
| Ex. 6 | A-1/A-X | B-3 | C-X | B-3 | A1/A2/A3 | W-1 | 4.7 | 0.14 | B |
| | (0.5/0.3) | | (0.31) | | (85/10/5) | | | | |
| Ex. 7 | A-1/A-2 | B-2 | C-1/C-X | B-21 | A1/B1 | W-3 | 4.9 | 0.14 | A |
| | (0.5/0.5) | | (0.21/0.13) | | (60/40) | | | | |
| Ex. 8 | A-2/A-X | B-3 | C-1 | B-2 | A1/A2 | W-2 | 4.6 | 0.14 | A |
| | (0.6/0.2) | | (0.28) | | (70/30) | | | | |
| Ex. 9 | A-2 | B-1 | C-X | — | A1/A2/A3 | W-1 | 6 | 0.09 | B |
| | (0.5) | | (0.31) | | (85/10/5) | | | | |
| Comp. Ex. 1 | A-1 | B-X | C-X | B-8 | A1 | W-1 | 6.7 | 0.05 | D |
| | (0.5) | | (0.32) | | (100) | | | | |

The meanings of designations appearing in the table are indicated below.

[Photoacid Generator]

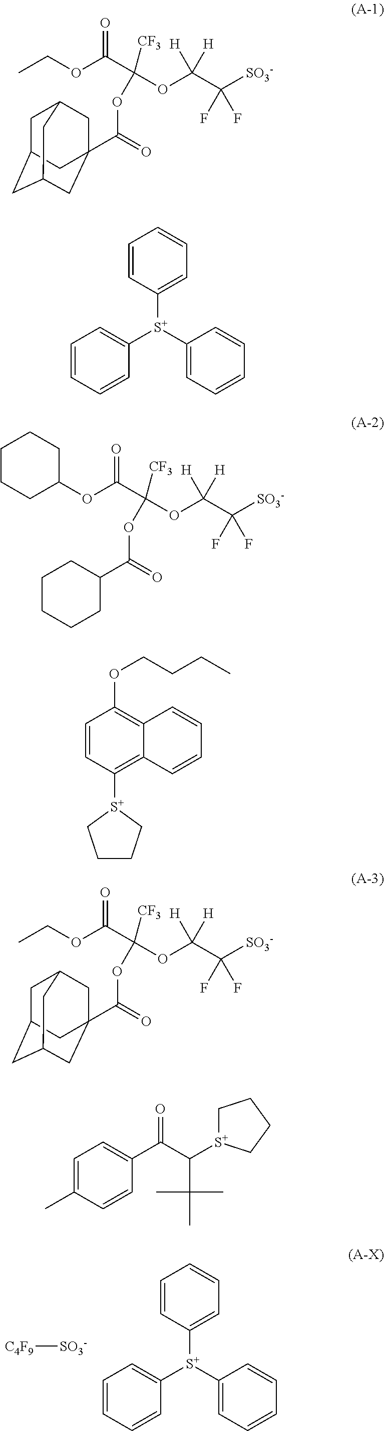

[Resin]

In each of the following resins, the ratio of repeating units contained is a molar ratio.

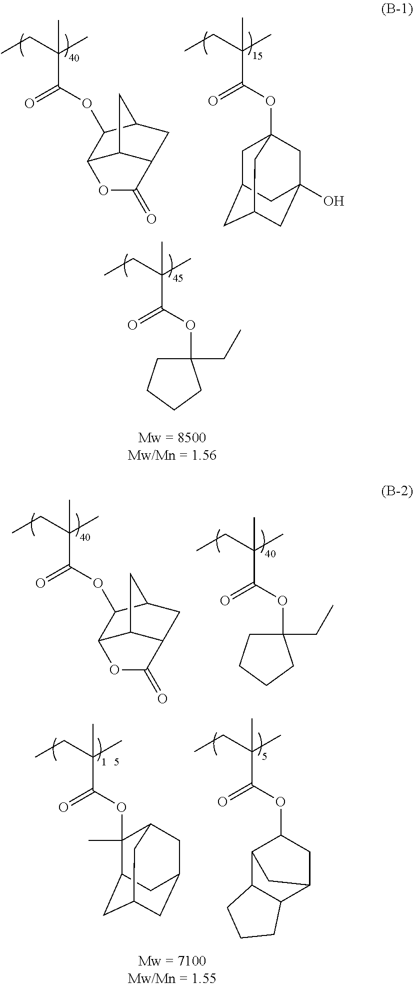

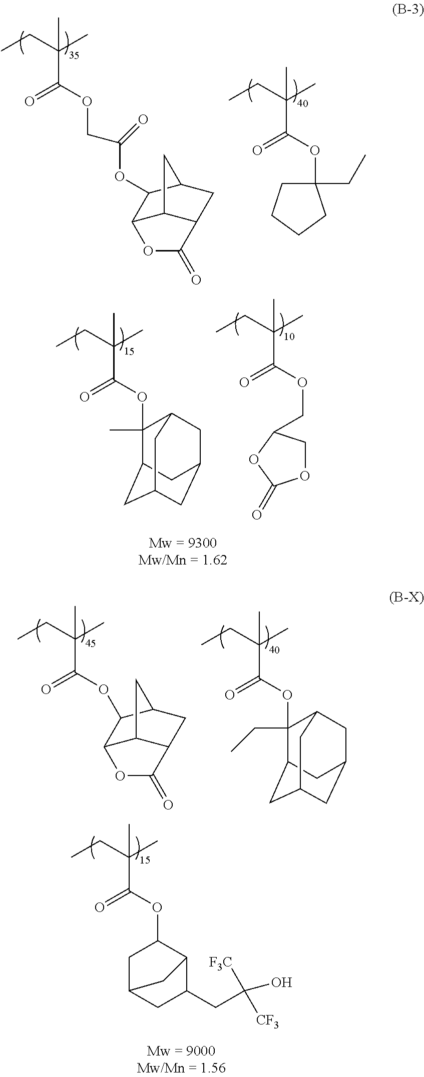

[Basic Compound]

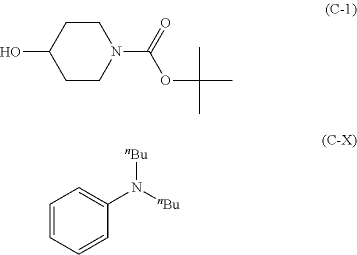

[Hydrophobic Resin]

The employed hydrophobic resins are those appropriately selected from among hydrophobic resins (B-1) to (B-55) set forth hereinbefore as particular examples thereof.

[Solvent]

A1: propylene glycol monomethyl ether acetate (PGMEA),

A2: cyclohexanone,

A3: γ-butyrolactone,

B1: propylene glycol monomethyl ether (PGME), and

B2: ethyl lactate.

[Surfactant]

W-1: Megafac F176 (produced by DIC Corporation) (fluorinated),

W-2: Troy Sol S-366 (produced by Troy Chemical Co., Ltd.) (fluorinated), and

W-3: PF656 (produced by OMNOVA SOLUTIONS, INC.) (fluorinated).

Table 2 above shows that the compositions employed in Examples excel in not only exposure latitude and pattern roughness, such as LWR, but also temporal stability.

What is claimed is:

1. An actinic-ray- or radiation-sensitive resin composition comprising:
(A) at least one of compounds of general formula (I) below that when exposed to actinic rays or radiation, generates acids, and
(B) a resin containing at least one of repeating units of general formula (1) below, which resin when acted on by an acid, is decomposed to thereby increase its solubility in an alkali developer, 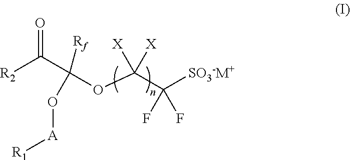
in which
each of X's independently represents a hydrogen atom, a fluorine atom or a fluorinated alkyl group;
R₁ represents a hydrogen atom, a halogen atom, an alkyl group, a mono- or polycycloalkyl group, an alkenyl group, an oxoalkyl group, an aryl group or an aralkyl group;
R₂ is either R₃O or R₄R₅N, in which each of R₃, R₄ and R₅ independently represents a hydrogen atom, an alkyl group, a mono- or polycycloalkyl group, an alkenyl group, an oxoalkyl group, an aryl group, an aralkyl group or a lactone group, provided that when R₂ is R₄R₅N, R₄ and R₅ may be bonded to each other to thereby form a ring structure in cooperation with the nitrogen atom to which R₄ and R₅ are bonded;
R_{f} represents a hydrogen atom, a fluorine atom or a fluorinated alkyl group;
A is any of groups of formulae below; 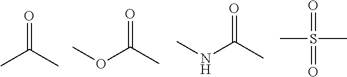
M⁺ represents a monovalent cation; and
n is an integer of 1 to 10, 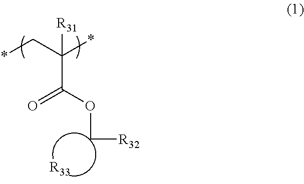
in which
R₃₁ represents a hydrogen atom, a fluorine atom, an alkyl group or a fluorinated alkyl group;
R₃₂ represents a methyl group, an ethyl group, an n-propyl group, an isopropyl group, an n-butyl group, an isobutyl group or a sec-butyl group; and
R₃₃ represents an atomic group required to form a monoalicyclic hydrocarbon structure in cooperation with the carbon atom to which R₃₂ is bonded, provided that in the alicyclic hydrocarbon structure, ring-constituting carbon atoms may be partially replaced by a heteroatom or a heteroatom-containing group.

2. The actinic-ray- or radiation-sensitive resin composition according to claim 1, wherein in general formula (I), M⁺ is any of sulfonium cations of general formulae (II) and (III) below, 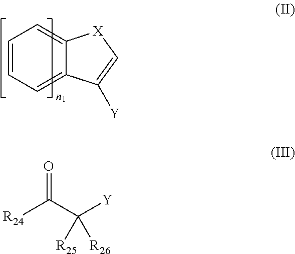
in which
Y represents any of structures of general formulae (V-1) to (V-3) below, 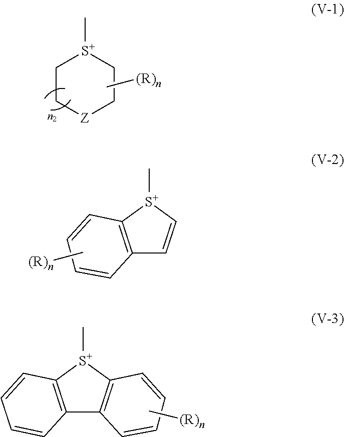
each of n₁ and n₂ independently is 0 or 1;
each of X and Z is any of —CH₂—, —CR₂₁═CR₂₂—, —NR₂₃—, —S— and —O—, in which each of R₂₁, R₂₂ and R₂₃ independently represents a hydrogen atom, a substituted or unsubstituted alkyl group, a cycloalkyl group or an alkoxy group;
R₂₄ represents a substituted or unsubstituted aryl group;
each of R₂₅ and R₂₆ independently represents a hydrogen atom, a substituted or unsubstituted alkyl group or a cycloalkyl group, provided that R₂₅ and R₂₆ may be connected to each other to thereby form a ring; and
(R)ₙ represents a substituent.

3. The actinic-ray- or radiation-sensitive resin composition according to claim 1, further comprising (C) any of compounds of general formula (2) below, 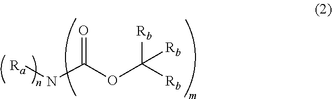
in which
Ra, or each of Ra's independently, represents a hydrogen atom, an alkyl group, a cycloalkyl group, an aryl group or an aralkyl group, provided that when n is 2, two Ra's may be identical to or different from each other, and two Ra's may be bonded to each other to thereby form a heterocyclic hydrocarbon group or a derivative thereof in cooperation with the nitrogen atom to which Ra is bonded;
each of Rb's independently represents a hydrogen atom, an alkyl group, a cycloalkyl group, an aryl group or an aralkyl group, provided that a plurality of Rb's may be bonded to each other to thereby form an alicyclic hydrocarbon group, an aromatic hydrocarbon group, a heterocyclic hydrocarbon group or a derivative of any of these; and
n is an integer of 0 to 2, and m is an integer of 1 to 3, provided that n+m=3.

4. The actinic-ray- or radiation-sensitive resin composition according to claim 1, further comprising at least one photoacid generator other than the compounds (A).

5. The actinic-ray- or radiation-sensitive resin composition according to claim 1, wherein the resin (B) further contains at least one repeating unit that when acted on by an acid, is decomposed to thereby realize an increased solubility in an alkali developer, other than the repeating units of general formula (1).

6. The actinic-ray- or radiation-sensitive resin composition according to claim 1, further comprising a hydrophobic resin.

7. An actinic-ray- or radiation-sensitive film comprising the composition according to claim 1.

8. A method of forming a pattern, comprising forming a film comprising the composition according to claim 1, exposing the film to actinic rays or radiation, and developing the film having been exposed to actinic rays or radiation.

9. The pattern forming method according to claim 8, wherein the exposure to actinic rays or radiation is performed by ArF liquid-immersion exposure.

10. A process for manufacturing an electronic device, comprising the pattern forming method according to claim 8.

11. An electronic r device manufactured by the electronic device manufacturing process according to claim 10.
